(19) United States
(12) Patent Application Publication
(10) Pub. No.: US 2020/0266289 A1
(43) Pub. Date: Aug. 20, 2020

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., ATSUGI-SHI, KANAGAWA-KEN (JP)

(72) Inventors: Shunpei YAMAZAKI, Setagaya, Tokyo (JP); Toshihiko TAKEUCHI, Atsugi, Kanagawa (JP); Tsutomu MURAKAWA, Isehara, Kanagawa (JP); Hiroki KOMAGATA, Atsugi, Kanagawa (JP); Naoki OKUNO, Yamato, Kanagawa (JP); Noritaka ISHIHARA, Koza, Kanagawa (JP); Yusuke NONAKA, Atsugi, Kanagawa (JP)

(73) Assignee: SEMICONDUCTOR ENERGY LABORATORY CO., LTD., ATSUGI-SHI, KANAGAWA-KEN (JP)

(21) Appl. No.: 16/642,998

(22) PCT Filed: Aug. 28, 2018
(86) PCT No.: PCT/IB2018/056535

§ 371 Date: Feb. 28, 2020

(30) Foreign Application Priority Data
Sep. 5, 2017 (JP) 2017-170056
Sep. 5, 2017 (JP) 2017-170060
Dec. 13, 2017 (JP) 2017-238209

(51) Int. Cl. H01L 29/66; H01L 21/02; H01L 29/786; H01L 27/108

(52) U.S. Cl. CPC H01L 29/66969; H01L 27/10805; H01L 29/7869; H01L 21/02323

(57) ABSTRACT

A semiconductor device with favorable electrical characteristics and reliability is provided. A first insulator is formed. A second insulator is formed over the first insulator. An island-shaped oxide is formed over the second insulator. A stacked body of a third insulator and a conductor is formed over the oxide. The resistance of the oxide is selectively reduced by forming a film containing a metal element over the oxide and the stacked body. After a fourth insulator is formed over the second insulator, the oxide, and the stacked body, an opening portion exposing the second insulator is formed in the fourth insulator. A fifth insulator is formed over the second insulator and the fourth insulator. Oxygen introduction treatment is performed on the fifth insulator.

### TECHNICAL FIELD

One embodiment of the present invention relates to a semiconductor device and a method for manufacturing the semiconductor device. Another embodiment of the present invention relates to a semiconductor wafer, a module, and an electronic device.

Note that in this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Another embodiment of the present invention relates to a process, a machine, manufacture, or a composition of matter.

### BACKGROUND ART

In recent years, semiconductor devices have been developed and an LSI, a CPU, or a memory is mainly used. A CPU is an aggregation of semiconductor elements in which an electrode which is a connection terminal is formed, which includes a semiconductor integrated circuit (at least a transistor and a memory) separated from a semiconductor wafer.

A semiconductor circuit (an IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has attracted attention. The transistor is applied to a wide range of electronic devices such as an integrated circuit (IC) and an image display device (also simply referred to as a display device). A silicon-based semiconductor material is widely known as a semiconductor thin film applicable to the transistor; in addition, an oxide semiconductor has been attracting attention as another material.

It is known that a transistor using an oxide semiconductor has an extremely low leakage current in a non-conduction state. For example, a low-power-consumption CPU or the like utilizing a characteristic of low leakage current of the transistor using an oxide semiconductor has been disclosed (see Patent Document 1).

A transistor with a self-aligned structure has been proposed as the transistor using an oxide semiconductor. A method for manufacturing the transistor with a self-aligned structure in which a metal film is formed over a source region and a drain region and heat treatment is performed on the metal film so that the resistance of the metal film is increased and the resistance of the source region and the drain region is reduced is disclosed (see Patent Document 2).

As a method for manufacturing the transistor using an oxide semiconductor, a method in which a metal film is formed over a source region and a drain region, heat treatment is performed, and a dopant is introduced through the metal film so that the resistance of the source region and the drain region is reduced is disclosed (see Patent Document 3).

In recent years, a demand for an integrated circuit in which transistors and the like are integrated with high density has risen with reductions in the size and weight of an electronic device. In addition, improvement in the productivity of a semiconductor device including an integrated circuit is required.

A silicon-based semiconductor material is widely known as a semiconductor thin film that can be used in a transistor, and as another material, an oxide semiconductor has attracted attention. As the oxide semiconductor, not only single-component metal oxides, such as indium oxide and zinc oxide, but also multi-component metal oxides are known. Among the multi-component metal oxides, in particular, an In—Ga—Zn oxide (hereinafter also referred to as IGZO) has been actively studied.

From the studies on IGZO, a CAAC (c-axis aligned crystalline) structure and an nc (nanocrystalline) structure, which are not single crystal nor amorphous, have been found in an oxide semiconductor (see Non-Patent Document 1 to Non-Patent Document 3). In Non-Patent Document 1 and Non-Patent Document 2, a technique for manufacturing a transistor using an oxide semiconductor having a CAAC structure is also disclosed. Moreover, Non-Patent Document 4 and Non-Patent Document 5 show that a fine crystal is included even in an oxide semiconductor which has lower crystallinity than an oxide semiconductor having the CAAC structure or the nc structure.

In addition, a transistor using IGZO for an active layer has an extremely low off-state current (see Non-Patent Document 6), and an LSI and a display utilizing the characteristics have been reported (see Non-Patent Document 7 and Non-Patent Document 8).

### REFERENCES

### Patent Documents

[Patent Document 1] Japanese Published Patent Application No. 2012-257187
[Patent Document 2] Japanese Published Patent Application No. 2011-228622
[Patent Document 3] Japanese Published Patent Application No. 2013-016782

### Non-Patent Documents

[Non-Patent Document 1] S. Yamazaki et al., “SID Symposium Digest of Technical Papers”, 2012, volume 43, issue 1, pp. 183-186.
[Non-Patent Document 2] S. Yamazaki et al., “Japanese Journal of Applied Physics”, 2014, volume 53, Number 4S, pp. 04ED18-1-04ED18-10.
[Non-Patent Document 3] S. Ito et al., “The Proceedings of AM-FPD′13 Digest of Technical Papers”, 2013, pp. 151-154.
[Non-Patent Document 4] S. Yamazaki et al., “ECS Journal of Solid State Science and Technology”, 2014, volume 3, issue 9, pp. Q3012-Q3022.
[Non-Patent Document 5] S. Yamazaki, “ECS Transactions”, 2014, volume 64, issue 10, pp. 155-164.
[Non-Patent Document 6] K. Kato et al., “Japanese Journal of Applied Physics”, 2012, volume 51, pp. 021201-1-021201-7.
[Non-Patent Document 7] S. Matsuda et al., “2015 Symposium on VLSI Technology Digest of Technical Papers”, 2015, pp. T216-T217.
[Non-Patent Document 8] S. Amano et al., “SID Symposium Digest of Technical Papers”, 2010, volume 41, issue 1, pp. 626-629.

### SUMMARY OF THE INVENTION

### Problems to be Solved by the Invention

In Patent Document 2, when the resistance of a source region and a drain region is reduced, a metal film is formed over the source region and the drain region and heat treatment is performed on the metal film in an oxygen atmosphere. By performing the heat treatment, a constituent element of the metal film enters the source region and the drain region of an oxide semiconductor film as a dopant, whereby the resistance is reduced. By performing the heat treatment in an oxygen atmosphere, the conductive film is oxidized, whereby the resistance of the conductive film is increased. Note that since the heat treatment is performed in an oxygen atmosphere, the metal film has a weak effect of extracting oxygen from the oxide semiconductor film.

Patent Document 2 discloses the oxygen concentration in a channel formation region, and does not refer to the concentration of impurities such as water and hydrogen. That is, purification of the channel formation region (a reduction in impurities such as water and hydrogen, typically, dehydration or dehydrogenation) is not performed; thus, there is a problem in that a transistor tends to have normally-on characteristics. Note that normally-on characteristics of a transistor mean a state where a channel exists and a current flows through the transistor without application of a voltage to a gate. In contrast, normally-off characteristics of a transistor mean a state where a current does not flow through the transistor without application of a voltage to a gate.

In view of the above problems, an object of one embodiment of the present invention is to provide a semiconductor device having favorable electrical characteristics by stably reducing the resistance of a source region and a drain region of a transistor and purifying a channel formation region.

Another object of one embodiment of the present invention is to provide a semiconductor device that can be miniaturized or highly integrated. An object of one embodiment of the present invention is to provide a semiconductor device having favorable electrical characteristics. An object of one embodiment of the present invention is to provide a semiconductor device with high productivity.

An object of one embodiment of the present invention is to provide a semiconductor device capable of retaining data for a long time. An object of one embodiment of the present invention is to provide a semiconductor device capable of high-speed data writing. An object of one embodiment of the present invention is to provide a semiconductor device with high design flexibility. An object of one embodiment of the present invention is to provide a semiconductor device in which power consumption can be reduced. An object of one embodiment of the present invention is to provide a novel semiconductor device.

Note that the descriptions of these objects do not disturb the existence of other objects. In one embodiment of the present invention, there is no need to achieve all the objects. Objects other than these will be apparent from the descriptions of the specification, the drawings, the claims, and the like, and objects other than these can be derived from the descriptions of the specification, the drawings, the claims, and the like.

### Means for Solving the Problems

In one embodiment of the present invention, a first insulator is formed; a second insulator is formed over the first insulator; an island-shaped oxide is formed over the second insulator; a stacked body of a third insulator and a conductor is formed over the oxide; the resistance of the oxide is selectively reduced by forming a film containing a metal element over the oxide and the stacked body; after a fourth insulator is formed over the second insulator, the oxide, and the stacked body, an opening portion exposing the second insulator is formed in the fourth insulator; a fifth insulator is formed over the second insulator and the fourth insulator; and the fifth insulator is subjected to oxygen introduction treatment.

In the above, the oxygen introduction treatment is performed by an ion implantation method.

In the above, the oxygen introduction treatment is performed in such a manner that a sixth insulator is deposited over the fifth insulator by a sputtering method using an oxygen gas.

In the above, the sixth insulator has a function of inhibiting diffusion of oxygen.

In the above, the first insulator has a function of inhibiting diffusion of oxygen.

In the above, the fourth insulator is formed after the film containing the metal element is removed.

In the above, the metal element is at least one of aluminum, ruthenium, titanium, tantalum, chromium, and tungsten.

### Effect of the Invention

According to one embodiment of the present invention, a semiconductor device having favorable electrical characteristics can be provided. According to one embodiment of the present invention, a semiconductor device that can be miniaturized or highly integrated can be provided. According to one embodiment of the present invention, a semiconductor device with high productivity can be provided.

Alternatively, a semiconductor device capable of retaining data for a long time can be provided. Alternatively, a semiconductor device capable of high-speed data writing can be provided. Alternatively, a semiconductor device with high design flexibility can be provided. Alternatively, a semiconductor device in which power consumption can be reduced can be provided. Alternatively, a novel semiconductor device can be provided.

Note that the descriptions of these effects do not disturb the existence of other effects. Note that one embodiment of the present invention does not necessarily have all of these effects. Effects other than these will be apparent from the descriptions of the specification, the drawings, the claims, and the like, and effects other than these can be derived from the descriptions of the specification, the drawings, the claims, and the like.

### BRIEF DESCRIPTION OF THE DRAWINGS

FIG. 1 A top view and cross-sectional views illustrating a semiconductor device of one embodiment of the present invention.

FIG. 2 A cross-sectional view illustrating a semiconductor device of one embodiment of the present invention.

FIG. 3 A top view and cross-sectional views illustrating a method for manufacturing a semiconductor device of one embodiment of the present invention.

FIG. 4 A top view and cross-sectional views illustrating a method for manufacturing a semiconductor device of one embodiment of the present invention.

FIG. 5 A top view and cross-sectional views illustrating a method for manufacturing a semiconductor device of one embodiment of the present invention.

FIG. 6 A top view and cross-sectional views illustrating a method for manufacturing a semiconductor device of one embodiment of the present invention.

FIG. 7 A top view and cross-sectional views illustrating a method for manufacturing a semiconductor device of one embodiment of the present invention.

FIG. 8 A top view and cross-sectional views illustrating a method for manufacturing a semiconductor device of one embodiment of the present invention.

FIG. 9 A top view and cross-sectional views illustrating a method for manufacturing a semiconductor device of one embodiment of the present invention.

FIG. 10 A top view and cross-sectional views illustrating a method for manufacturing a semiconductor device of one embodiment of the present invention.

FIG. 11 A top view and cross-sectional views illustrating a method for manufacturing a semiconductor device of one embodiment of the present invention.

FIG. 12 A top view and cross-sectional views illustrating a method for manufacturing a semiconductor device of one embodiment of the present invention.

FIG. 13 A top view and cross-sectional views illustrating a method for manufacturing a semiconductor device of one embodiment of the present invention.

FIG. 14 A top view and cross-sectional views illustrating a semiconductor device of one embodiment of the present invention.

FIG. 15 A top view and cross-sectional views illustrating a semiconductor device of one embodiment of the present invention.

FIG. 16 A top view and a cross-sectional view illustrating a structure of a memory device of one embodiment of the present invention.

FIG. 17 A circuit diagram illustrating a structure of a memory device of one embodiment of the present invention.

FIG. 18 A cross-sectional view illustrating a structure of a memory device of one embodiment of the present invention.

FIG. 19 A cross-sectional view illustrating a structure of a memory device of one embodiment of the present invention.

FIG. 20 A circuit diagram illustrating a structure example of an inverter circuit and a timing chart showing its operation example.

FIG. 21 A block diagram illustrating a structure example of a memory device of one embodiment of the present invention.

FIG. 22 Circuit diagrams each illustrating a structure example of a memory device of one embodiment of the present invention.

FIG. 23 A circuit diagram illustrating a structure example of a memory device of one embodiment of the present invention.

FIG. 24 A block diagram illustrating a structure example of a memory device of one embodiment of the present invention.

FIG. 25 A block diagram and a circuit diagram illustrating a structure example of a memory device of one embodiment of the present invention.

FIG. 26 Block diagrams illustrating a structure example of a semiconductor device of one embodiment of the present invention.

FIG. 27 A block diagram and a circuit diagram illustrating a structure example of a semiconductor device of one embodiment of the present invention and a timing chart showing an operation example of the semiconductor device.

FIG. 28 A block diagram illustrating a structure example of a semiconductor device of one embodiment of the present invention.

FIG. 29 A circuit diagram illustrating a structure example of a semiconductor device of one embodiment of the present invention and a timing chart showing an operation example of the semiconductor device.

FIG. 30 A block diagram illustrating a configuration example of an AI system of one embodiment of the present invention.

FIG. 31 Block diagrams illustrating application examples of an AI system of one embodiment of the present invention.

FIG. 32 A schematic perspective view illustrating a configuration example of an IC incorporating an AI system of one embodiment of the present invention.

FIG. 33 Diagrams each illustrating an electronic device of one embodiment of the present invention.

FIG. 34 Diagrams illustrating a cross section of each sample of Example and TDS measurement result of each sample.

FIG. 35 A diagram showing stress time dependence of AVsh of each sample of Example.

### MODE FOR CARRYING OUT THE INVENTION

Hereinafter, embodiments will be described with reference to drawings. However, the embodiments can be implemented with many different modes, and it will be readily appreciated by those skilled in the art that modes and details thereof can be changed in various ways without departing from the spirit and scope thereof. Thus, the present invention should not be interpreted as being limited to the following descriptions of the embodiments.

In the drawings, the size, the layer thickness, or the region is exaggerated for clarity in some cases. Therefore, the size, the layer thickness, or the region is not limited to the scale. Note that the drawings are schematic views showing ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. Note that in the drawings, the same reference numerals are used, in different drawings, for the same portions or portions having similar functions, and repeated description thereof is omitted in some cases. Furthermore, the same hatch pattern is used for the portions having similar functions, and the portions are not especially denoted by reference numerals in some cases.

Furthermore, especially in a top view (also referred to as a “plan view”), a perspective view, or the like, the description of some components might be omitted for easy understanding of the invention. Furthermore, the description of some hidden lines and the like might be omitted.

Note that in this specification and the like, the ordinal numbers such as first and second are used for convenience and do not denote the order of steps or the stacking order of layers. Therefore, for example, description can be made even when “first” is replaced with “second”, “third”, or the like, as appropriate. In addition, the ordinal numbers in this specification and the like do not correspond to the ordinal numbers which are used to specify one embodiment of the present invention in some cases.

In this specification, terms for describing arrangement, such as “over” and “under”, are used for convenience in describing a positional relationship between components with reference to drawings. Furthermore, the positional relationship between components is changed as appropriate in accordance with a direction in which each component is described. Thus, without limitation to terms described in this specification, the description can be changed appropriately depending on the situation.

In the case where there is an explicit description, X and Y are connected, in this specification and the like, for example, the case where X and Y are electrically connected, the case where X and Y are functionally connected, and the case where X and Y are directly connected are disclosed in this specification and the like. Accordingly, without being limited to a predetermined connection relationship, for example, a connection relationship shown in drawings or texts, a connection relationship other than one shown in drawings or texts is included in the drawings or the texts.

Here, X and Y denote an object (e.g., a device, an element, a circuit, a wiring, an electrode, a terminal, a conductive film, or a layer).

An example of the case where X and Y are directly connected is the case where an element that allows electrical connection between X and Y (e.g., a switch, a transistor, a capacitor, an inductor, a resistor, a diode, a display element, a light-emitting element, or a load) is not connected between X and Y, and is the case where X and Y are connected without an element that allows electrical connection between X and Y (e.g., a switch, a transistor, a capacitor, an inductor, a resistor, a diode, a display element, a light-emitting element, or a load) placed therebetween.

In an example of the case where X and Y are electrically connected, one or more elements that allow electrical connection between X and Y (e.g., a switch, a transistor, a capacitor, an inductor, a resistor, a diode, a display element, a light-emitting element, or a load) can be connected between X and Y. Note that a switch has a function of being controlled to be turned on or off That is, a switch has a function of being in a conduction state (on state) or non-conduction state (off state) to control whether or not current flows. Alternatively, the switch has a function of selecting and changing a current path. Note that the case where X and Y are electrically connected includes the case where X and Y are directly connected.

An example of the case where X and Y are functionally connected is the case where one or more circuits that allow functional connection between X and Y (for example, a logic circuit (an inverter, a NAND circuit, a NOR circuit, or the like), a signal converter circuit (a DA converter circuit, an AD converter circuit, a gamma correction circuit, or the like), a potential level converter circuit (a power supply circuit (for example, a step-up circuit, a step-down circuit, or the like), a level shifter circuit for changing the potential level of a signal, or the like), a voltage source, a current source, a switching circuit, an amplifier circuit (a circuit capable of increasing signal amplitude, the amount of current, or the like, an operational amplifier, a differential amplifier circuit, a source follower circuit, a buffer circuit, or the like), a signal generator circuit, a memory circuit, a control circuit, or the like) can be connected between X and Y. Note that even if another circuit is sandwiched between X and Y, for example, X and Y are regarded as being functionally connected when a signal output from X is transmitted to Y. Note that the case where X and Y are functionally connected includes the case where X and Y are directly connected and the case where X and Y are electrically connected.

In this specification and the like, a transistor is an element having at least three terminals of a gate, a drain, and a source. The transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when a transistor of opposite polarity is employed or a direction of current flow is changed in circuit operation, for example. Therefore, the terms “source” and “drain” can be used interchangeably in this specification and the like in some cases.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a region where a channel is formed in a top view of the transistor. Note that in one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

A channel width refers to, for example, the length of a portion where a source and a drain face each other in a region where a semiconductor (or a portion where current flows in a semiconductor when a transistor is in an on state) and a gate electrode overlap with each other, or a region where a channel is formed. In one transistor, channel widths in all regions are not necessarily the same. In other words, the channel width of one transistor is not fixed to one value in some cases. Therefore, in this specification, the channel width is any one of values, the maximum value, the minimum value, or the average value in a region where a channel is formed.

Note that depending on transistor structures, a channel width in a region where a channel is actually formed (hereinafter, also referred to as an “effective channel width”) is different from a channel width shown in a top view of a transistor (hereinafter, also referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is increased in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

Thus, in this specification, an apparent channel width is referred to as a “surrounded channel width (SCW)” in some cases. Furthermore, in this specification, the simple term “channel width” refers to a surrounded channel width or an apparent channel width in some cases. Alternatively, in this specification, the simple term “channel width” refers to an effective channel width in some cases. Note that values of a channel length, a channel width, an effective channel width, an apparent channel width, a surrounded channel width, and the like can be determined, for example, by analyzing a cross-sectional TEM image and the like.

Note that an impurity in a semiconductor refers to, for example, elements other than the main components of a semiconductor. For example, an element with a concentration of lower than 0.1 atomic % can be regarded as an impurity. When an impurity is contained, for example, DOS (Density of States) in a semiconductor may be increased or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. In the case of an oxide semiconductor, water also functions as an impurity in some cases. In addition, in the case of an oxide semiconductor, oxygen vacancies are formed by entry of impurities, for example. Furthermore, in the case where the semiconductor is silicon, examples of an impurity which changes the characteristics of the semiconductor include oxygen, Group 1 elements except hydrogen, Group 2 elements, Group 13 elements, and Group 15 elements.

Note that in this specification and the like, “silicon oxynitride film” is a film in which oxygen content is higher than nitrogen content in its composition. A silicon oxynitride film preferably contains, for example, oxygen, nitrogen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively. Moreover, “silicon nitride oxide film” is a film in which nitrogen content is higher than oxygen content in its composition. A silicon nitride oxide film preferably contains nitrogen, oxygen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively.

Moreover, in this specification and the like, the term “film” and the term “layer” can be interchanged with each other. For example, the term “conductive layer” can be changed into the term “conductive film” in some cases. For another example, the term “insulating film” can be changed into the term “insulating layer” in some cases.

Furthermore, unless otherwise specified, transistors described in this specification and the like are field-effect transistors. Furthermore, unless otherwise specified, transistors described in this specification and the like are n-channel transistors. Thus, unless otherwise specified, the threshold voltage (also referred to as “Vₜₕ”) is higher than 0 V.

In this specification and the like, “parallel” indicates a state where the angle formed between two straight lines is greater than or equal to −10° and less than or equal to 10°. Thus, the case where the angle is greater than or equal to −5° and less than or equal to 5° is also included. Furthermore, the term “substantially parallel” indicates a state where the angle formed between two straight lines is greater than or equal to −30° and less than or equal to 30°. Moreover, “perpendicular” indicates a state where the angle formed between two straight lines is greater than or equal to 80° and less than or equal to 100°. Thus, the case where the angle is greater than or equal to 85° and less than or equal to 95° is also included. In addition, “substantially perpendicular” indicates a state where the angle formed between two straight lines is greater than or equal to 60° and less than or equal to 120°.

Furthermore, in this specification, in the case where a crystal is a trigonal crystal or a rhombohedral crystal, the crystal is regarded as a hexagonal crystal system.

Note that in this specification, a barrier film means a film having a function of inhibiting the passage of oxygen and impurities such as hydrogen, and the barrier film having conductivity is referred to as a conductive barrier film in some cases.

In this specification and the like, a metal oxide means an oxide of a metal in a broad sense. Metal oxides are classified into an oxide insulator, an oxide conductor (including a transparent oxide conductor), an oxide semiconductor (also simply referred to as an OS), and the like. For example, when a metal oxide is used in an active layer of a transistor, the metal oxide is called an oxide semiconductor in some cases. That is, in the case where an OS FET is stated, it can also be referred to as a transistor including an oxide or an oxide semiconductor.

In this specification and the like, “normally off” means that current per micrometer of channel width flowing in a transistor when a voltage is not applied to a gate or the gate is supplied with a ground potential is 1×10⁻²⁰ A or lower at room temperature, 1×10⁻¹⁸ A or lower at 85° C., or 1×10⁻¹⁶A or lower at 125° C.

### Embodiment 1

An example of a semiconductor device including a transistor 200 of one embodiment of the present invention will be described below.

### <Structure Example of Semiconductor Device>

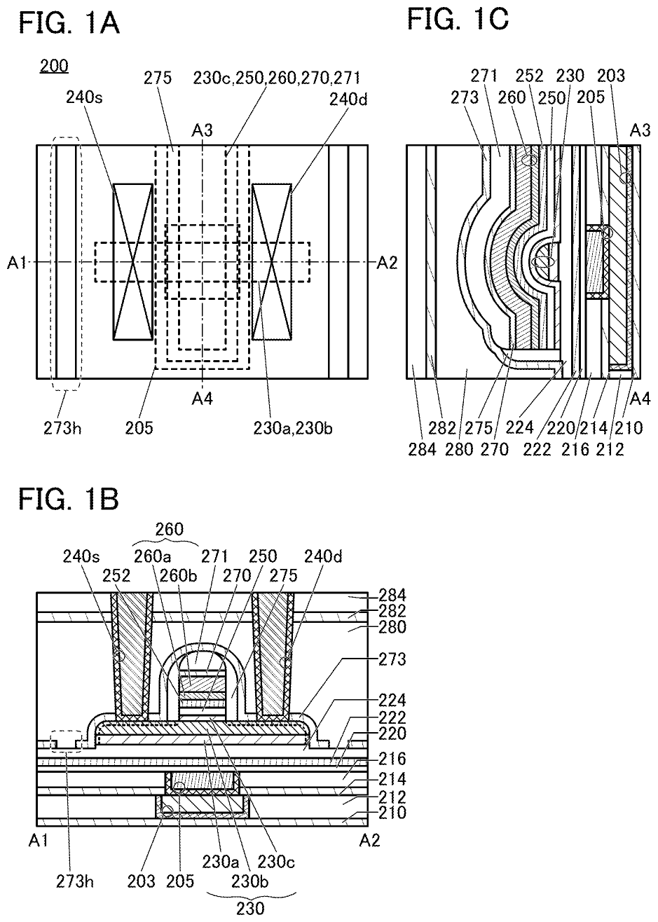

FIG. 1(A), FIG. 1(B), and FIG. 1(C) are a top view and cross-sectional views of the transistor 200 of one embodiment of the present invention and the periphery of the transistor 200.

FIG. 1(A) is a top view of the semiconductor device including the transistor 200. FIG. 1(B) and FIG. 1(C) are cross-sectional views of the semiconductor device. Here, FIG. 1(B) is a cross-sectional view of a portion indicated by dashed-dotted line A1-A2 in FIG. 1(A). FIG. 1(C) is a cross-sectional view of a portion indicated by dashed-dotted line A3-A4 in FIG. 1(A). For clarity of the drawing, some components are not illustrated in the top view of FIG. 1(A).

The semiconductor device of one embodiment of the present invention includes the transistor 200, and an insulator 210, an insulator 212, an insulator 280, an insulator 282, and an insulator 284 functioning as interlayer films. The semiconductor device also includes a conductor 203 functioning as a wiring and a conductor 240 (a conductor 240s and a conductor 240d) functioning as a plug, which are electrically connected to the transistor 200.

Note that in the conductor 203, a first conductor of the conductor 203 is formed in contact with an inner wall of an opening in the insulator 212 and a second conductor of the conductor 203 is formed on the inner side. Here, the level of a top surface of the conductor 203 and the level of a top surface of the insulator 212 can be substantially the same. Although the structure in which the first conductor of the conductor 203 and the second conductor of the conductor 203 are stacked is described in this embodiment, the present invention is not limited thereto. For example, a structure may be employed in which the conductor 203 of a single layer or a stacked-layer structure of three or more layers is provided. Note that in the case where a structure body has a stacked-layer structure, the layers may be distinguished by ordinal numbers corresponding to the formation order.

The conductor 240 is formed in contact with an inner wall of an opening in the insulator 280, the insulator 282, and the insulator 284. Here, the level of a top surface of the conductor 240 and the level of a top surface of the insulator 284 can be substantially the same. Although the structure in which the conductor 240 has a stacked-layer structure of two layers is described in this embodiment, the present invention is not limited thereto. For example, the conductor 240 may be a single layer or have a stacked-layer structure of three or more layers.

### [Transistor 200]

As illustrated in FIG. 1, the transistor 200 includes an insulator 214 and an insulator 216 positioned over a substrate (not illustrated); a conductor 205 positioned to be embedded in the insulator 214 and the insulator 216; an insulator 220 positioned over the insulator 216 and the conductor 205; an insulator 222 positioned over the insulator 220; an insulator 224 positioned over the insulator 222; an oxide 230 (an oxide 230a, an oxide 230b, and an oxide 230c) positioned over the insulator 224; an insulator 250 positioned over the oxide 230; a conductor 260 (a conductor 260a, a conductor 260b, and a conductor 260c) positioned over the insulator 250; an insulator 270 positioned over the conductor 260; an insulator 271 positioned over the insulator 270; an insulator 275 positioned in contact with at least side surfaces of the oxide 230c, the insulator 250, and the conductor 260; and an insulator 273 positioned over the oxide 230.

Although the transistor 200 illustrated in FIG. 1 has a structure in which three layers of the oxide 230a, the oxide 230b, and the oxide 230c are stacked, the present invention is not limited thereto. For example, a structure may be employed in which a single layer of the oxide 230b, a two-layer structure of the oxide 230b and the oxide 230a, a two-layer structure of the oxide 230b and the oxide 230c, or a stacked-layer structure of four or more layers is provided. Similarly, although the transistor 200 has a structure in which the conductor 260a and the conductor 260b are stacked, the present invention is not limited thereto.

In the transistor 200, a metal oxide functioning as an oxide semiconductor (hereinafter also referred to as an oxide semiconductor) is preferably used for the oxide 230 (the oxide 230a, the oxide 230b, and the oxide 230c), which includes a region where a channel is formed (hereinafter also referred to as a channel formation region).

For the oxide 230, a metal oxide such as an In-M-Zn oxide (an element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used. Alternatively, for the oxide 230, an In—Ga oxide or an In—Zn oxide may be used.

The transistor 200 using an oxide semiconductor in its channel formation region has an extremely low leakage current in a non-conduction state; thus, a semiconductor device with low power consumption can be provided. An oxide semiconductor can be deposited by a sputtering method or the like, and thus can be used for the transistor 200 constituting a highly integrated semiconductor device.

In contrast, a transistor using an oxide semiconductor is likely to have normally-on characteristics (characteristics in that a channel exists without voltage application to a gate electrode and current flows in a transistor) owing to an impurity and an oxygen vacancy in the oxide semiconductor that affect the electrical characteristics. In the case where the transistor is driven in the state where excess oxygen exceeding the proper amount is included in the oxide semiconductor, the valence of the excess oxygen atoms is changed and the electrical characteristics of the transistor are changed, so that reliability is decreased in some cases.

Therefore, it is preferable to use, as the oxide semiconductor used in the transistor, a highly purified intrinsic oxide semiconductor that does not include an impurity, an oxygen vacancy, and oxygen in excess of oxygen in the stoichiometric composition (hereinafter, also referred to as excess oxygen).

However, in the transistor using the oxide semiconductor, oxygen in the oxide semiconductor is gradually absorbed by a conductor included in the transistor or a conductor used for a plug or a wiring connected to the transistor, and an oxygen vacancy is generated as one of changes over time in some cases.

Accordingly, it is preferable to provide a structure body including an excess-oxygen region in the vicinity of the oxide semiconductor of the transistor. Excess oxygen of the structure body including the excess-oxygen region is diffused into oxygen vacancies generated in the oxide semiconductor, whereby the oxygen vacancies can be compensated for. On the other hand, in the case where the amount of diffused excess oxygen of the structure body including the excess-oxygen region exceeds the proper value, the oversupplied oxygen might cause a change in the structure of the oxide semiconductor.

Thus, an insulator containing oxygen is used for the insulator 280 functioning as an interlayer film provided over the transistor 200 and the insulator 224 provided in contact with the insulator 280 and the oxide 230. It is particularly preferable to use, for the insulator 280, an oxide that contains more oxygen than oxygen in the stoichiometric composition. That is, in the insulator 280, a region in which oxygen in excess of that in the stoichiometric composition exists (hereinafter also referred to as an excess-oxygen region) is preferably formed.

In order to provide the excess-oxygen region in the insulator 280, oxygen (including at least oxygen radicals, oxygen atoms, or oxygen ions) is introduced into the insulator 280, whereby a region containing oxygen in excess is formed.

For example, oxygen ions can be introduced into the insulator 280 by an ion implantation method, an ion doping method, a plasma immersion ion implantation method, plasma treatment, or the like. For example, as the oxygen introduction treatment, the treatment may be performed by an ion implantation method using a gas containing oxygen. As the gas containing oxygen, oxygen, dinitrogen monoxide, nitrogen dioxide, carbon dioxide, carbon monoxide, or the like can be used. A rare gas may be contained in the gas containing oxygen in the oxygen introduction treatment; for example, a mixed gas of carbon dioxide, hydrogen, and argon can be used.

In particular, treatment conditions can be set as appropriate when an ion implantation method, an ion doping method, a plasma immersion ion implantation method, plasma treatment, or the like is used. Thus, the amount of excess oxygen included in the insulator 280 can be adjusted or controlled depending on the shape, size, integration, or layout of the transistor.

A method for stacking oxides over the insulator 280 using a sputtering apparatus is given as an example of the oxygen introduction treatment. For example, when the deposition in an oxygen gas atmosphere is performed using a sputtering apparatus as a means for depositing the insulator 282, oxygen can be introduced into the insulator 280 while the insulator 282 is deposited.

During the deposition by a sputtering method, ions and sputtered particles exist between a target and a substrate. For example, a potential E₀ is supplied to the target, to which a power source is connected. A potential E₁ such as a ground potential is supplied to the substrate. Note that the substrate may be electrically floating. In addition, there is a region at a potential E₂ between the target and the substrate. The relationship between the potentials is E₂>E₁>E₀.

The ions in plasma are accelerated by a potential difference E₂−E₀ and collide with the target, whereby the sputtered particles are ejected from the target. These sputtered particles are attached on a deposition surface and deposited thereover; as a result, a film is deposited. Some ions recoil by the target and might pass through the deposited film as recoil ions, and be taken into the insulator 280 in contact with the deposition surface. The ions in the plasma are accelerated by a potential difference E₂−E₁ and collide with the deposition surface. At this time, some ions reach the inside of the insulator 280. The ions are taken into the insulator 280, so that a region into which the ions are taken is formed in the insulator 280. That is, an excess-oxygen region is formed in the insulator 280 in the case where the ions contain oxygen.

In contrast, the insulator 224 in contact with the oxide 230 is preferably an insulator that diffuses oxygen. In addition, the insulator 273 that inhibits diffusion of oxygen is provided between the insulator 280 and the insulator 224. Note that the insulator 273 includes an opening portion 273h, and the insulator 280 is in contact with the insulator 224 through the opening portion 273h. The opening portion 273h may be designed as appropriate depending on the shape, size, integration, or layout of the transistor 200. For example, the opening portion 273h may be a circular or polygonal hole, groove, slit, or the like.

That is, when the excess oxygen contained in the insulator 280 reduces the oxygen vacancies in the oxide 230 through the insulator 224, a transistor having normally-off characteristics (electric characteristics in that the threshold voltage is positive) and a high reliability can be provided. Furthermore, by providing the insulator 273 including the opening portion 273h, the excess oxygen contained in the insulator 280 can be inhibited from being diffused into the oxide 230 at a value exceeding the proper value.

The opening portion 273h included in the insulator 273 may be provided so as to expose the insulator 275 in contact with the insulator 250, for example. The insulator 280 and the insulator 275 are in contact with each other through the opening portion 273h, whereby the excess oxygen in the insulator 280 is diffused into the insulator 275 and the insulator 250 to be supplied to the oxide 230. The excess oxygen that reaches the oxide 230 compensates for the oxygen vacancies generated in the oxide 230, so that the transistor 200 has normally-off characteristics. Furthermore, the compensation of the oxygen vacancies generated in the oxide 230 can improve the reliability of the transistor 200.

In addition, the insulator 282 is provided over the insulator 280 to supply oxygen in the excess-oxygen region of the insulator 280 efficiently to the oxide 230. That is, when the insulator 282 has a barrier property against oxygen, oxygen in the excess-oxygen region can be supplied to the oxide 230 efficiently without being diffused to the outside of the transistor 200. Note that a barrier property refers to a function of inhibiting diffusion of impurities typified by hydrogen and water, oxygen, or the like.

The insulator 222 having a barrier property against oxygen may be provided below the insulator 224. With the insulator 222, oxygen in the excess-oxygen region can be supplied to the oxide 230 efficiently without being diffused to the outside of the transistor 200.

Furthermore, when a metal element such as aluminum, ruthenium, titanium, tantalum, chromium, or tungsten is added to the oxide semiconductor in addition to the constituent element of the oxide semiconductor, the resistance is reduced in some cases. Selective addition of a metal element and impurity elements such as hydrogen and nitrogen to the oxide semiconductor allows a high-resistance region and a low-resistance region to be provided in the oxide semiconductor. In other words, when the resistance of the oxide 230 is selectively reduced, a region functioning as a semiconductor having a low carrier density and a low-resistance region functioning as a source region or a drain region having a high carrier density can be provided in the island-shaped oxide 230.

To add the metal element to the oxide semiconductor, for example, a metal film containing the metal element, a nitride film containing the metal element, or an oxide film containing the metal element is preferably provided over the oxide semiconductor.

After the metal film, the nitride film containing the metal element, or the oxide film containing the metal element is provided over the oxide semiconductor, heat treatment is preferably performed in an atmosphere containing nitrogen. By the heat treatment in an atmosphere containing nitrogen, nitrogen or the metal element that is the component of the metal film, the nitride film containing the metal element, or the oxide film containing the metal element diffuses to the oxide semiconductor from the film, and thus the resistance can be reduced. The metal element added to the oxide semiconductor is brought into a relatively stable state when the oxide semiconductor and the metal element form a metal compound; thus, a highly reliable semiconductor device can be provided.

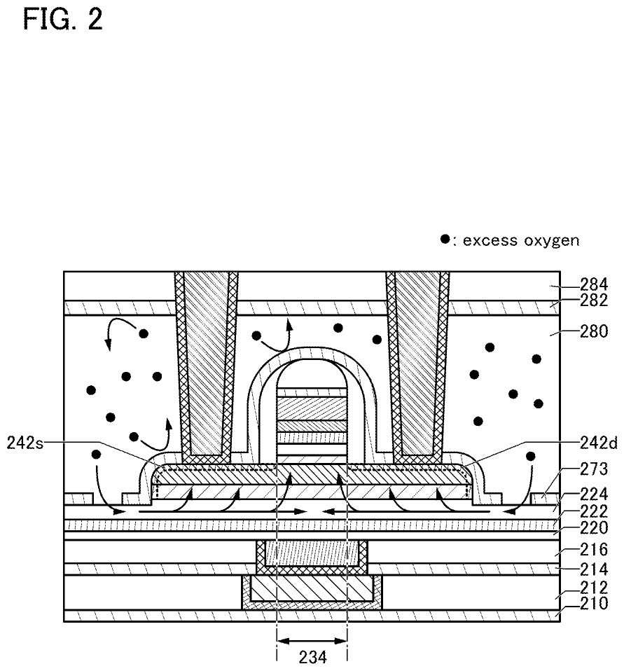

Here, FIG. 2 is an enlarged view of FIG. 1(B). In FIG. 2, black dots indicate excess oxygen and arrows indicate possible diffusion paths of excess oxygen. The insulator 273 includes the opening portion 273h in a region overlapping with the insulator 224. The excess oxygen contained in the insulator 280 passes through the opening portion 273h of the insulator 273 and is diffused into the oxide 230.

As illustrated in FIG. 2, the oxide 230 includes a region 234 functioning as a channel formation region of the transistor and a region 242 (a region 242s and a region 242d) functioning as a source region or a drain region.

The region 242 functioning as the source region or the drain region is a region with reduced resistance. The region 234 functioning as the channel formation region is a high-resistance region whose carrier density is lower than that of the region 242 functioning as the source region or the drain region.

The concentration of at least one of the metal element and the impurity elements such as hydrogen and nitrogen in the region 242 is preferably higher than that in the region 234. For example, in addition to the oxide 230, the region 242 preferably contains one or a plurality of metal elements selected from aluminum, ruthenium, titanium, tantalum, tungsten, chromium, and the like.

In order to selectively form the region 242 in the oxide 230, a film containing a metal element is provided over and in contact with the oxide 230 using, as a mask, the conductor 260 functioning as a gate, for example. Note that as the film containing the metal element, a metal film, an oxide film containing a metal element, or a nitride film containing a metal element can be used. Addition of the metal element to a region in contact with the film containing the metal element in the oxide 230 can form a metal compound in the oxide 230, and the resistance of the region 242 can be reduced.

A compound layer may be formed at an interface between the oxide 230 and the film containing the metal element. Note that the compound layer is a layer containing a metal compound containing a component of the film containing the metal element and a component of the oxide 230. For example, as the compound layer, a layer in which the metal element in the oxide 230 and the added metal element are alloyed may be formed.

Note that the metal compound is not necessarily formed in the oxide 230. For example, the metal compound may be formed in the film containing the metal element. For example, it may be provided on a surface of the oxide 230 or a surface of the film containing the metal element, or in the compound layer formed at the interface between the film containing the metal element and the oxide 230.

Thus, in some cases, the region 242 also includes a low-resistance region of the film containing the metal element, or a low-resistance region of the compound layer formed between the film containing the metal element and the oxide 230. In other words, in this specification, a region functioning as the source region or the drain region is the region 242.

As described above, in formation of the low-resistance region in the oxide 230, the resistance of the oxide 230 is reduced in a self-aligned manner with the use of the conductor 260 functioning as a gate electrode as a mask. Thus, when the plurality of transistors 200 are formed simultaneously, variations in electrical characteristics of the transistors can be reduced. The channel length of the transistor 200 depends on the width of the conductor 260; the transistor 200 can be miniaturized when the conductor 260 with the minimum feature width is used.

In the case where the film containing the metal element has a property of absorbing hydrogen, hydrogen in the oxide 230 is absorbed by the film. Thus, hydrogen, which is an impurity in the oxide 230, can be reduced. The film containing the metal element may be removed with hydrogen absorbed from the oxide 230 in a later step.

Note that the film containing the metal element is not necessarily removed. For example, in the case where the film containing the metal element is insulated and its resistance is increased, the film may remain. For example, the film containing the metal element is oxidized by oxygen absorbed from the oxide 230 to be an insulator, and the resistance is increased, in some cases. In that case, the film containing the metal element functions as an interlayer film in some cases.

For example, in the case where a region having conductivity remains in the film containing the metal element, heat treatment is performed for oxidation, whereby an insulator is obtained and the resistance is increased. The heat treatment is preferably performed in an oxidation atmosphere, for example. In the case where there is a structure body containing oxygen in the vicinity of the film containing the metal element, heat treatment may cause a reaction of the film containing the metal element with oxygen contained in the structure body and oxidation.

The film containing the metal element and remaining as an insulator can function as an interlayer film. In the case of the above structure, the film containing the metal element is provided to have a thickness that allows the film to become an insulator in a later process. Note that in the case where the heat treatment is performed in the above oxidation atmosphere, it is suitably performed after heat treatment in an atmosphere containing nitrogen is performed once in a state where the oxide 230 and the film containing the metal element are in contact with each other. When heat treatment is performed in an atmosphere containing nitrogen in advance, oxygen in the oxide 230 is easily diffused into the film containing the metal element.

The excess oxygen contained in the insulator 280 passes through the opening portion 273h of the insulator 273, and is supplied to the oxide 230 through the insulator 224. The excess oxygen is diffused to the oxide 230 from a surface where the oxide 230 is in contact with the insulator 224 and the oxygen vacancies generated in the oxide 230 are reduced; thus, the transistor 200 has normally-off characteristics. Furthermore, the oxygen vacancies generated in the oxide 230 are compensated for, whereby the reliability of the transistor 200 can be improved.

Note that the oxide 230 and the insulator 280 are sealed by the insulator 282 and the insulator 220, whereby the excess oxygen contained in the insulator 280 is supplied to the oxide 230 efficiently. When the insulator 273 including the opening portion 273h has a barrier property against oxygen, oversupply of oxygen to the oxide 230 and the insulator in contact with the oxide 230 can be suppressed.

Since the metal element is added, the low-resistance region 242 provided in the oxide 230 is stable, and can keep its low resistance even when the oxygen vacancies in the oxide 230 are reduced.

Although the region 234 and the region 242 are formed in the oxide 230b in FIG. 2, it is not limited thereto. These regions may also be formed in the oxide 230a and the oxide 230c, for example. Although boundaries between the regions are illustrated as being substantially perpendicular to the top surface of the oxide 230 in FIG. 2, this embodiment is not limited thereto. For example, in some cases, each region projects to the conductor 260 side in the vicinity of a surface of the oxide 230b, and recedes to the conductor 240s side or the conductor 240d side in the vicinity of a bottom surface of the oxide 230b.

In the oxide 230, the boundaries between the regions are difficult to clearly observe in some cases. The concentration of a metal element and an impurity element such as hydrogen and nitrogen, which are detected in each region, may be not only gradually changed between the regions, but also continuously changed (also referred to as gradation) in each region. That is, the region closer to the channel formation region preferably has a lower concentration of a metal element and an impurity element such as hydrogen and nitrogen.

With the above structure, a highly reliable transistor with a small variation in the electrical characteristics can be provided. Moreover, a transistor having electrical characteristics that meet the demand for the circuit design can be easily provided.

An oxide semiconductor can be deposited by a sputtering method or the like, and thus can be used for a transistor constituting a highly integrated semiconductor device. The transistor using an oxide semiconductor in its channel formation region has an extremely low leakage current (off-state current) in a non-conduction state; thus, a semiconductor device with low power consumption can be provided.

Accordingly, a semiconductor device including a transistor having a high on-state current can be provided. Alternatively, a semiconductor device including a transistor having a low off-state current can be provided. Alternatively, a semiconductor device that has small variation in electrical characteristics, stable electrical characteristics, and improved reliability can be provided.

The structure of the semiconductor device including the transistor 200 of one embodiment of the present invention will be described in detail below.

The conductor 203 extends in the channel width direction as illustrated in FIG. 1(A) and FIG. 1(C) and functions as a wiring that applies a potential to the conductor 205. Note that the conductor 203 is preferably provided to be embedded in the insulator 212.

The conductor 205 is positioned to overlap with the oxide 230 and the conductor 260. Moreover, the conductor 205 is preferably provided over and in contact with the conductor 203. Furthermore, the conductor 205 is preferably provided to be embedded in the insulator 214 and the insulator 216.

Here, the conductor 260 sometimes functions as a first gate (also referred to as a top gate) electrode. The conductor 205 sometimes functions as a second gate (also referred to as a bottom gate) electrode.

For example, when, in a transistor including a first gate electrode and a second gate electrode, different potentials are applied to the first gate electrode and the second gate electrode, the threshold voltage of the transistor can be controlled. For example, by applying a negative potential to the second gate electrode, the threshold voltage of the transistor can be higher than 0 V and the off-state current can be reduced. That is, when a negative potential is applied to the second gate electrode, a drain current when the potential applied to the first gate electrode is 0 V can be reduced.

When the conductor 205 is provided over the conductor 203, the distance between the conductor 203 and the conductor 260 functioning as the first gate electrode and the wiring can be designed as appropriate. That is, the insulator 214, the insulator 216, and the like are provided between the conductor 203 and the conductor 260, whereby a parasitic capacitance between the conductor 203 and the conductor 260 can be reduced, and the withstand voltage between the conductor 203 and the conductor 260 can be increased.

Moreover, the reduction in the parasitic capacitance between the conductor 203 and the conductor 260 can improve the switching speed of the transistor 200, so that the transistor 200 can have high frequency characteristics. The increase in the withstand voltage between the conductor 203 and the conductor 260 can improve the reliability of the transistor 200. Therefore, the film thicknesses of the insulator 214 and the insulator 216 are preferably large. Note that the extending direction of the conductor 203 is not limited to this; for example, the conductor 203 may extend in the channel length direction of the transistor 200.

Note that as illustrated in FIG. 1(A), the conductor 205 is positioned to overlap with the oxide 230 and the conductor 260. The conductor 205 is preferably larger than the region 234 of the oxide 230. As illustrated in FIG. 1(C), it is particularly preferable that the conductor 205 extend to a region outside an end portion of the region 234 of the oxide 230 that intersects with the channel width direction. That is, the conductor 205 and the conductor 260 preferably overlap with each other with the insulator therebetween on an outer side of the side surface of the oxide 230 in the channel width direction.

With the above structure, in the case where potentials are applied to the conductor 260 and the conductor 205, an electric field generated from the conductor 260 and an electric field generated from the conductor 205 are connected and can cover the channel formation region formed in the oxide 230. That is, the channel formation region in the region 234 can be electrically surrounded by the electric field of the conductor 260 functioning as the first gate electrode and the electric field of the conductor 205 functioning as the second gate electrode.

In the conductor 205, a first conductor is formed in contact with an inner wall of an opening in the insulator 214 and the insulator 216, and a second conductor is formed on the inner side. Here, the levels of top surfaces of the first conductor and the second conductor can be substantially the same as the level of a top surface of the insulator 216. Although the first conductor of the conductor 205 and the second conductor of the conductor 205 are stacked in the transistor 200, the present invention is not limited thereto. For example, the conductor 205 may have a single-layer structure or a stacked-layer structure of three or more layers.

The first conductor of the conductor 205 or the conductor 203 is preferably formed using a conductive material which has a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (through which the above impurity does not easily pass). Alternatively, it is preferable to use a conductive material which has a function of inhibiting diffusion of oxygen (e.g., at least one of oxygen atoms, oxygen molecules, and the like) (through which the above oxygen does not easily pass). Note that in this specification, a function of inhibiting diffusion of impurities or oxygen means a function of inhibiting diffusion of any one or all of the above impurities and the above oxygen.

When the first conductor of the conductor 205 or the conductor 203 has a function of inhibiting diffusion of oxygen, the conductivity of the second conductor of the conductor 205 or the conductor 203 can be inhibited from being lowered because of oxidization. As a conductive material having a function of inhibiting diffusion of oxygen, for example, tantalum, tantalum nitride, ruthenium, or ruthenium oxide is preferably used. Thus, the first conductor of the conductor 205 or the conductor 203 may be a single layer or a stacked layer of the above conductive materials. Thus, impurities such as water and hydrogen can be inhibited from being diffused into the transistor 200 side through the conductor 203 and the conductor 205.

A conductive material containing tungsten, copper, or aluminum as its main component is preferably used for the second conductor of the conductor 205. Note that the second conductor of the conductor 205 is a single layer in the drawing but may have a stacked-layer structure; for example, a stacked layer of any of the above conductive materials and titanium or titanium nitride may be employed.

The second conductor of the conductor 203 functions as a wiring and thus is preferably formed using a conductor having higher conductivity than the second conductor of the conductor 205. For example, a conductive material containing copper or aluminum as its main component can be used. The second conductor of the conductor 203 may have a stacked-layer structure; for example, a stacked layer of any of the above conductive materials and titanium or titanium nitride may be employed.

It is particularly preferable to use copper for the conductor 203. Copper is preferably used for a wiring and the like because of its small resistance. However, copper is easily diffused, and thus may deteriorate the electrical characteristics of the transistor 200 when diffused into the oxide 230. In view of the above, for example, a material through which copper is less likely to pass, such as aluminum oxide or hafnium oxide, is used for the insulator 214, whereby diffusion of copper can be inhibited.

The conductor 205, the insulator 214, and the insulator 216 are not necessarily provided. In this case, part of the conductor 203 can function as the second gate electrode.

The insulator 210 and the insulator 214 preferably function as a barrier insulating film that inhibits impurities such as water and hydrogen from entering the transistor 200 from the substrate side. Thus, the insulator 210 and the insulator 214 are preferably formed using an insulating material which has a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (through which the above impurity does not easily pass). Alternatively, it is preferable to use an insulating material which has a function of inhibiting diffusion of oxygen (e.g., at least one of oxygen atoms, oxygen molecules, and the like) (through which the above oxygen does not easily pass).

For example, it is preferable that aluminum oxide or the like be used for the insulator 210 and that silicon nitride or the like be used for the insulator 214. Thus, impurities such as hydrogen and water can be inhibited from being diffused into the transistor 200 side from the substrate side of the insulator 210 and the insulator 214. Alternatively, oxygen contained in the insulator 224 or the like can be inhibited from being diffused to the substrate side of the insulator 210 and the insulator 214.

For example, in the case where a structure is employed in which the conductor 205 is stacked over the conductor 203, the insulator 214 is provided between the conductor 203 and the conductor 205. Even when a metal that is easily diffused, such as copper, is used for the second conductor of the conductor 203, silicon nitride or the like provided as the insulator 214 can inhibit diffusion of the metal into a layer positioned over the insulator 214.

The permittivity of each of the insulator 212 and the insulator 216 functioning as interlayer films is preferably lower than that of the insulator 210 or the insulator 214. When a material with a low permittivity is used for an interlayer film, the parasitic capacitance generated between wirings can be reduced.

For example, a single layer or a stacked layer of an insulator such as silicon oxide, silicon oxynitride, silicon nitride oxide, aluminum oxide, hafnium oxide, tantalum oxide, zirconium oxide, lead zirconate titanate (PZT), strontium titanate (SrTiO₃), or (Ba,Sr)TiO₃ (BST) can be used as the insulator 212 and the insulator 216. Alternatively, to the insulator of these, aluminum oxide, bismuth oxide, germanium oxide, niobium oxide, silicon oxide, titanium oxide, tungsten oxide, yttrium oxide, or zirconium oxide may be added, for example. Alternatively, the insulator of these may be subjected to nitriding treatment. Silicon oxide, silicon oxynitride, or silicon nitride may be stacked over the insulator.

The insulator 220, the insulator 222, and the insulator 224 each have a function of a gate insulator.

For the insulator 224 in contact with the oxide 230, an insulator having a function of diffusing oxygen is preferably used. In contrast, the insulator 222 preferably has a function of inhibiting diffusion of oxygen. When the insulator 222 has a function of inhibiting diffusion of oxygen, excess oxygen diffused by the insulator 224 is not diffused to the insulator 220 side and thus can be supplied to the oxide 230 efficiently. Furthermore, the conductor 205 can be inhibited from reacting with oxygen in the excess-oxygen region included in the insulator 224.

Specifically, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used for the insulator 224, for example. In particular, silicon oxide and silicon oxynitride, which have thermal stability, are preferable.

For example, a single layer or a stacked layer of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) is preferably used for the insulator 222. With miniaturization and high integration of a transistor, a problem such as leakage current may arise because of a thinner gate insulator. When a high-k material is used for an insulator functioning as the gate insulator, a gate potential during operation of the transistor can be reduced while the physical thickness of the gate insulator is kept.

In particular, an insulator containing an oxide of one or both of aluminum and hafnium, which is an insulating material which has a function of inhibiting diffusion of impurities, oxygen, and the like (through which the above oxygen does not easily pass) is preferably used. As the insulator containing an oxide of one or both of aluminum and hafnium, aluminum oxide, hafnium oxide, an oxide containing aluminum and hafnium (hafnium aluminate), or the like is preferably used. In the case where the insulator 222 is formed using such a material, the insulator 222 functions as a layer that inhibits release of oxygen from the oxide 230 and entry of impurities such as hydrogen from the periphery of the transistor 200 into the oxide 230.

Alternatively, to the insulator of these, aluminum oxide, bismuth oxide, germanium oxide, niobium oxide, silicon oxide, titanium oxide, tungsten oxide, yttrium oxide, or zirconium oxide may be added, for example. Alternatively, the insulator of these may be subjected to nitriding treatment. Silicon oxide, silicon oxynitride, or silicon nitride may be stacked over the insulator.

It is preferable that the insulator 220 be thermally stable. For example, as silicon oxide and silicon oxynitride have thermal stability, a combination of an insulator with a high-k material and the insulator 220 allows the stacked-layer structure to be thermally stable and have a high dielectric constant.

Note that the insulator 220, the insulator 222, and the insulator 224 may each have a stacked-layer structure of two or more layers. In that case, without limitation to a stacked-layer structure formed of the same material, a stacked-layer structure formed of different materials may be employed.

The oxide 230 includes the oxide 230a, the oxide 230b over the oxide 230a, and the oxide 230c over the oxide 230b. When the oxide 230a is provided under the oxide 230b, impurities can be inhibited from being diffused into the oxide 230b from the components formed below the oxide 230a. When the oxide 230c is provided over the oxide 230b, impurities can be inhibited from being diffused to the oxide 230b from the components formed above the oxide 230c.

In addition, the oxide 230 preferably has a stacked-layer structure of oxides which differ in the atomic ratio of metal atoms. Specifically, the atomic ratio of the element M to constituent elements in the metal oxide used for the oxide 230a is preferably greater than the atomic ratio of the element M to constituent elements in the metal oxide used for the oxide 230b. Moreover, the atomic ratio of the element M to In in the metal oxide used for the oxide 230a is preferably greater than the atomic ratio of the element M to In in the metal oxide used for the oxide 230b. Furthermore, the atomic ratio of In to the element M in the metal oxide used for the oxide 230b is preferably greater than the atomic ratio of In to the element M in the metal oxide used for the oxide 230a. A metal oxide that can be used for the oxide 230a or the oxide 230b can be used for the oxide 230c.

The energy of the conduction band minimum of each of the oxide 230a and the oxide 230c is preferably higher than the energy of the conduction band minimum of the oxide 230b. In other words, the electron affinity of each of the oxide 230a and the oxide 230c is preferably smaller than the electron affinity of the oxide 230b.

The conduction band minimum gradually changes at a junction portion of the oxide 230a, the oxide 230b, and the oxide 230c. In other words, the conduction band minimum at a junction portion of the oxide 230a, the oxide 230b, and the oxide 230c continuously changes or is continuously connected. To obtain this, the density of defect states in a mixed layer formed at an interface between the oxide 230a and the oxide 230b, and an interface between the oxide 230b and the oxide 230c is preferably made low.

Specifically, when the oxide 230a and the oxide 230b or the oxide 230b and the oxide 230c contain the same element (as a main component) in addition to oxygen, a mixed layer with a low density of defect states can be formed. For example, in the case where the oxide 230b is an In—Ga—Zn oxide, an In—Ga—Zn oxide, a Ga—Zn oxide, gallium oxide, or the like is preferably used for the oxide 230a and the oxide 230c.

At this time, the oxide 230b serves as a main carrier path. When the oxide 230a and the oxide 230c have the above structure, the density of defect states at the interface between the oxide 230a and the oxide 230b and the interface between the oxide 230b and the oxide 230c can be made low. Thus, the influence of interface scattering on carrier conduction is small, and the transistor 200 can have a high on-state current.

The oxide 230 includes the region 234 and the low-resistance region 242. Note that when the transistor 200 is turned on, the region 242 functions as the source region or the drain region. At least part of the region 234 functions as the region where a channel is formed.

In other words, by appropriately selecting the areas of the regions, a transistor having electrical characteristics that meet the demand for the circuit design can be easily provided.

For the oxide 230, a metal oxide functioning as an oxide semiconductor (hereinafter also referred to as an oxide semiconductor) is preferably used. For example, as the metal oxide to be the region 234, it is preferable to use one having a band gap of 2 eV or more, preferably 2.5 eV or more. With the use of a metal oxide having such a wide band gap, the off-state current of the transistor can be reduced.

A transistor using an oxide semiconductor has an extremely low leakage current in a non-conduction state; thus, a semiconductor device with low power consumption can be provided. Moreover, an oxide semiconductor can be deposited by a sputtering method or the like, and thus can be used for a transistor included in a highly integrated semiconductor device.

The insulator 250 functions as a gate insulator. The insulator 250 is preferably positioned in contact with a top surface of the oxide 230c. In some cases, the excess oxygen in the insulator 280 is diffused to the opening portion 273h of the insulator 273, the insulator 275, and the insulator 250, and then supplied to the oxide 230. Thus, like the insulator 224, the insulator 250 is preferably formed using an insulator having a function of diffusing oxygen.

Furthermore, in order that the excess oxygen may be supplied to the oxide 230 efficiently, the metal oxide 252 may be provided over the insulator 250. Thus, the metal oxide 252 preferably inhibits diffusion of oxygen. When the metal oxide 252 that inhibits diffusion of oxygen is provided between the insulator 250 and the conductor 260, diffusion of the excess oxygen to the conductor 260 is inhibited. That is, a reduction in the amount of excess oxygen supplied to the oxide 230 can be inhibited. Moreover, oxidization of the conductor 260 due to the excess oxygen can be inhibited.

Note that the metal oxide 252 may function as part of the first gate. For example, an oxide semiconductor that can be used for the oxide 230 can be used for the metal oxide 252. In this case, when the conductor 260 is deposited by a sputtering method, the metal oxide 252 can have a reduced electric resistance to be a conductor. This can be called an OC (Oxide Conductor) electrode.

Note that the metal oxide 252 functions as part of the gate insulator in some cases. Thus, when silicon oxide, silicon oxynitride, or the like is used for the insulator 250, a metal oxide that is a high-k material with a high dielectric constant is preferably used for the metal oxide 252. Such a stacked-layer structure can be thermally stable and can have a high dielectric constant. Thus, a gate potential that is applied during operation of the transistor can be reduced while the physical thickness is kept. In addition, the equivalent oxide thickness (EOT) of the insulator functioning as the gate insulator can be reduced.

Although the metal oxide 252 in the transistor 200 is shown as a single layer, the metal oxide 252 may have a stacked-layer structure of two or more layers. For example, a metal oxide functioning as part of a gate electrode and a metal oxide functioning as part of a gate insulator may be stacked.

With the metal oxide 252 functioning as a gate electrode, the on-state current of the transistor 200 can be increased without a reduction in the influence of the electric field generated from the conductor 260. With the metal oxide 252 functioning as a gate insulator, the distance between the conductor 260 and the oxide 230 is kept by the physical thicknesses of the insulator 250 and the metal oxide 252, so that leakage current between the conductor 260 and the oxide 230 can be reduced. Thus, with the stacked-layer structure of the insulator 250 and the metal oxide 252, the physical distance between the conductor 260 and the oxide 230 and the intensity of electric field applied from the conductor 260 to the oxide 230 can be easily adjusted as appropriate.

Specifically, the oxide semiconductor that can be used for the oxide 230 can also be used for the metal oxide 252 when the resistance thereof is reduced. Alternatively, a metal oxide containing one kind or two or more kinds selected from hafnium, aluminum, gallium, yttrium, zirconium, tungsten, titanium, tantalum, nickel, germanium, magnesium, and the like can be used.

It is particularly preferable to use an insulator containing an oxide of one or both of aluminum and hafnium, for example, aluminum oxide, hafnium oxide, or an oxide containing aluminum and hafnium (hafnium aluminate). In particular, hafnium aluminate has higher heat resistance than a hafnium oxide film. Therefore, hafnium aluminate is preferable since it is less likely to be crystallized by a thermal budget through the following process. Note that the metal oxide 252 is not an essential structure. Design is appropriately set in consideration of required transistor characteristics.

The conductor 260 functioning as the first gate electrode includes the conductor 260a and the conductor 260b over the conductor 260a. Like the first conductor of the conductor 205, the conductor 260a is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of oxygen atoms, oxygen molecules, and the like).

When the conductor 260a has a function of inhibiting diffusion of oxygen, the conductivity of the conductor 260b can be inhibited from being lowered because of oxidization due to excess oxygen contained in the insulator 250 and the metal oxide 252. As a conductive material having a function of inhibiting diffusion of oxygen, for example, tantalum, tantalum nitride, ruthenium, ruthenium oxide, or the like is preferably used.

Furthermore, the conductor 260b is preferably formed using a conductive material containing tungsten, copper, or aluminum as its main component. The conductor 260 functions as a wiring and thus is preferably formed using a conductor having high conductivity. For example, a conductive material containing tungsten, copper, or aluminum as its main component can be used. The conductor 260b may have a stacked-layer structure, for example, a stacked layer of any of the above conductive materials and titanium or titanium nitride.

Furthermore, the insulator 270 functioning as a barrier film may be positioned over the conductor 260. For the insulator 270, an insulating material having a function of inhibiting the passage of oxygen and impurities such as water and hydrogen is preferably used. For example, aluminum oxide or hafnium oxide is preferably used. Thus, oxidization of the conductor 260 due to oxygen from above the insulator 270 can be inhibited. Moreover, entry of impurities such as water and hydrogen from above the insulator 270 into the oxide 230 through the conductor 260 and the insulator 250 can be inhibited.

The insulator 271 functioning as a hard mask may be positioned over the insulator 270. By providing the insulator 271, the conductor 260 can be processed to have the side surface that is substantially vertical; specifically, an angle formed by the side surface of the conductor 260 and a surface of the substrate can be greater than or equal to 75° and less than or equal to 100°, preferably greater than or equal to 80° and less than or equal to 95°. When the conductor 260 is processed into such a shape, the insulator 275 that is subsequently formed can be formed into a desired shape.

An insulating material having a function of inhibiting the passage of oxygen and impurities such as water and hydrogen may be used for the insulator 271 so that the insulator 271 also functions as a barrier film. In that case, the insulator 270 does not have to be provided.

The insulator 275 functioning as a buffer layer is provided in contact with a side surface of the oxide 230c, a side surface of the insulator 250, a side surface of the metal oxide 252, the side surface of the conductor 260, and a side surface of the insulator 270.

For example, the insulator 275 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride, which have thermal stability, are preferable.

Like the insulator 250 and the insulator 224, the insulator 275 preferably has a function of diffusing oxygen. In that case, the insulator 280 including the excess-oxygen region may be provided in contact with the insulator 275 through an opening provided in the insulator 273. The excess oxygen in the insulator 280 is effectively supplied to the oxide 230 through the opening portion of the insulator 273, the insulator 275, and the insulator 250.

The insulator 273 is provided over at least the low-resistance region 242 of the oxide 230. Here, the opening portion 273h that exposes one or both of the insulator 224 and the insulator 275 is included.

The oxide 230 overlaps with the insulator 280 including the excess-oxygen region with the insulator 273 therebetween. Accordingly, excess oxygen is supplied from the insulator 280 to the oxide 230 not directly but through other structure bodies (e.g., the insulator 224, the insulator 250, and the insulator 275). In addition, owing to the insulator 273, a region in which the insulator 280 is in contact with the insulator 224, the insulator 250, and the insulator 275 is limited. Accordingly, the excess oxygen in the insulator 280 can be inhibited from being excessively diffused into the oxide 230.

The insulator 273 has a function of inhibiting diffusion of oxygen. For example, a metal oxide containing one kind or two or more kinds selected from hafnium, aluminum, gallium, yttrium, zirconium, tungsten, titanium, tantalum, nickel, germanium, magnesium, and the like can be used for the insulator 273.

Note that the opening portion 273h included in the insulator 280 may be designed as appropriate depending on the shape, size, integration, or layout of the transistor 200. For example, the opening portion 273h may be a circular or polygonal hole, groove, slit, or the like.

That is, the excess oxygen contained in the insulator 280 reduces oxygen vacancies in the oxide 230 through the insulator 224, whereby reliability can be improved. Furthermore, by providing the insulator 273 including the opening portion 273h, the excess oxygen contained in the insulator 280 can be inhibited from being diffused into the oxide 230 at a value exceeding the proper value.

Then, the insulator 280 functioning as an interlayer film is preferably provided over the insulator 273. The concentration of impurities such as water and hydrogen in the insulator 280 is preferably reduced.

Here, it is preferable to use, for the insulator 280, an insulator containing more oxygen than oxygen in the stoichiometric composition. That is, the excess-oxygen region is preferably formed in the insulator 280. When such an insulator containing excess oxygen is provided in the vicinity of the transistor 200 with the insulator 273 including the opening portion therebetween, oxygen vacancies in the oxide 230 can be reduced and the reliability of the transistor 200 can be improved.

For the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³, or greater than or equal to 3.0×10²⁰ atoms/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which have thermal stability, are preferable.

In the case where the insulator 280 includes the excess-oxygen region, it is preferable that the insulator 282 have a function of inhibiting diffusion of oxygen (e.g., at least one of oxygen atoms, oxygen molecules, and the like) (that the insulator 282 do not easily transmit the above oxygen).

When the insulator 282 that inhibits diffusion of oxygen is provided over the insulator 280, diffusion of the excess oxygen to the insulator 284 side is inhibited. That is, a reduction in the amount of excess oxygen supplied to the oxide 230 can be inhibited. Thus, the excess oxygen can be supplied to the oxide 230 efficiently.

For example, when the insulator 282 is deposited by a sputtering method, impurities in the insulator 280 can be reduced. Furthermore, the insulator 284 similar to the insulator 210 may be provided over the insulator 282.

The conductor 240s and the conductor 240d are provided in the openings formed in the insulator 284, the insulator 282, the insulator 280, and the insulator 273. The conductor 240s and the conductor 240d are positioned to face each other with the conductor 260 sandwiched therebetween. Note that the top surfaces of the conductor 240s and the conductor 240d may be on the same surface as the top surface of the insulator 284.

The conductor 240s is in contact with the region 242s functioning as one of the source region and the drain region of the transistor 200, and the conductor 240d is in contact with the region 242d functioning as the other of the source region and the drain region of the transistor 200. Thus, the conductor 240s can function as one of the source electrode and the drain electrode, and the conductor 240d can function as the other of the source electrode and the drain electrode.

Note that the conductor 240s is formed in contact with the inner wall of the opening in the insulator 284, the insulator 282, the insulator 280, and the insulator 273. The region 242s of the oxide 230 is positioned on at least part of a bottom of the opening, and thus the conductor 240s is in contact with the region 242s. Similarly, the conductor 240d is formed in contact with the inner wall of the opening in the insulator 284, the insulator 282, the insulator 280, and the insulator 273. The region 242d of the oxide 230 is positioned on at least part of a bottom of the opening, and thus the conductor 240d is in contact with the region 242d.

Here, the conductor 240s and the conductor 240d preferably overlap with the side surfaces of the oxide 230. It is particularly preferable that the conductor 240s and the conductor 240d overlap with one or both of the side surface of the oxide 230 on the A3 side and the side surface of the oxide 230 on the A4 side, which intersect with the channel width direction of the oxide 230. Alternatively, the conductor 240s and the conductor 240d may overlap with the side surface of the oxide 230 on the A1 side (the A2 side), which intersects with the channel length direction of the oxide 230. Thus, with the structure in which the conductor 240s and the conductor 240d overlap with the region 242 to be the source region or the drain region and the side surface of the oxide 230, the contact area of a contact portion between the conductor 240s and the transistor 200 and the conductor 240d and the transistor 200 can be increased without increasing the projected area of the contact portion, so that the contact resistance between the conductor 240s and the transistor 200 and the conductor 240d and the transistor 200 can be reduced. Thus, miniaturization of the source electrode and the drain electrode of the transistor can be achieved and, in addition, the on-state current can be increased.

The conductor 240s and the conductor 240d are preferably formed using a conductive material containing tungsten, copper, or aluminum as its main component. The conductor 240s and the conductor 240d may have a stacked-layer structure.

In the case where the conductor 240 has a stacked-layer structure, a conductive material having a function of inhibiting the passage of impurities such as water and hydrogen is preferably used for a conductor in contact with the insulator 284, the insulator 282, the insulator 280, and the insulator 273, like the first conductor of the conductor 205, for example. For example, tantalum, tantalum nitride, titanium, titanium nitride, ruthenium, ruthenium oxide, or the like is preferably used. The conductive material having a function of inhibiting the passage of impurities such as water and hydrogen may be a single layer or a stacked layer. With the use of the conductive material, impurities such as hydrogen and water can be inhibited from entering the oxide 230 through the conductor 240s and the conductor 240d from a layer above the insulator 280.

Although not illustrated, a conductor functioning as a wiring may be positioned in contact with the top surface of the conductor 240s and the top surface of the conductor 240d. For the conductor functioning as a wiring, a conductive material containing tungsten, copper, or aluminum as its main component is preferably used. The conductor may have a stacked-layer structure, for example, a stacked layer of any of the above conductive materials and titanium or titanium nitride. Note that like the conductor 203 or the like, the conductor may be formed to be embedded in an opening provided in an insulator.

### <Constituent Materials for Semiconductor Device>

Constituent materials that can be used for a semiconductor device will be described below.

### <<Substrate>>

As a substrate over which the transistor 200 is formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate containing silicon carbide, silicon germanium, gallium arsenide, indium phosphide, zinc oxide, or gallium oxide. Moreover, a semiconductor substrate in which an insulator region is included in the above semiconductor substrate, e.g., an SOI (Silicon On Insulator) substrate or the like is used. Examples of the conductor substrate include a graphite substrate, a metal substrate, an alloy substrate, and a conductive resin substrate. A substrate including a metal nitride, a substrate including a metal oxide, or the like is used. Moreover, an insulator substrate provided with a conductor or a semiconductor, a semiconductor substrate provided with a conductor or an insulator, a conductor substrate provided with a semiconductor or an insulator, or the like is used. Alternatively, any of these substrates provided with an element may be used. Examples of the element provided for the substrate include a capacitor, a resistor, a switching element, a light-emitting element, and a memory element.

Alternatively, a flexible substrate may be used as the substrate. Note that as a method for providing a transistor over a flexible substrate, there is a method in which a transistor is fabricated over a non-flexible substrate and then the transistor is separated from the non-flexible substrate and transferred to a substrate that is a flexible substrate. In that case, a separation layer is preferably provided between the non-flexible substrate and the transistor. In addition, the substrate may have elasticity. Furthermore, the substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. Moreover, when the substrate has a small thickness, even in the case of using glass or the like, the substrate may have elasticity or a property of returning to its original shape when bending or pulling is stopped. Thus, an impact applied to a semiconductor device over the substrate, which is caused by dropping or the like, can be reduced. That is, a durable semiconductor device can be provided.

For the substrate that is a flexible substrate, for example, a metal, an alloy, a resin, glass, or fiber thereof can be used. Note that as the substrate, a sheet, a film, a foil, or the like that contains a fiber may be used. The substrate that is a flexible substrate preferably has a lower coefficient of linear expansion because deformation due to an environment is inhibited. For the substrate that is a flexible substrate, for example, a material whose coefficient of linear expansion is lower than or equal to 1×10⁻³/K, lower than or equal to 5×10⁻⁵/K, or lower than or equal to 1×10⁻⁵/K may be used. Examples of the resin include polyester, polyolefin, polyamide (nylon, aramid, or the like), polyimide, polycarbonate, and acrylic. In particular, aramid is suitable for the substrate that is a flexible substrate because of its low coefficient of linear expansion.

### <<Insulator>>

Examples of an insulator include an oxide, a nitride, an oxynitride, a nitride oxide, a metal oxide, a metal oxynitride, and a metal nitride oxide, each of which has an insulating property.

With miniaturization and high integration of a transistor, for example, a problem such as leakage current may arise because of a thinner gate insulator. When a high-k material is used for an insulator functioning as the gate insulator, a voltage during operation of the transistor can be reduced while the physical thickness of the gate insulator is kept. By contrast, when a material having a low dielectric constant is used for the insulator functioning as an interlayer film, the parasitic capacitance generated between wirings can be reduced. Thus, a material is preferably selected depending on the function of the insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

In particular, silicon oxide and silicon oxynitride are thermally stable. Accordingly, a stacked-layer structure which is thermally stable and has a low dielectric constant can be obtained by combination with a resin, for example. Examples of the resin include polyester, polyolefin, polyamide (nylon, aramid, or the like), polyimide, polycarbonate, and acrylic. Furthermore, combining silicon oxide and silicon oxynitride with an insulator having a high dielectric constant enables a stacked-layer structure to have thermal stability and a high dielectric constant.

In addition, when a transistor using an oxide semiconductor is surrounded by an insulator having a function of inhibiting the passage of oxygen and impurities such as hydrogen, the transistor can have stable electrical characteristics.

As the insulator having a function of inhibiting the passage of oxygen and impurities such as hydrogen, a single layer or a stacked layer of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

For example, a metal oxide containing one or more kinds selected from hafnium, aluminum, gallium, yttrium, zirconium, tungsten, titanium, tantalum, nickel, germanium, magnesium, and the like can be used for the insulator 273.

In particular, aluminum oxide has a high barrier property, so that even a thin aluminum oxide film having a thickness of greater than or equal to 0.5 nm and less than or equal to 3.0 nm can inhibit diffusion of hydrogen and nitrogen. Although hafnium oxide has a lower barrier property than aluminum oxide, hafnium oxide having a large thickness can have a high barrier property. Therefore, the amount of added hydrogen and nitrogen can be adjusted appropriately by adjusting the thickness of hafnium oxide.

For example, silicon oxide or silicon oxynitride, which is thermally stable, is preferably used for the insulator 220. When the gate insulator has a stacked-layer structure of a thermally stable film and a film having a high dielectric constant, the equivalent oxide thickness (EOT) of the gate insulator can be reduced while the physical thickness thereof is kept.

With the above stacked-layer structure, the on-state current can be increased without a reduction in the influence of the electric field from the gate electrode. Since the distance between the gate electrode and the region where a channel is formed is kept by the physical thickness of the gate insulator, a leakage current between the gate electrode and the channel formation region can be inhibited.

The insulator 212, the insulator 216, the insulator 271, and the insulator 284 each preferably include an insulator with a low relative permittivity. For example, the insulators each preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulators each preferably have a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low dielectric constant. Examples of the resin include polyester, polyolefin, polyamide (nylon, aramid, or the like), polyimide, polycarbonate, and acrylic.

For the insulator 210, the insulator 214, the insulator 270, and the insulator 282, an insulator having a function of inhibiting the passage of oxygen and impurities such as hydrogen may be used. For the insulator 270, a metal oxide such as aluminum oxide, hafnium oxide, magnesium oxide, gallium oxide, germanium oxide, yttrium oxide, zirconium oxide, lanthanum oxide, neodymium oxide, or tantalum oxide, silicon nitride oxide, silicon nitride, or the like may be used, for example.

### <<Conductor>>

For the conductors, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

Furthermore, a stack including a plurality of conductive layers formed with the above materials may be used. For example, a stacked-layer structure in which a material containing the above metal element and a conductive material containing oxygen are combined may be employed. Furthermore, a stacked-layer structure in which a material containing the above metal element and a conductive material containing nitrogen are combined may be employed. Furthermore, a stacked-layer structure in which a material containing the above metal element, a conductive material containing oxygen, and a conductive material containing nitrogen are combined may be employed.

Note that when an oxide is used for the channel formation region of the transistor, a stacked-layer structure in which a material containing the above metal element and a conductive material containing oxygen are combined is preferably used for the conductor functioning as the gate electrode. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. Furthermore, a conductive material containing the above metal element and nitrogen may be used. For example, a conductive material containing nitrogen, such as titanium nitride or tantalum nitride, may be used. Furthermore, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide where the channel is formed can be trapped in some cases. Alternatively, hydrogen entering from an external insulator or the like can be trapped in some cases.

For the conductor 260, the conductor 203, the conductor 205, and the conductor 240, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon including an impurity element such as phosphorus, or silicide such as nickel silicide may be used.

### <<Metal Oxide>>

For the oxide 230, a metal oxide functioning as an oxide semiconductor (hereinafter also referred to as an oxide semiconductor) is preferably used. A metal oxide that can be used for the oxide 230 of the present invention will be described below.

The metal oxide preferably contains at least indium or zinc. In particular, indium and zinc are preferably contained. Furthermore, aluminum, gallium, yttrium, tin, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, and the like may be contained.

Here, the case where the metal oxide is an In-M-Zn oxide containing indium, the element M, and zinc is considered. Note that the element M is aluminum, gallium, yttrium, tin, or the like. Other elements that can be used as the element M include boron, titanium, iron, nickel, germanium, zirconium, molybdenum, lanthanum, cerium, neodymium, hafnium, tantalum, tungsten, and magnesium. Note that a plurality of the above-described elements may be combined as the element M.

Note that in this specification and the like, a metal oxide containing nitrogen is also referred to as a metal oxide in some cases. Alternatively, a metal oxide containing nitrogen may be referred to as a metal oxynitride.

### [Composition of Metal Oxide]

The composition of a CAC (Cloud-Aligned Composite)-OS that can be used for a transistor disclosed in one embodiment of the present invention will be described below.

Note that in this specification and the like, CAAC (c-axis aligned crystal) and CAC (Cloud-Aligned Composite) might be stated. Note that CAAC refers to an example of a crystal structure, and CAC refers to an example of a function or a material composition.

A CAC-OS or a CAC-metal oxide has a conducting function in a part of the material and an insulating function in another part of the material, and has a function of a semiconductor as the whole material. Note that in the case where the CAC-OS or the CAC-metal oxide is used in an active layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

In addition, the CAC-OS or the CAC-metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. Moreover, the conductive regions are sometimes observed to be coupled in a cloud-like manner with their boundaries blurred.

Furthermore, in the CAC-OS or the CAC-metal oxide, the conductive regions and the insulating regions each having a size greater than or equal to 0.5 nm and less than or equal to 10 nm, preferably greater than or equal to 0.5 nm and less than or equal to 3 nm are dispersed in the material in some cases.

The CAC-OS or the CAC-metal oxide is composed of components having different band gaps. For example, the CAC-OS or the CAC-metal oxide is composed of a component having a wide gap due to the insulating region and a component having a narrow gap due to the conductive region. In the case of the structure, when carriers flow, the carriers mainly flow in the component having a narrow gap. Moreover, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, the transistor in an on state can achieve high current driving capability, that is, high on-state current and high field-effect mobility.

In other words, the CAC-OS or the CAC-metal oxide can also be referred to as a matrix composite or a metal matrix composite.

### [Structure of Metal Oxide]

Oxide semiconductors (metal oxides) are classified into a single-crystal oxide semiconductor and a non-single-crystal oxide semiconductor. Examples of the non-single-crystal oxide semiconductors include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and the crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) is difficult to observe even in the vicinity of distortion in the CAAC-OS. That is, formation of a crystal grain boundary is inhibited due to the distortion of lattice arrangement. This is because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other, and when the element M in the (M,Zn) layer is replaced with indium, the layer can also be referred to as an (InN,Zn) layer. Furthermore, when indium in the In layer is replaced with the element M, the layer can also be referred to as an (In,M) layer.

The CAAC-OS is a metal oxide with high crystallinity. On the other hand, a clear crystal grain boundary is difficult to observe in the CAAC-OS; thus, a reduction in the electron mobility due to the crystal grain boundary is less likely to occur. Furthermore, entry of impurities, formation of defects, or the like might decrease the crystallinity of a metal oxide, which means that the CAAC-OS is a metal oxide having small amounts of impurities and defects (e.g., oxygen vacancies (V₀)). Thus, a metal oxide including the CAAC-OS is physically stable. Therefore, the metal oxide including the CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, in some cases, the nc-OS cannot be distinguished from an a-like OS or an amorphous oxide semiconductor depending on the analysis method.

The a-like OS is a metal oxide having a structure between those of the nc-OS and the amorphous oxide semiconductor. The a-like OS contains a void or a low-density region. That is, the a-like OS has low crystallinity as compared with the nc-OS and the CAAC-OS.

An oxide semiconductor (a metal oxide) has various structures with different properties. Two or more kinds of the amorphous oxide semiconductor, the polycrystalline oxide semiconductor, the a-like OS, the nc-OS, and the CAAC-OS may be included in an oxide semiconductor of one embodiment of the present invention.

### [Transistor Including Metal Oxide]

Next, the case where the above metal oxide is used for a channel formation region of a transistor will be described.

Note that when the above metal oxide is used for a channel formation region of a transistor, the transistor having high field-effect mobility can be achieved. In addition, the transistor having high reliability can be achieved.

Here, an example of the hypothesis about electric conduction of a metal oxide is described.

Electric conduction in a solid is inhibited by a scattering source called a scattering center. For example, it is known that in the case of single crystal silicon, lattice scattering and ionized impurity scattering are main scattering centers. In other words, in the elemental state with few lattice defects and impurities, the carrier mobility is high because there is no factor that inhibits the electric conduction in the solid.

The above presumably applies to a metal oxide. For example, it is probable that a metal oxide containing less oxygen than that in the stoichiometric composition has many oxygen vacancies. Atoms around the oxygen vacancies are positioned in places shifted from those in the elemental state. This distortion due to the oxygen vacancies might become a scattering center.

Furthermore, a metal oxide containing less oxygen than that in the stoichiometric composition contains excess oxygen, for example. Excess oxygen existing in a liberated state in the metal oxide becomes O⁻ or O²⁻ by receiving an electron. Excess oxygen that has become O⁻ or O²⁻ might be a scattering center.

According to the above, it is probable that in the case where the metal oxide has an elemental state containing oxygen in the stoichiometric composition, the carrier mobility is high.

Since crystal growth tends to hardly occur particularly in the air in an indium-gallium-zinc oxide (hereinafter IGZO), which is one kind of metal oxide containing indium, gallium, and zinc, small crystals (e.g., the above-described nanocrystals) have more stable structures than large crystals (here, several-millimeter crystals or several-centimeter crystal) in some cases. This is probably because connection of small crystals, rather than formation of large crystals, leads to a reduction in distortion energy.

Note that in a region where small crystals are connected to each other, defects are formed in some cases to reduce the distortion energy of the region. Thus, when the distortion energy is reduced without formation of a defect in the region, the carrier mobility can be increased.

Furthermore, a metal oxide with a low carrier density is preferably used for the transistor. In the case where the carrier density of a metal oxide film is reduced, the impurity concentration in the metal oxide film is reduced to reduce the density of defect states. In this specification and the like, a state with a low impurity concentration and a low density of defect states is referred to as a highly purified intrinsic or substantially highly purified intrinsic state. For example, a metal oxide has a carrier density lower than 8×10¹¹/cm³, preferably lower than 1×10¹¹/cm³, and further preferably lower than 1×10¹⁰/cm³, and higher than or equal to 1×10⁻⁹/cm³.

Moreover, a highly purified intrinsic or substantially highly purified intrinsic metal oxide film has a low density of defect states and accordingly may have a low density of trap states.

Charges trapped by the trap states in the metal oxide take a long time to be released and may behave like fixed charges. Thus, a transistor whose channel formation region includes a metal oxide having a high density of trap states has unstable electrical characteristics in some cases.

Accordingly, in order to obtain stable electrical characteristics of the transistor, it is effective to reduce the concentration of impurities in the metal oxide. In addition, in order to reduce the concentration of impurities in the metal oxide, the impurity concentration in an adjacent film is also preferably reduced. Examples of impurities include hydrogen, nitrogen, an alkali metal, an alkaline earth metal, iron, nickel, and silicon.

As a metal oxide used for a semiconductor of the transistor, a thin film having high crystallinity is preferably used. With the use of the thin film, the stability or the reliability of the transistor can be improved. Examples of the thin film include a thin film of a single-crystal metal oxide and a thin film of a polycrystalline metal oxide. However, for forming the thin film of a single-crystal metal oxide or the thin film of a polycrystalline metal oxide over a substrate, a high-temperature process or a laser heating process is needed. Thus, the manufacturing cost is increased, and in addition, the throughput is decreased.

Non-Patent Document 1 and Non-Patent Document 2 have reported that an In—Ga—Zn oxide having a CAAC structure (referred to as CAAC-IGZO) was found in 2009. It has been reported that CAAC-IGZO has c-axis alignment, a crystal grain boundary is not clearly observed in CAAC-IGZO, and CAAC-IGZO can be formed over a substrate at low temperatures. It has also been reported that a transistor using CAAC-IGZO has excellent electrical characteristics and high reliability.

In addition, in 2013, an In—Ga—Zn oxide having an nc structure (referred to as nc-IGZO) was found (see Non-Patent Document 3). It has been reported that nc-IGZO has periodic atomic arrangement in a microscopic region (for example, a region with a size greater than or equal to 1 nm and less than or equal to 3 nm) and there is no regularity of crystal orientation between different regions.

Non-Patent Document 4 and Non-Patent Document 5 have shown a change in average crystal size due to electron beam irradiation to thin films of the above CAAC-IGZO, the above nc-IGZO, and IGZO having low crystallinity. In the thin film of IGZO having low crystallinity, crystalline IGZO with a crystal size of approximately 1 nm was observed even before the electron beam irradiation. Thus, it has been reported that the existence of a completely amorphous structure was not observed in IGZO. In addition, it has been shown that the thin film of CAAC-IGZO and the thin film of nc-IGZO each have higher stability to electron beam irradiation than the thin film of IGZO having low crystallinity. Thus, the thin film of CAAC-IGZO or the thin film of nc-IGZO is preferably used for a semiconductor of a transistor.

Non-Patent Document 6 shows that a transistor using a metal oxide has an extremely low leakage current in a non-conduction state; specifically, the off-state current per micrometer in the channel width of the transistor is of the order of yA/μm (10⁻²⁴ A/μm). For example, a low-power-consumption CPU utilizing a characteristic of a low leakage current of the transistor using a metal oxide is disclosed (see Non-Patent Document 7).

Furthermore, application of a transistor using a metal oxide to a display device that utilizes the characteristic of a low leakage current of the transistor has been reported (see Non-Patent Document 8). In the display device, a displayed image is changed several tens of times per second. The number of times an image is changed per second is called a refresh rate. The refresh rate is also referred to as driving frequency. Such high-speed screen change that is hard for human eyes to recognize is considered as a cause of eyestrain. Thus, it is proposed that the refresh rate of the display device is lowered to reduce the number of times of image rewriting. Moreover, driving with a lowered refresh rate enables the power consumption of the display device to be reduced. Such a driving method is referred to as idling stop (IDS) driving.

The discovery of the CAAC structure and the nc structure has contributed to an improvement in electrical characteristics and reliability of a transistor using a metal oxide having the CAAC structure or the nc structure, a reduction in manufacturing cost, and an improvement in throughput. Furthermore, applications of the transistor to a display device and an LSI utilizing the characteristics of a low leakage current of the transistor have been studied.

### [Impurities]

Here, the influence of each impurity in the metal oxide will be described.

When silicon or carbon that is a Group 14 element is contained in the metal oxide, defect states are formed in the metal oxide. Thus, the concentration of silicon or carbon in the metal oxide and the concentration of silicon or carbon in the vicinity of an interface with the metal oxide (the concentration measured by secondary ion mass spectrometry (SIMS)) are set to lower than or equal to 2×10¹⁸ atoms/cm³, preferably lower than or equal to 2×10¹⁷ atoms/cm³.

When the metal oxide contains an alkali metal or an alkaline earth metal, defect states are formed and carriers are generated, in some cases. Thus, a transistor using a metal oxide that contains an alkali metal or an alkaline earth metal for its channel formation region is likely to have normally-on characteristics. Therefore, it is preferable to reduce the concentration of an alkali metal or an alkaline earth metal in the metal oxide. Specifically, the concentration of an alkali metal or an alkaline earth metal in the metal oxide obtained by SIMS is set to lower than or equal to 1×10¹⁸ atoms/cm³, preferably lower than or equal to 2×10¹⁶ atoms/cm³.

Furthermore, when containing nitrogen, the metal oxide easily becomes n-type by generation of electrons serving as carriers and an increase in carrier density. As a result, a transistor using a metal oxide containing nitrogen for its channel formation region is likely to have normally-on characteristics. Thus, nitrogen in the channel formation region in the metal oxide is preferably reduced as much as possible. For example, the nitrogen concentration in the metal oxide is set to lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³ in SIMS.

Furthermore, hydrogen contained in a metal oxide reacts with oxygen bonded to a metal atom to be water, and thus forms an oxygen vacancy, in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using a metal oxide containing hydrogen is likely to have normally-on characteristics. Accordingly, hydrogen in the metal oxide is preferably reduced as much as possible. Specifically, the hydrogen concentration of the metal oxide, which is obtained by SIMS, is set to lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When a metal oxide in which impurities are sufficiently reduced is used for a channel formation region of a transistor, stable electrical characteristics can be given.

### [Effect of Vacuum Baking]

Here, a weak Zn—O bond in the metal oxide will be explained and an example of a method for reducing the number of oxygen atoms and zinc atoms which form the bond will be described.

In a transistor using a metal oxide, oxygen vacancies are given as an example of a defect which leads to poor electrical characteristics of the transistor. For example, the threshold voltage of a transistor using a metal oxide which includes oxygen vacancies in a film tends to shift in the negative direction, and thus the transistor tends to have normally-on characteristics. This is because a donor caused by oxygen vacancies included in the metal oxide is generated and the carrier concentration increases. The transistor having normally-on characteristics causes various problems in that a malfunction is likely to occur at the time of operation and power consumption is increased at the time of non-operation, for example.

Furthermore, there are problems in that thermal budget in the step of forming a connection wiring in fabricating a module causes degradation of the electrical characteristics of the transistor, such as variation in the threshold voltage and an increase in parasitic resistance, and an increase in variation in the electrical characteristics due to such degradation. Since such problems directly lead to a decrease in manufacturing yield, it is important to consider countermeasures. Furthermore, the electrical characteristics of the transistor are degraded through a stress test, which can evaluate a change in transistor characteristics by long-term use (a change over time) in a short time. The degradation of the electrical characteristics is presumably caused by oxygen vacancies in the metal oxide due to high temperature treatment performed in the thermal budget process or electrical stress applied during the stress test.

In the metal oxide, there is an oxygen atom which weakly bonds to a metal atom and thus is likely to form an oxygen vacancy. In particular, in the case where the metal oxide is an In—Ga—Zn oxide, a zinc atom and an oxygen atom are likely to form a weak bond (also referred to as a weak Zn—O bond). Here, the weak Zn—O bond means a bond generated between a zinc atom and an oxygen atom, which is weak enough to be broken by high temperature treatment performed in the thermal budget process or electrical stress applied during the stress test. When the weak Zn—O bond exists in the metal oxide, the bond is broken by thermal budget or current stress, so that an oxygen vacancy is formed. The formation of the oxygen vacancy decreases the stability of the transistor such as resistance to thermal budget and resistance in a stress test.

The bond between a zinc atom and an oxygen atom bonded to many zinc atoms is the weak Zn—O bond in some cases. A zinc atom bonds to an oxygen atom more weakly than a gallium atom does. Thus, an oxygen atom bonded to many zinc atoms is likely to form a vacancy. That is, the bond between a zinc atom and an oxygen atom is probably weaker than a bond between an oxygen atom and another metal.

It is supposed that the weak Zn—O bond is likely to be formed when impurities exist in the metal oxide. Examples of the impurities in the metal oxide include a water molecule and hydrogen. When a water molecule or hydrogen exists in the metal oxide, the hydrogen atom bonds to an oxygen atom contained in the metal oxide (also referred to as an OH bond) in some cases. In the case where the In—Ga—Zn oxide is a single crystal, an oxygen atom contained in the metal oxide is bonded to four metal atoms contained in the metal oxide. However, an oxygen atom bonded to the hydrogen atom is bonded to two or three metal atoms in some cases. When the number of metal atoms bonded to the oxygen atom is decreased, the oxygen atom is likely to form an oxygen vacancy. Note that when a zinc atom is bonded to an oxygen atom which forms an OH bond, the bond between the oxygen atom and the zinc atom is probably weak.

Note that the weak Zn—O bond is sometimes formed in a distortion where a plurality of nanocrystals are connected. Although the shape of nanocrystals is basically a hexagon, a pentagonal lattice arrangement, a heptagonal lattice arrangement, or the like is included in the distortion. It is supposed that the weak Zn—O bond is formed in the distortion because the bond distances between atoms are not uniform therein.

It is also supposed that the weak Zn—O bond is likely to be formed in the case where the metal oxide has low crystallinity. In the case where the metal oxide has high crystallinity, a zinc atom contained in the metal oxide is bonded to four or five oxygen atoms. However, when the crystallinity of the metal oxide becomes lower, the number of oxygen atoms bonded to a zinc atom tends to decrease. When the number of oxygen atoms bonded to a zinc atom decreases, the zinc atom easily forms a vacancy. That is, a bond between the zinc atom and the oxygen atom is presumably weaker than that in a single crystal.

The number of oxygen atoms and zinc atoms which form the weak Zn—O bonds is reduced, whereby formation of oxygen vacancies due to the thermal budget or the current stress can be inhibited, leading to an improvement in stability of a transistor. Note that in the case where only the number of oxygen atoms that form the weak Zn—O bonds is reduced and the number of zinc atoms that form the weak Zn—O bonds is not reduced, a weak Zn—O bond is formed again in some cases when an oxygen atom is supplied to the vicinity of the zinc atom. Therefore, it is preferable to reduce the number of zinc atoms and oxygen atoms that form the weak Zn—O bonds.

As a method for reducing the number of oxygen atoms and zinc atoms that form the weak Zn—O bonds, for example, a method in which vacuum baking is performed after the deposition of a metal oxide can be given. Note that the vacuum baking is heat treatment performed under a vacuum atmosphere. A vacuum atmosphere is kept by evacuation with a turbo-molecular pump or the like. The pressure in the treatment chamber is preferably lower than or equal to 1×10⁻² Pa, further preferably lower than or equal to 1×10⁻³ Pa. The substrate temperature in the heat treatment is higher than or equal to 300° C., preferably higher than or equal to 400° C.

Performing the vacuum baking can reduce the number of oxygen atoms and zinc atoms that form the weak Zn—O bonds. Furthermore, since heat is applied to the metal oxide by vacuum baking, atoms contained in the metal oxide are rearranged after the number of oxygen atoms and zinc atoms that form the weak Zn—O bonds is reduced, so that the number of oxygen atoms each bonded to four metal atoms is increased. Accordingly, the number of oxygen atoms and zinc atoms that form the weak Zn—O bonds can be reduced, and a weak Zn—O bond can be inhibited from being formed again.

Furthermore, when impurities exist in the metal oxide, performing the vacuum baking can release a water molecule or hydrogen in the metal oxide, so that the number of OH bonds can be reduced. When the number of OH bonds in the metal oxide is reduced, the proportion of the oxygen atoms each bonded to four metal atoms is increased. Furthermore, atoms contained in the metal oxide are rearranged when a water molecule or hydrogen is released, so that the number of the oxygen atoms each bonded to four metal atoms is increased. Thus, a weak Zn—O bond can be inhibited from being formed again.

As described above, when the vacuum baking is performed after the metal oxide is deposited, the number of oxygen atoms and zinc atoms that form weak Zn—O bonds can be reduced. Thus, stability of the transistor can be improved through the step. Furthermore, an improvement in stability of the transistor increases the degree of freedom for selecting a material and a formation method.

### <Manufacturing Method of Semiconductor Device>

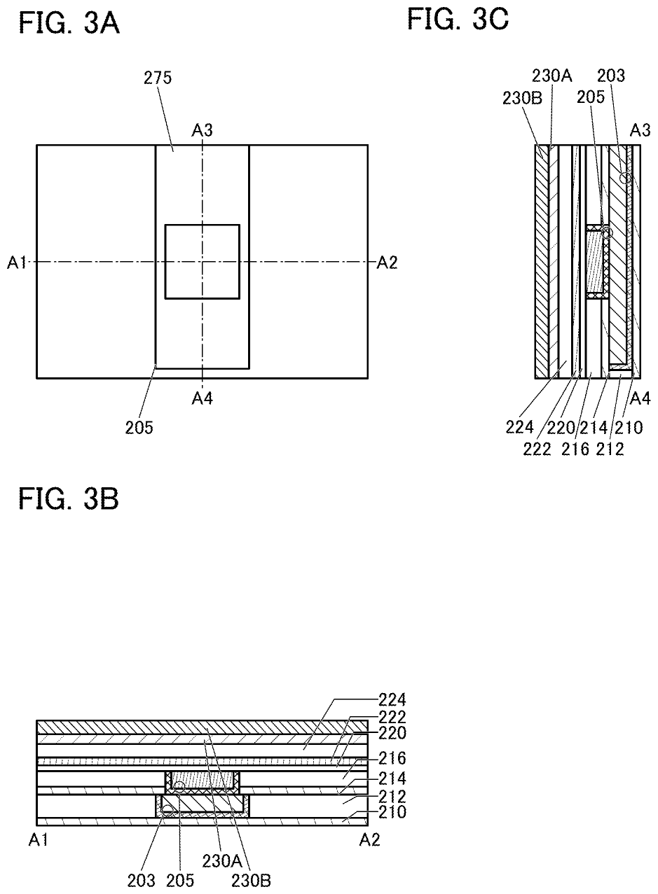

Next, a manufacturing method of a semiconductor device including the transistor 200 of the present invention will be described with reference to FIG. 3 to FIG. 13. In each of FIG. 3 to FIG. 13, figure (A) is a top view. Moreover, (B) of each drawing is a cross-sectional view corresponding to a portion indicated by dashed-dotted line A1-A2 in (A). Furthermore, (C) of each drawing is a cross-sectional view corresponding to a portion indicated by dashed-dotted line A3-A4 in (A).

First, a substrate (not illustrated) is prepared, and the insulator 210 is deposited over the substrate. The insulator 210 can be deposited by a sputtering method, a chemical vapor deposition (CVD) method, a molecular beam epitaxy (MBE) method, a pulsed laser deposition (PLD) method, an atomic layer deposition (ALD) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma enhanced CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during deposition, so that a film with few defects can be obtained.

An ALD method is also a deposition method which enables less plasma damage to an object. Thus, a film with few defects can be obtained. Note that a precursor used in an ALD method sometimes contains impurities such as carbon. Thus, a film provided by an ALD method contains impurities such as carbon in a larger amount than a film provided by another deposition method, in some cases. Note that impurities can be quantified by X-ray photoelectron spectroscopy (XPS).

Unlike a deposition method in which particles ejected from a target or the like are deposited, a CVD method and an ALD method are deposition methods in which a film is formed by reaction at a surface of an object. Thus, a CVD method and an ALD method are deposition methods that are less likely to be influenced by the shape of an object and thus have favorable step coverage. In particular, an ALD method has excellent step coverage and excellent thickness uniformity, and thus is suitable for the case of covering a surface of an opening with a high aspect ratio, for example. Note that an ALD method has a relatively low deposition rate, and thus is preferably used in combination with another deposition method with a high deposition rate such as a CVD method, in some cases.

A CVD method or an ALD method enables control of composition of a film to be obtained with a flow rate ratio of the source gases. For example, by a CVD method or an ALD method, a film with a desired composition can be deposited by adjusting the flow rate ratio of the source gases. Moreover, for example, by a CVD method or an ALD method, by changing the flow rate ratio of the source gases during the deposition, a film whose composition is continuously changed can be deposited. In the case of depositing a film while changing the flow rate ratio of the source gases, as compared with the case of depositing a film with the use of a plurality of deposition chambers, time taken for the deposition can be shortened because time taken for transfer and pressure adjustment is omitted. Thus, productivity of semiconductor devices can be improved in some cases.

In this embodiment, for the insulator 210, aluminum oxide is deposited by a sputtering method. The insulator 210 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Next, the insulator 212 is deposited over the insulator 210. The insulator 212 can be deposited by a sputtering method, a CVD method, an MBE method, a PLD method, an ALD method, or the like. In this embodiment, for the insulator 212, silicon oxide is deposited by a CVD method.

Then, the opening reaching the insulator 210 is formed in the insulator 212. Examples of the opening include a groove and a slit. A region where the opening is formed may be referred to as an opening portion. The opening may be formed by a wet etching method; however, a dry etching method is preferably used for microfabrication. As the insulator 210, it is preferable to select an insulator that functions as an etching stopper film used in forming the opening by etching the insulator 212. For example, in the case where a silicon oxide film is used as the insulator 212 in which the opening is to be formed, it is preferable to use, as the insulator 210, a silicon nitride film, an aluminum oxide film, or a hafnium oxide film as an insulating film functioning as an etching stopper film.

After the formation of the opening, a conductive film to be the first conductor of the conductor 203 is deposited. The conductive film preferably includes a conductor having a function of inhibiting the passage of oxygen. For example, tantalum nitride, tungsten nitride, or titanium nitride can be used. Alternatively, a stacked-layer film with tantalum, tungsten, titanium, molybdenum, aluminum, copper, or a molybdenum-tungsten alloy can be used. The conductive film to be the first conductor of the conductor 203 can be deposited by a sputtering method, a CVD method, an MBE method, a PLD method, an ALD method, or the like.

In this embodiment, as the conductive film to be the first conductor of the conductor 203, tantalum nitride or a film of tantalum nitride and titanium nitride stacked thereover is deposited by a sputtering method. With the use of such a metal nitride as the first conductor of the conductor 203, even when a metal that is easy to diffuse, such as copper, is used for the second conductor of the conductor 203 described later, the metal can be inhibited from being diffused outward through the first conductor of the conductor 203.

Next, a conductive film to be the second conductor of the conductor 203 is deposited over the conductive film to be the first conductor of the conductor 203. The conductive film can be deposited by a sputtering method, a CVD method, an MBE method, a PLD method, an ALD method, or the like. In this embodiment, for the conductive film to be the second conductor of the conductor 203, a low-resistance conductive material such as copper is deposited.

Next, CMP (chemical mechanical polishing) treatment is performed to remove parts of the conductive film to be the first conductor of the conductor 203 and the conductive film to be the second conductor of the conductor 203, so that the insulator 212 is exposed. As a result, the conductive film to be the first conductor of the conductor 203 and the conductive film to be the second conductor of the conductor 203 remain only in the opening portion. Thus, the conductor 203 including the first conductor of the conductor 203 and the second conductor of the conductor 203, which has a planar top surface, can be formed (see FIG. 3). Note that the insulator 212 is partly removed by the CMP treatment in some cases.

Next, the insulator 214 is deposited over the insulator 212 and the conductor 203. The insulator 214 can be deposited by a sputtering method, a CVD method, an MBE method, a PLD method, an ALD method, or the like. In this embodiment, for the insulator 214, silicon nitride is deposited by a CVD method. As described here, an insulator through which copper is less likely to pass, such as silicon nitride, is used for the insulator 214; accordingly, even when a metal that is easily diffused, such as copper, is used for the second conductor of the conductor 203, the metal can be prevented from being diffused into layers above the insulator 214.

Next, the insulator 216 is deposited over the insulator 214. The insulator 216 can be deposited by a sputtering method, a CVD method, an MBE method, a PLD method, an ALD method, or the like. In this embodiment, for the insulator 216, silicon oxide is deposited by a CVD method.

Next, an opening reaching the conductor 203 is formed in the insulator 214 and the insulator 216. The opening may be formed by wet etching; however, dry etching is preferably used for microfabrication.

After the formation of the opening, a conductive film to be the first conductor of the conductor 205 is deposited. The conductive film to be the first conductor of the conductor 205 preferably includes a conductive material that has a function of inhibiting the passage of oxygen. For example, tantalum nitride, tungsten nitride, or titanium nitride can be used. Alternatively, a stacked-layer film with tantalum, tungsten, titanium, molybdenum, aluminum, copper, or a molybdenum-tungsten alloy can be used. The conductive film to be the first conductor of the conductor 205 can be deposited by a sputtering method, a CVD method, an MBE method, a PLD method, an ALD method, or the like.

In this embodiment, for the conductive film to be the first conductor of the conductor 205, tantalum nitride is deposited by a sputtering method.

Next, a conductive film to be the second conductor of the conductor 205 is deposited over the conductive film to be the first conductor of the conductor 205. The conductive film can be deposited by a sputtering method, a CVD method, an MBE method, a PLD method, an ALD method, or the like.

In this embodiment, for the conductive film to be the second conductor of the conductor 205, titanium nitride is deposited by a CVD method and tungsten is deposited by a CVD method over the titanium nitride.

Next, CMP treatment is performed to remove parts of the conductive film to be the first conductor of the conductor 205 and the conductive film to be the second conductor of the conductor 205, so that the insulator 216 is exposed. As a result, the conductive film to be the first conductor of the conductor 205 and the conductive film to be the second conductor of the conductor 205 remain only in the opening portion. Thus, the conductor 205 including the first conductor of the conductor 205 and the second conductor of the conductor 205, which has a flat top surface, can be formed (see FIG. 3). Note that the insulator 216 is partly removed by the CMP treatment in some cases.

Next, the insulator 220 is deposited over the insulator 216 and the conductor 205. The insulator 220 can be deposited by a sputtering method, a CVD method, an MBE method, a PLD method, an ALD method, or the like. In this embodiment, for the insulator 220, silicon oxide is deposited by a CVD method.

Next, the insulator 222 is deposited over the insulator 220. An insulator containing an oxide of one or both of aluminum and hafnium is preferably deposited for the insulator 222. Note that as the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulator 222 has a barrier property against hydrogen and water, hydrogen and water contained in structure bodies provided around the transistor 200 are prevented from being diffused into the transistor 200 through the insulator 222, and generation of oxygen vacancies in the oxide 230 can be inhibited.

The insulator 222 can be deposited by a sputtering method, a CVD method, an MBE method, a PLD method, an ALD method, or the like.

Then, the insulator 224 is deposited over the insulator 222. The insulator 224 can be deposited by a sputtering method, a CVD method, an MBE method, a PLD method, an ALD method, or the like (see FIG. 3). In this embodiment, for the insulator 224, silicon oxide is deposited by a CVD method.

Sequentially, heat treatment is preferably performed. The heat treatment may be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen atmosphere, an inert gas atmosphere, or an atmosphere containing an oxidizing gas at 10 ppm or more, 1% or more, or 10% or more. The heat treatment may be performed under a reduced pressure. Alternatively, the heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen.

In this embodiment, heat treatment is performed at 400° C. in a nitrogen atmosphere for one hour after the deposition of the insulator 224. By the heat treatment, impurities such as hydrogen and water contained in the insulator 224 can be removed, for example.

This heat treatment can also be performed after the deposition of the insulator 220 and after the deposition of the insulator 222. Although the conditions for the above-described heat treatment can be used for the heat treatment, the heat treatment after the deposition of the insulator 220 is preferably performed in an atmosphere containing nitrogen.

Here, in order to form an excess-oxygen region in the insulator 224, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be produced, and RF application to the substrate side allows the oxygen radicals generated by the high-density plasma to be efficiently introduced into the insulator 224. Alternatively, after plasma treatment containing an inert gas is performed with this apparatus, plasma treatment containing oxygen may be performed to compensate for released oxygen. Note that impurities such as water and hydrogen contained in the insulator 224 can be removed by selecting the conditions for the plasma treatment appropriately. In that case, the heat treatment is not necessarily performed.

Next, an oxide film 230A to be the oxide 230a and an oxide film 230B to be the oxide 230b are deposited in this order over the insulator 224 (see FIG. 3). Note that the oxide films are preferably deposited successively without exposure to an air atmosphere. By the deposition without exposure to the air, impurities or moisture from the air atmosphere can be prevented from being attached to the oxide film 230A and the oxide film 230B, so that the vicinity of an interface between the oxide film 230A and the oxide film 230B can be kept clean.

The oxide film 230A and the oxide film 230B can be deposited by a sputtering method, a CVD method, an MBE method, a PLD method, an ALD method, or the like.

In the case where the oxide film 230A and the oxide film 230B are deposited by a sputtering method, for example, oxygen or a mixed gas of oxygen and a rare gas is used as a sputtering gas. By increasing the proportion of oxygen contained in the sputtering gas, the amount of excess oxygen in the oxide films to be deposited can be increased. In the case where the above oxide films are deposited by a sputtering method, the above In-M-Zn oxide target can be used.

In particular, when the oxide film 230A is deposited, part of oxygen contained in the sputtering gas is supplied to the insulator 224 in some cases. Therefore, the proportion of oxygen contained in the sputtering gas for the oxide film 230A is preferably 70% or higher, further preferably 80% or higher, still further preferably 100%.

In the case where the oxide film 230B is formed by a sputtering method, when the proportion of oxygen contained in the sputtering gas is 1% or higher and 30% or lower, preferably 5% or higher and 20% or lower during the deposition, an oxygen-deficient oxide semiconductor is formed. In a transistor using an oxygen-deficient oxide semiconductor for its channel formation region, relatively high field-effect mobility can be obtained.

In this embodiment, the oxide film 230A is deposited by a sputtering method using a target with In:Ga:Zn=1:3:4 [atomic ratio]. The oxide film 230B is deposited by a sputtering method using a target with In:Ga:Zn=4:2:4.1 [atomic ratio]. Note that each of the oxide films is preferably formed to have characteristics required for the oxide 230 by appropriate selection of deposition conditions and an atomic ratio.

Next, heat treatment may be performed. For the heat treatment, the conditions for the above-described heat treatment can be used. Through the heat treatment, impurities such as water and hydrogen in the oxide film 230A and the oxide film 230B can be removed, for example. In this embodiment, treatment is performed at 400° C. in a nitrogen atmosphere for one hour, and another treatment is successively performed at 400° C. in an oxygen atmosphere for one hour.

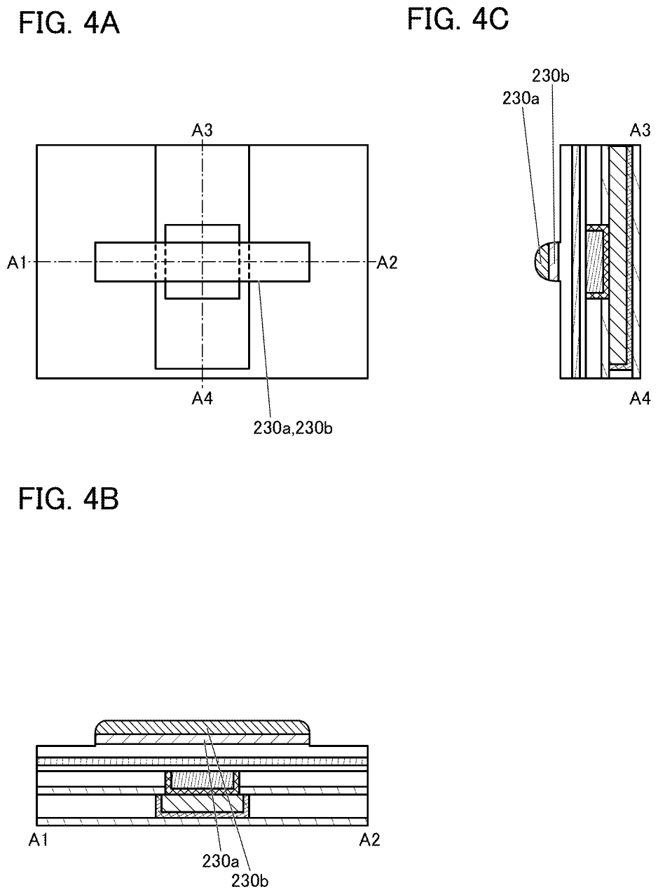

Then, the oxide film 230A and the oxide film 230B are processed into island shapes to form the oxide 230a and the oxide 230b (see FIG. 4).

Here, the oxide 230a and the oxide 230b are formed to at least partly overlap with the conductor 205. It is preferable that the side surfaces of the oxide 230a and the oxide 230b be substantially perpendicular to a top surface of the insulator 222. When the side surfaces of the oxide 230a and the oxide 230b are substantially perpendicular to the top surface of the insulator 222, the plurality of transistors 200 can be provided in a smaller area and at a higher density. Note that a structure may be employed in which an angle formed by the side surfaces of the oxide 230a and the oxide 230b and the top surface of the insulator 222 is an acute angle. In that case, the angle formed by the side surfaces of the oxide 230a and the oxide 230b and the top surface of the insulator 222 is preferably larger.

There is a curved surface between the side surfaces of the oxide 230a and the oxide 230b and the top surface of the oxide 230b. That is, an end portion of the side surface and an end portion of the top surface are preferably curved (hereinafter also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm, for example. When the end portions are not angular, the coverage with films deposited in a later step can be improved.

Note that for the processing of the oxide films, a lithography method can be employed. For the processing, a dry etching method or a wet etching method can be employed. The processing by a dry etching method is suitable for microfabrication.

In the lithography method, first, a resist is exposed to light through a mask. Next, a region exposed to light is removed or left using a developing solution, so that a resist mask is formed. Then, etching treatment through the resist mask is performed, so that a conductor, a semiconductor, an insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that the above mask for the exposure of the resist to light is unnecessary in the case of using an electron beam or an ion beam because direct writing is performed on the resist. Note that for removal of the resist mask, dry etching treatment such as ashing can be performed, wet etching treatment can be performed, wet etching treatment can be performed after dry etching treatment, or dry etching treatment can be performed after wet etching treatment, for example.

A hard mask formed of an insulator or a conductor may be used instead of the resist mask. In the case where a hard mask is used, a hard mask with a desired shape can be formed in the following manner: an insulating film or a conductive film that is the hard mask material is formed over the oxide film 230B, a resist mask is formed thereover, and then the hard mask material is etched. The etching of the oxide film 230A and the oxide film 230B may be performed after removal of the resist mask or while the resist mask remains. In the latter case, the resist mask may be removed during the etching. The hard mask may be removed by etching after the etching of the oxide film. The hard mask does not need to be removed in the case where the material of the hard mask does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power is applied to one of the parallel plate type electrodes. Alternatively, a structure may be employed in which different high-frequency powers are applied to one of the parallel plate type electrodes. Alternatively, a structure may be employed in which high-frequency powers with the same frequency are applied to the parallel plate type electrodes. Alternatively, a structure may be employed in which high-frequency powers with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, the treatment such as dry etching causes the attachment or diffusion of impurities due to an etching gas or the like to a surface or an inside of the oxide 230a, the oxide 230b, or the like. Examples of the impurities include fluorine and chlorine.

In order to remove the above impurities, cleaning is performed. Examples of the cleaning method include wet cleaning using a cleaning solution, plasma treatment using plasma, and cleaning by heat treatment, and any of these cleanings may be performed in appropriate combination.

As the wet cleaning, cleaning treatment may be performed using an aqueous solution obtained by diluting an oxalic acid, a phosphoric acid, a hydrofluoric acid, or the like with pure water or carbonated water. Alternatively, ultrasonic cleaning using pure water or carbonated water may be performed. In this embodiment, the ultrasonic cleaning using pure water or carbonated water is performed.

Sequentially, heat treatment may be performed. For the conditions of the heat treatment, the conditions for the above-described heat treatment can be used.

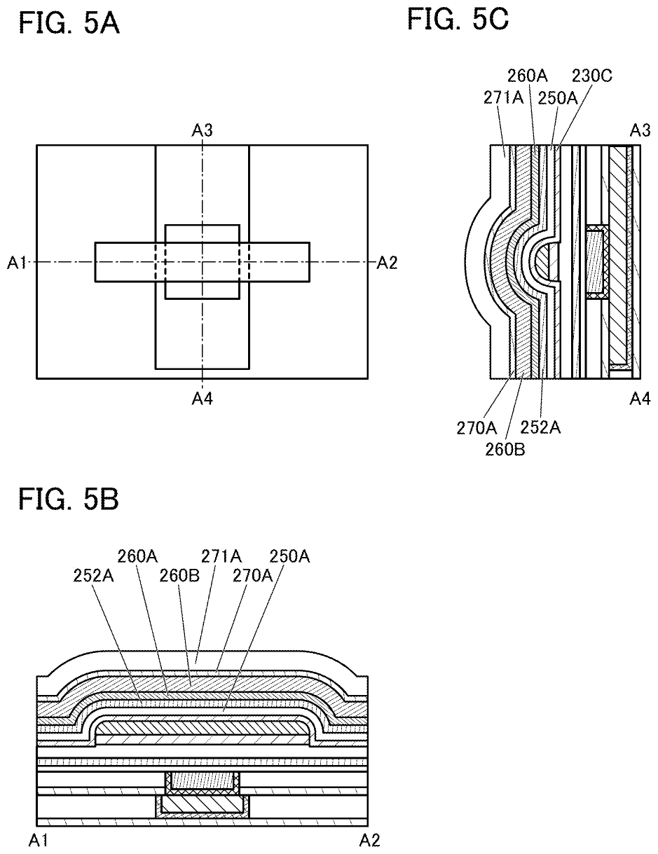

Next, an oxide film 230C to be the oxide 230c is deposited over the insulator 224, the oxide 230a, and the oxide 230b (see FIG. 5).

The oxide film 230C can be deposited by a sputtering method, a CVD method, an MBE method, a PLD method, an ALD method, or the like. The oxide film 230C may be deposited by a method similar to that for the oxide film 230A or the oxide film 230B in accordance with characteristics required for the oxide 230c. In this embodiment, the oxide film 230C is deposited by a sputtering method using a target with In:Ga:Zn=1:3:4 [atomic ratio].

Then, an insulating film 250A, a metal oxide film 252A, a conductive film 260A, a conductive film 260B, an insulating film 270A, and an insulating film 271A are deposited in this order over the oxide film 230C (see FIG. 5).

First, the insulating film 250A is deposited. The insulating film 250A can be deposited by a sputtering method, a CVD method, an MBE method, a PLD method, an ALD method, or the like. It is preferable to deposit silicon oxynitride by a CVD method for the insulating film 250A. Note that the deposition temperature at the time of the deposition of the insulating film 250A is preferably higher than or equal to 350° C. and lower than 450° C., particularly preferably approximately 400° C. When the insulating film 250A is deposited at 400° C., an insulator having few impurities can be deposited.

Note that oxygen is excited by microwaves to generate high-density oxygen plasma, and the insulating film 250A is exposed to the oxygen plasma, whereby oxygen can be introduced into the insulating film 250A.

Furthermore, heat treatment may be performed. For the heat treatment, the conditions for the above-described heat treatment can be used. The heat treatment can reduce the moisture concentration and the hydrogen concentration in the insulating film 250A.

Sequentially, the metal oxide film 252A, the conductive film 260A, and the conductive film 260B are deposited. As the metal oxide film 252A, an In—Ga—Zn oxide is formed by a sputtering method. The metal oxide film 252A is preferably formed by a sputtering method in an atmosphere containing an oxygen gas. Formation of the metal oxide film 252A in an atmosphere containing an oxygen gas can form an excess-oxygen region in the insulating film 250A. Excess oxygen added to the insulating film 250A can compensate for the oxygen vacancy in the oxide 230 when the oxygen is supplied to the oxide 230.

Here, when the deposition is performed in an oxygen gas atmosphere with a sputtering apparatus as a means for depositing the metal oxide film 252A, oxygen can be introduced into the insulating film 250A and the insulator 224 while the metal oxide film 252A is deposited. In addition, when an oxide of one or both of aluminum and hafnium that has a barrier property is used for the metal oxide film 252A, the excess oxygen introduced into the insulating film 250A can be effectively sealed therein.

The conductive film 260A and the conductive film 260B can be deposited by a sputtering method, a CVD method, an MBE method, a PLD method, an ALD method, or the like. For example, titanium nitride is preferably deposited as the conductive film 260A and tungsten is preferably deposited as the conductive film 260B.

As the conductive film 260A, a metal nitride is preferably formed by a sputtering method, for example. In the case where an oxide semiconductor typified by an In—Ga—Zn oxide is used as the metal oxide film 252A, for example, the metal oxide film 252A has a high carrier density when supplied with nitrogen or hydrogen. In other words, the oxide semiconductor functions as an oxide conductor (OC). Thus, when a metal nitride is formed by a sputtering method as the conductive film 260A, the constituent elements (nitrogen in particular) in the metal nitride are diffused into the metal oxide film 252A and the resistance of the metal oxide film 252A is reduced. Moreover, the resistance of the metal oxide film 252A is reduced by damage at the time of deposition of the conductive film 260A (e.g., sputtering damage). Accordingly, the metal oxide film 252A has a higher carrier density and thus the metal oxide film 252A has a higher conductivity.

Furthermore, when a low-resistance metal film is stacked as the conductive film 260B, a transistor with a low driving voltage can be provided.

Subsequently, heat treatment can be performed. For the heat treatment, the conditions for the above-described heat treatment can be used. Note that the heat treatment is not necessarily performed in some cases. Through the heat treatment, excess oxygen is added from the metal oxide film 252A to the insulating film 250A, whereby an excess-oxygen region can be easily formed in the insulating film 250A.

The insulating film 270A can be deposited by a sputtering method, a CVD method, an MBE method, a PLD method, an ALD method, or the like. For the insulating film 270A functioning as a barrier film, an insulating material having a function of inhibiting the passage of oxygen and impurities such as water and hydrogen is used. For example, aluminum oxide or hafnium oxide is preferably used. Thus, oxidation of the conductor 260 can be inhibited. Moreover, this can inhibit entry of impurities such as water and hydrogen into the oxide 230 through the conductor 260 and the insulator 250.

The insulating film 271A can be deposited by a sputtering method, a CVD method, an MBE method, a PLD method, an ALD method, or the like. Here, the film thickness of the insulating film 271A is preferably larger than the film thickness of an insulating film 275A to be deposited in a later step. In that case, when the insulator 275 is formed in a later step, the insulator 271 can remain easily over the conductor 260.

Next, the insulating film 271A is etched to form the insulator 271. Here, the insulator 271 functions as a hard mask. When the insulator 271 is provided, the side surface of the insulator 250, the side surface of the metal oxide 252, a side surface of the conductor 260a, a side surface of the conductor 260b, and the side surface of the insulator 270 can be formed substantially perpendicular to a top surface of the substrate.

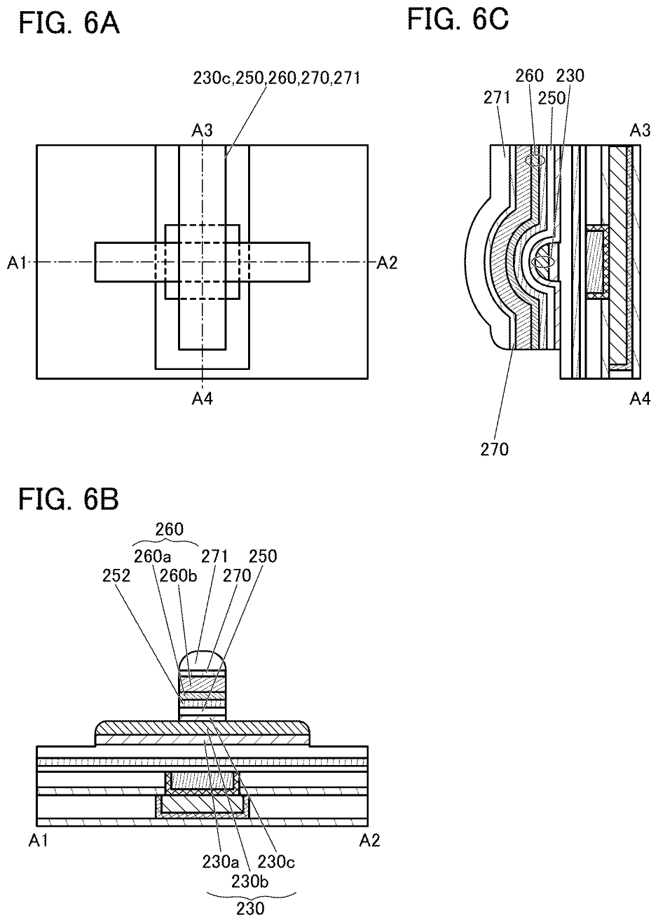

Then, with the use of the insulator 271 as a mask, the oxide film 230C, the insulating film 250A, the metal oxide film 252A, the conductive film 260A, the conductive film 260B, and the insulating film 270A are etched to form the oxide 230c, the insulator 250, the metal oxide 252, the conductor 260 (the conductor 260a and the conductor 260b), and the insulator 270 (see FIG. 6).

The oxide 230c, the insulator 250, the metal oxide 252, the conductor 260, the insulator 270, and the insulator 271 are formed to at least partly overlap with the conductor 205 and the oxide 230.

In addition, the side surface of the oxide 230c, the side surface of the insulator 250, the side surface of the metal oxide 252, the side surface of the conductor 260, and the side surface of the insulator 270 are preferably on the same surface.

It is also preferable that the surface shared by the side surface of the oxide 230c, the side surface of the insulator 250, the side surface of the metal oxide 252, the side surface of the conductor 260, and the side surface of the insulator 270 be substantially perpendicular to the top surface of the substrate. That is, in a cross-sectional shape, an angle between the top surface of the oxide 230 and the oxide 230c, the insulator 250, the metal oxide 252, the conductor 260, and the insulator 270 is preferably an acute angle and larger. Note that in the cross-sectional shape, a structure may be employed in which the angle formed by the side surfaces of the insulator 250, the metal oxide 252, the conductor 260, and the insulator 270 and the top surface of the oxide 230 is an acute angle. In that case, the angle formed by the side surfaces of the insulator 250, the metal oxide 252, the conductor 260, and the insulator 270 and the top surface of the oxide 230 is preferably larger.

Note that after the processing, the following process may be performed without removal of the hard mask (the insulator 271).

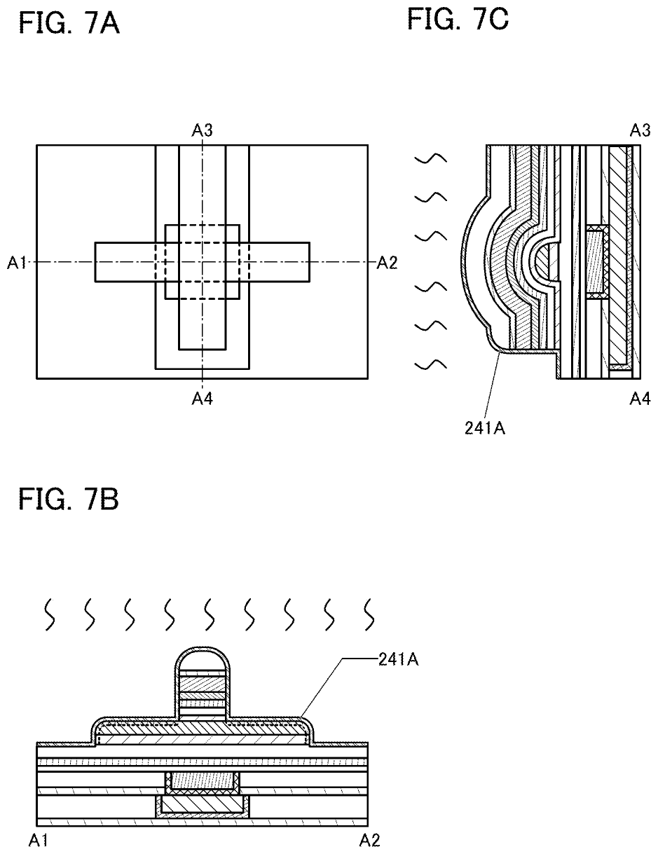

Subsequently, a film 241A is deposited over the insulator 224 and the oxide 230 with the oxide 230c, the insulator 250, the metal oxide 252, the conductor 260, the insulator 270, and the insulator 271 therebetween (see FIG. 7). Note that the thickness of the film 241A is preferably greater than or equal to 0.5 nm and less than or equal to 5 nm, further preferably greater than or equal to 1 nm and less than or equal to 3 nm. As the film 241A, a metal film, a nitride film containing a metal element, or an oxide film containing a metal element is used. For example, the film 241A is a film containing a metal element such as aluminum, ruthenium, titanium, tantalum, tungsten, or chromium. Note that the film 241A can be deposited by a sputtering method, a CVD method, an MBE method, a PLD method, an ALD method, or the like.

Subsequently, heat treatment is performed (see FIG. 7. Wavy lines in the figure indicate heat treatment.). By heat treatment in an atmosphere containing nitrogen, the metal element which is a component of the film 241A is diffused from the film 241A into the oxide 230 or the metal element which is a component of the oxide 230 is diffused into the film 241A, and the oxide 230 and the film 241A form a metal compound and the resistance can be reduced. A metal compound formed by the oxide 230 and the film 241A is in a relatively stable state, and thus a highly reliable semiconductor device can be provided.

Here, a region whose resistance is reduced by the formation of the metal compound of the metal element in the film 241A and the metal element in the oxide 230 is referred to as the region 242. Note that a compound layer may be formed at an interface between the film 241A and the oxide 230. Here, the compound layer is a layer including a metal compound containing a component of the film 241A and a component of the oxide 230. In this specification, the region 242 includes the compound layer in some cases. For example, as the compound layer, a layer in which the metal element in the oxide 230 and the metal element in the film 241A are alloyed may be formed. Being alloyed, the metal elements are brought into a relatively stable state, so that a highly reliable semiconductor device can be provided.

The heat treatment may be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The heat treatment is performed in nitrogen or an inert gas atmosphere. The heat treatment may be performed under a reduced pressure.

Moreover, oxygen in the vicinity of the interface between the oxide 230 and the film 241A is absorbed by the film 241A in some cases. As a result, the resistance of the vicinity of the interface between the oxide 230 and the film 241A is reduced. In contrast, in some cases, the film 241A, which is oxidized by oxygen absorbed from the oxide 230, becomes a high-resistance insulator.

Part of the oxide 230 may be alloyed with the above-described metal element by the heat treatment. When part of the oxide 230 is alloyed with the metal element, the metal element added to the oxide 230 is brought into a relatively stable state; therefore, a highly reliable semiconductor device can be provided. The film 241A whose resistance is increased may be used as an interlayer film.

Alternatively, heat treatment may be performed in a nitrogen atmosphere or an inert gas atmosphere, and then another heat treatment may be performed in an atmosphere containing an oxidizing gas at 10 ppm or more, 1% or more, or 10% or more. The heat treatment may be performed at higher than or equal to 250° C. and lower than or equal to 650° C., preferably higher than or equal to 300° C. and lower than or equal to 500° C., further preferably higher than or equal to 320° C. and lower than or equal to 450° C.

For example, in the case where a region having conductivity remains in the film 241A, heat treatment in an oxidization atmosphere oxidizes the film 241A, whereby the film 241A becomes an insulator and the resistance thereof is increased. The film 241A that remains as an insulator can function as an interlayer film.

Note that the film 241A may be removed. For example, as a method for removal, a dry etching method or a wet etching method can be used. At the same time as the film 241A is removed, hydrogen absorbed by the film 241A from the oxide 230 can be removed. Thus, hydrogen, which is an impurity in the transistor 200, can be reduced.

With the above structure, the regions of the oxide 230 can be formed in a self-aligned manner. Thus, minute or highly integrated semiconductor devices can be manufactured with high yield.

Note that the step of forming the region 242 may be performed after the formation of the insulator 275. In that case, a low-resistance region is not formed in a region where the oxide 230 and the insulator 275 overlap with each other, in some cases. That is, in some cases, a region having a higher resistance value (hereinafter also referred to as an Loff region) than the region 242 is formed between the region 242 and the region 234 of the oxide 230. When the Loff region is provided between the region 242 and the region 234, the leakage current in a non-conduction state (off-state current) can be reduced.

Thus, by appropriately selecting the areas of the regions, a transistor having electrical characteristics that meet the demand for the circuit design can be easily provided.

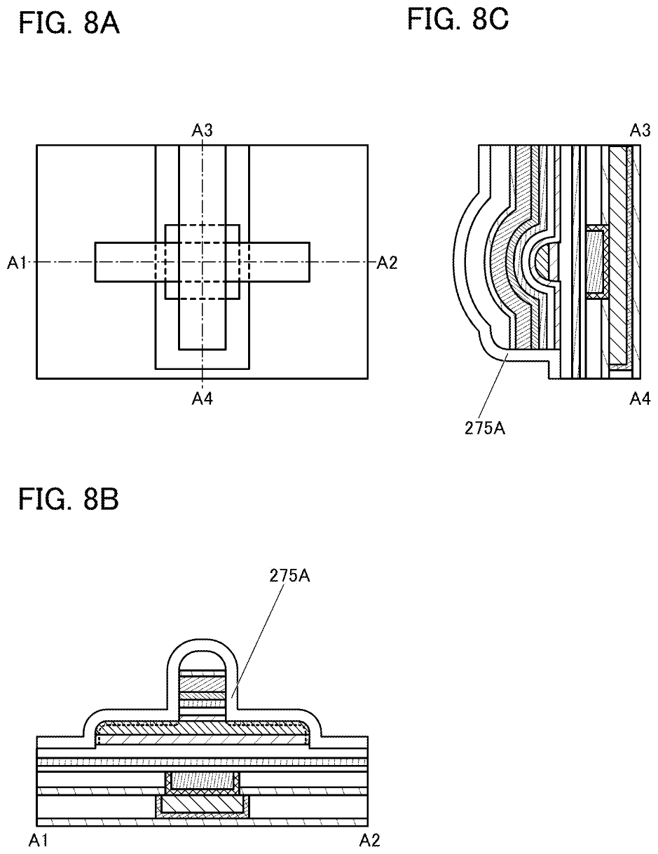

Next, the insulating film 275A is deposited to cover the oxide 230, the insulator 250, the metal oxide 252, the conductor 260, the insulator 270, and the insulator 271 (see FIG. 8).

The insulating film 275A preferably includes an insulator with a low relative permittivity. For example, the insulating film 275A preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide, silicon oxynitride, silicon nitride oxide, or porous silicon oxide is preferably used for the insulating film 275A because an excess-oxygen region can be easily formed in the insulator 275 in a later step. Furthermore, silicon oxide and silicon oxynitride, which have thermal stability, are preferable.

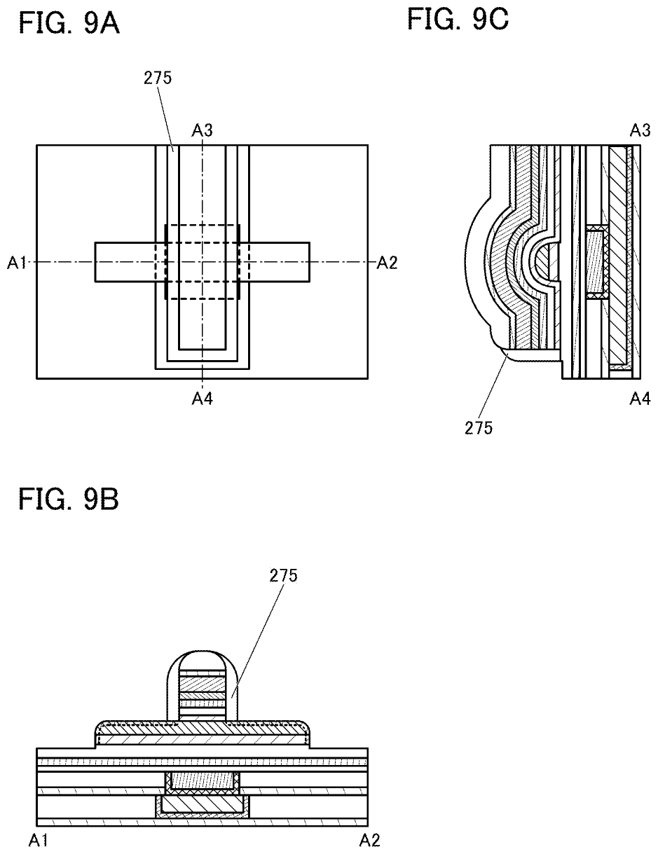

Next, the insulating film 275A is subjected to anisotropic etching treatment, whereby the insulator 275 is formed on the side surface of the oxide 230c, the side surface of the insulator 250, the side surface of the metal oxide 252, the side surface of the conductor 260, and the side surface of the insulator 270 (see FIG. 9). Note that in this step, the insulator 224 may be processed into an island shape. In that case, the insulator 222 can be used as an etching stopper film.

Although not illustrated, the insulator 275 may remain also on the side surface of the insulator 224. In that case, coverage with an interlayer film or the like to be deposited in a later step can be improved. Furthermore, since a structure body which is the insulator 275 remaining on the side surface of the insulator 224 is formed, an excess-oxygen region can also be provided in the insulator 224.

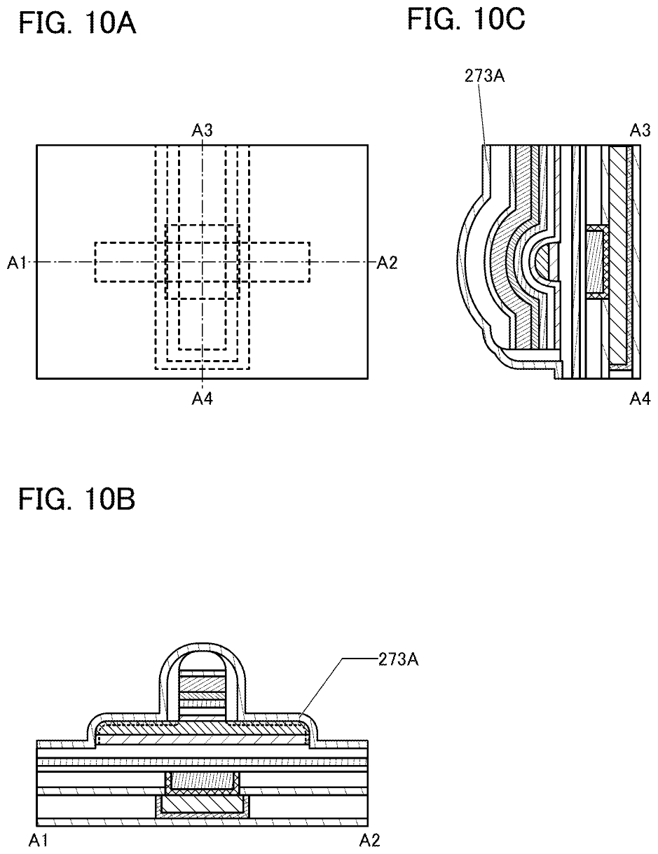

Subsequently, an insulating film 273A to be the insulator 273 is formed over the insulator 275 and the oxide 230 (see FIG. 10).

The insulating film 273A is preferably deposited by a sputtering method. When a sputtering method is used, an insulator containing few impurities such as water and hydrogen can be deposited. For example, for the insulator 273, aluminum oxide is preferably used.

Note that, in some cases, an oxide film formed by a sputtering method extracts hydrogen from the structure body over which the oxide film is deposited. Thus, the hydrogen concentrations in the oxide 230 and the insulator 275 can be reduced when hydrogen and water are absorbed from the oxide 230 and the insulator 275.

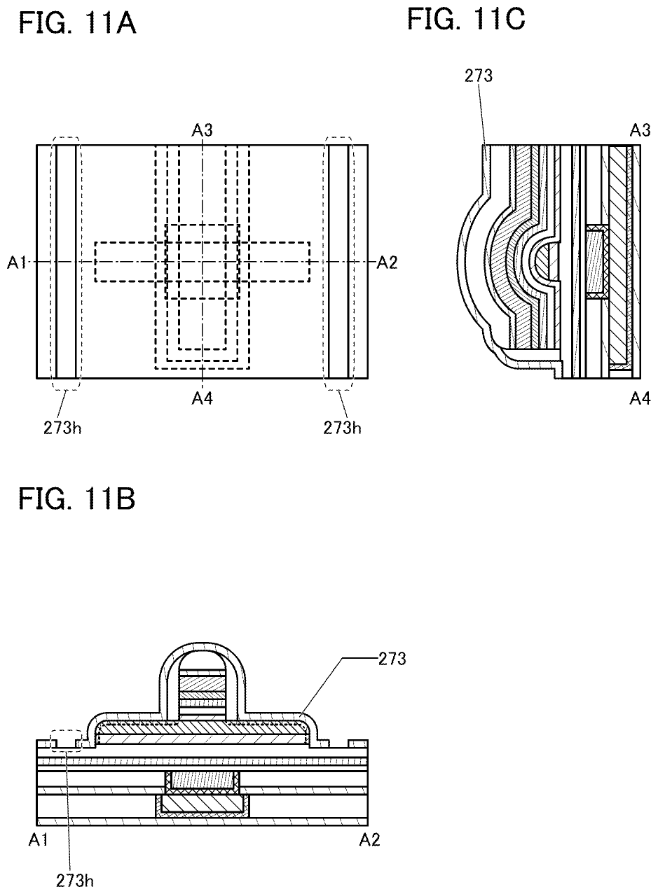

Next, the opening portion 273h is provided in the insulating film 273A, whereby the insulator 273 is formed (see FIG. 11). The opening portion 273h is formed by a lithography method. Note that the opening portion 273h is provided so as to expose the insulator 275 or the insulator 224. The opening portion 273h may be designed as appropriate depending on the shape, size, integration, or layout of the transistor 200. For example, the opening portion 273h may be a circular or polygonal hole, groove, slit, or the like.

That is, the excess oxygen contained in the insulator 280 reduces oxygen vacancies in the oxide 230 through the insulator 224, the insulator 275, the insulator 250, and the like, whereby reliability can be improved. Furthermore, by providing the insulator 273 including the opening portion 273h, the excess oxygen contained in the insulator 280 can be inhibited from being diffused into the oxide 230 at a value exceeding the proper value.

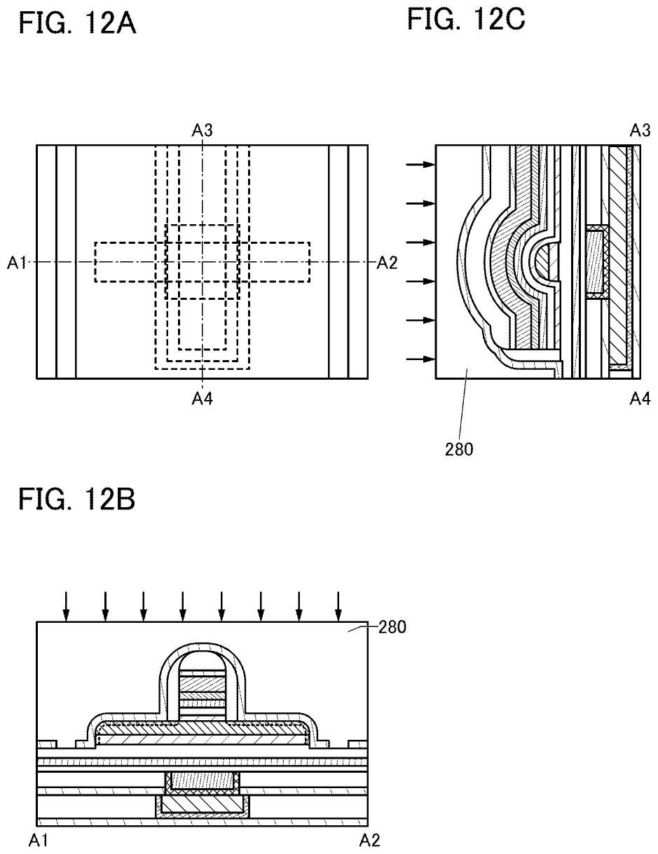

Then, the insulator 280 is deposited over the insulator 273 (see FIG. 12). The insulator 280 can be deposited by a sputtering method, a CVD method, an MBE method, a PLD method, an ALD method, or the like. Alternatively, the insulator 280 can be formed by a spin coating method, a dipping method, a droplet discharging method (such as an ink-jet method), a printing method (such as screen printing or offset printing), a doctor knife method, a roll coater method, a curtain coater method, or the like. For example, silicon oxynitride may be used for the insulator 280.

Next, the insulator 280 is partly removed. The insulator 280 is preferably formed to have a flat top surface. For example, the insulator 280 may have a flat top surface right after the deposition. Alternatively, for example, the insulator 280 may have a flat top surface by removing the insulator or the like from the top surface after the deposition so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not necessarily have planarity.

Next, the excess-oxygen region is provided in the insulator 280. In order to provide the excess-oxygen region in the insulator 280, oxygen (including at least oxygen radicals, oxygen atoms, or oxygen ions) is introduced into the insulator 280, whereby a region containing oxygen in excess is formed.

For example, oxygen ions can be introduced into the insulator 280 by an ion implantation method, an ion doping method, a plasma immersion ion implantation method, plasma treatment, or the like. For example, as the oxygen introduction treatment, the treatment may be performed by an ion implantation method using a gas containing oxygen. As the gas containing oxygen, oxygen, dinitrogen monoxide, nitrogen dioxide, carbon dioxide, carbon monoxide, or the like can be used. A rare gas may be contained in the gas containing oxygen in the oxygen introduction treatment; for example, a mixed gas of carbon dioxide, hydrogen, and argon can be used.

In particular, treatment conditions can be set as appropriate when an ion implantation method, an ion doping method, a plasma immersion ion implantation method, plasma treatment, or the like is used. Thus, the amount of excess oxygen included in the insulator 280 can be adjusted or controlled depending on the shape, size, integration, or layout of the transistor.

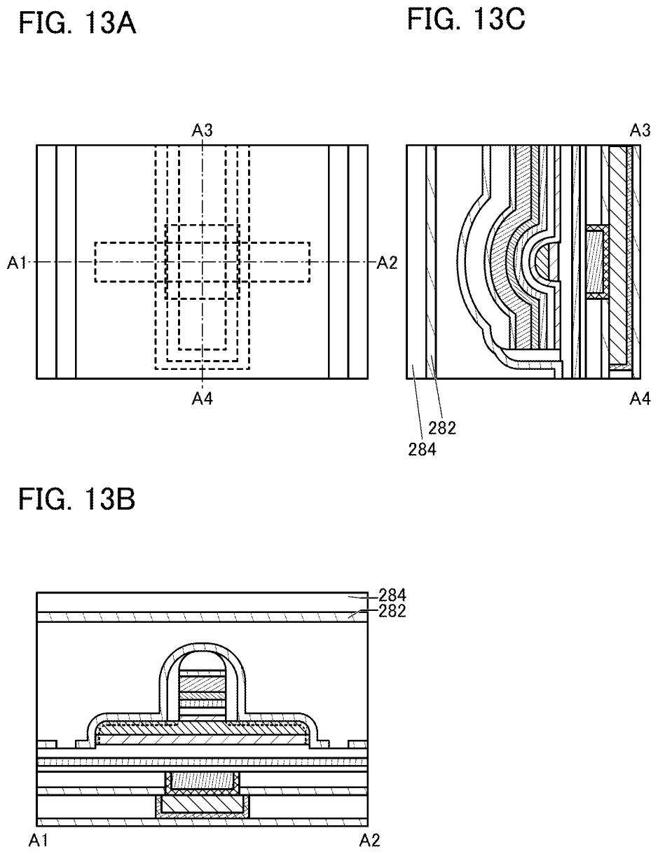

Subsequently, the insulator 282 is formed over the insulator 280 (see FIG. 13). The insulator 282 is preferably deposited with a sputtering apparatus. This structure can prevent hydrogen from entering a component underlying the insulator 282. Furthermore, hydrogen or water in the insulator 280 is absorbed by the insulator 282, so that the impurity concentration in the insulator 280 can be reduced.

A method for stacking oxides over the insulator 280 using a sputtering apparatus is given as an example of the oxygen introduction treatment. For example, when the deposition in an oxygen gas atmosphere is performed using a sputtering apparatus as a means for depositing the insulator 282, oxygen can be introduced into the insulator 280 while the insulator 282 is deposited.

Subsequently, the insulator 284 is formed over the insulator 282 (see FIG. 13). As the insulator 284, an insulator containing oxygen, such as a silicon oxide film or a silicon oxynitride film, is formed by a CVD method, for example. The permittivity of the insulator 284 is preferably lower than that of the insulator 282. When a material with a low permittivity is used for an interlayer film, the parasitic capacitance generated between wirings can be reduced.

Next, openings reaching the oxide 230 are formed in the insulator 284, the insulator 282, the insulator 280, and the insulator 273. The openings may be formed by a lithography method. Note that in order that the conductor 240s and the conductor 240d are provided in contact with the side surfaces of the oxide 230, the openings reaching the oxide 230 are formed such that the side surfaces of the oxide 230 are exposed in the openings.

Next, a conductive film to be a first conductor of the conductor 240 and a conductive film to be a second conductor of the conductor 240 are deposited. The conductive films can be deposited by a sputtering method, a CVD method, an MBE method, a PLD method, an ALD method, or the like.

Here, for example, the low-resistance region of the region 242 might be removed when the openings are formed in the insulator 284, the insulator 282, the insulator 280, and the insulator 273. In this case, the first conductor of the conductor 240 is preferably formed using a metal film, a nitride film containing a metal element, or an oxide film containing a metal element. That is, since the oxide 230 is in contact with the first conductor of the conductor 240, a metal compound or an oxygen vacancy is formed in the contact region, whereby the resistance of the contact region between the oxide 230 and the conductor 240 can be reduced. The reduction in the resistance of the oxide 230 that is in contact with the first conductor of the conductor 240 can reduce contact resistance between the oxide 230 and the conductor 240. Therefore, the first conductor of the conductor 240 preferably contains a metal element such as aluminum, ruthenium, titanium, tantalum, tungsten, or chromium, for example.

Next, CMP treatment is performed to remove part of the conductive film to be the conductor 240s and the conductor 240d, so that the insulator 284 is exposed. As a result, the conductive film remains only in the opening, so that the conductor 240s and the conductor 240d having flat top surfaces can be formed (see FIG. 1).

Through the above process, the semiconductor device including the transistor 200 can be manufactured. As illustrated in FIG. 3 to FIG. 13, with the use of the method for manufacturing the semiconductor device described in this embodiment, the transistor 200 can be formed.

According to one embodiment of the present invention, a semiconductor device having favorable electrical characteristics can be provided. Alternatively, according to one embodiment of the present invention, a semiconductor device having a low off-state current can be provided. Alternatively, according to one embodiment of the present invention, a semiconductor device having a high on-state current can be provided. Alternatively, according to one embodiment of the present invention, a highly reliable semiconductor device can be provided. Alternatively, according to one embodiment of the present invention, a semiconductor device that can be miniaturized or highly integrated can be provided. Alternatively, according to one embodiment of the present invention, a semiconductor device in which power consumption is reduced can be provided. Alternatively, according to one embodiment of the present invention, a semiconductor device with high productivity can be provided.

The structure, method, and the like described above in this embodiment can be used in combination as appropriate with the structures, methods, and the like described in the other embodiments.

### <Modification Example of Semiconductor Device>

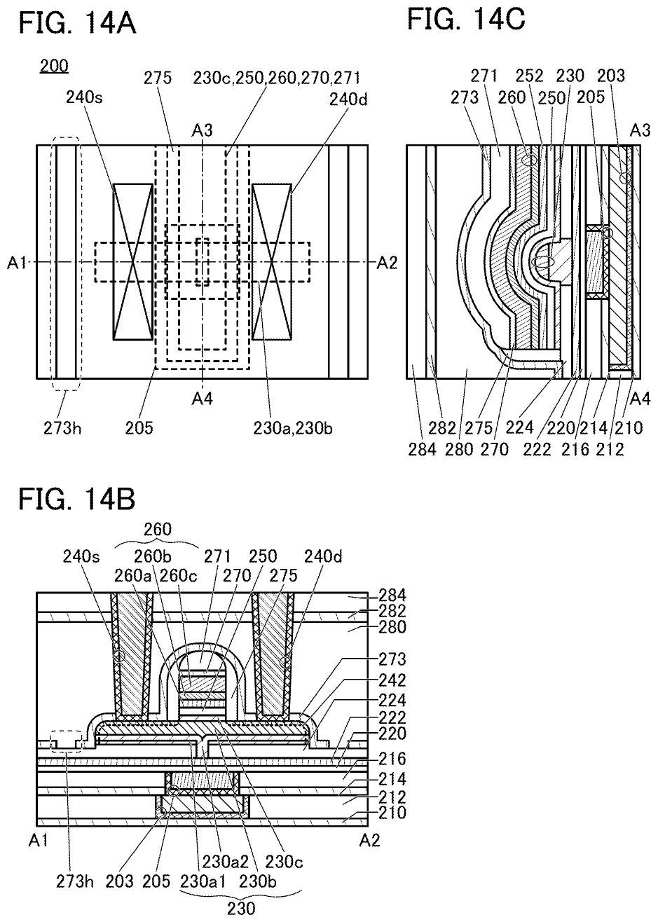

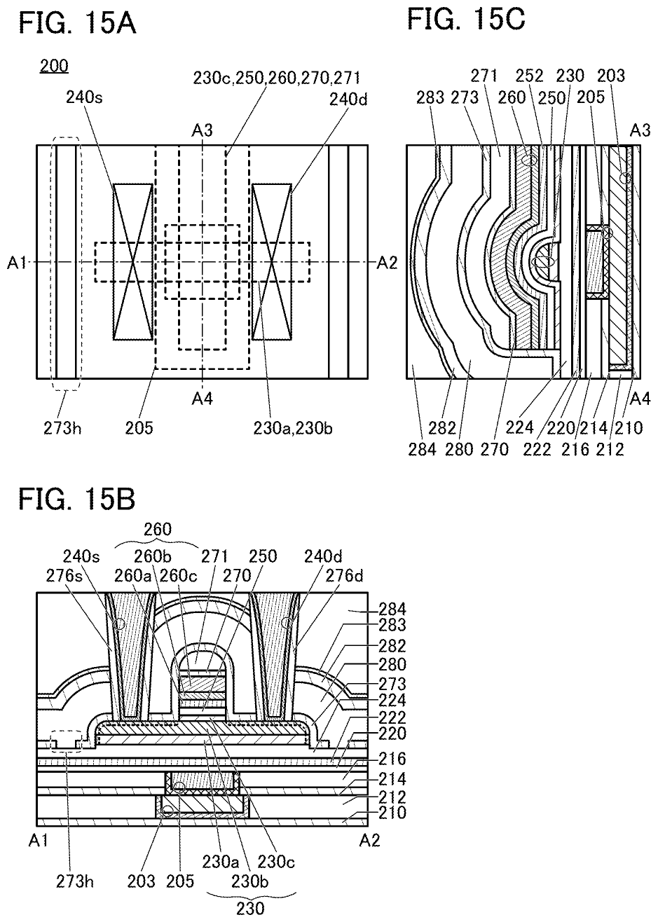

Examples of semiconductor devices including the transistor 200 of one embodiment of the present invention will be described below with reference to FIG. 14 and FIG. 15.

Here, (A) of each drawing is a top view. Moreover, (B) of each drawing is a cross-sectional view corresponding to a portion indicated by dashed-dotted line A1-A2 in (A). Furthermore, (C) of each drawing is a cross-sectional view corresponding to a portion indicated by dashed-dotted line A3-A4 in (A).

Note that in the semiconductor devices illustrated in FIG. 14 and FIG. 15, components having the same functions as the components included in the semiconductor device described in <Structure example of semiconductor device> are denoted by the same reference numerals.

The structures of the semiconductor devices are described below with reference to FIG. 14 and FIG. 15. Note that the materials described in detail in <Structure example of semiconductor device> can also be used as materials of the semiconductor devices in this section.

### [Modification Example 1 of Semiconductor Device]

The semiconductor device illustrated in FIG. 14 is different from the semiconductor device described in <Structure example of semiconductor device> in that an oxide 230a1 and an oxide 230a2 are provided instead of the oxide 230a. Note that the oxide 230a1 has a slit or an opening portion in a region overlapping with the region 234 of the oxide 230b. Thus, the oxide 230a2 provided over the oxide 230a1 is in contact with the insulator 224 through the slit.

Note that part of the insulator 224 may be removed when the slit or the opening portion is formed. Furthermore, for example, when the processing is performed, the insulator 222 may function as an etching stopper film.

Furthermore, the oxide 230a1 preferably has higher capability of inhibiting diffusion of oxygen than the oxide 230a2 and the oxide 230b. Specifically, in the case where an In-M-Zn oxide (the element M is one or a plurality of kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is used for the oxide 230, the higher the proportion of Zn atoms in the total number of metal atoms is, the higher the capability of inhibiting diffusion of oxygen is likely to be. Therefore, it is preferable that the oxide 230a1 be formed using an In-M-Zn oxide with a higher proportion of Zn atoms in the total number of metal atoms than that of the oxide 230a2 and the oxide 230b.

With the above structure, it is highly probable that the excess oxygen contained in the insulator 280 is diffused to the oxide 230a2 rather than the oxide 230a1 when supplied to the oxide 230 through the opening portion 273h of the insulator 273 and the insulator 224. Furthermore, since the slit in the oxide 230a1 overlaps with the region overlapping with the region 234 of the oxide 230, the excess oxygen preferentially compensates for oxygen vacancies generated in the region 234 of the oxide 230. Thus, the region 234 of the oxide 230, which functions as a channel formation region, can be highly purified intrinsic.

Accordingly, a highly reliable transistor with a small variation in the electrical characteristics can be provided. Moreover, a transistor having electrical characteristics that meet the demand for the circuit design can be easily provided.

### [Modification Example 2 of Semiconductor Device]

The semiconductor device illustrated in FIG. 15 is different from the semiconductor device described in <Structure example of semiconductor device> in that an insulator 276 (an insulator 276s and an insulator 276d) functioning as a barrier layer is provided between the conductor 240 and the insulator 280, the insulator 282, and the insulator 284 functioning as interlayer films. Note that in the case of this structure, the insulator 276 and the insulator 282 preferably have a barrier property against oxygen, hydrogen, and water.

Specifically, as illustrated in FIG. 15, the insulator 276 is preferably provided between the conductor 240 and the insulator 280 and the insulator 282 having a barrier property. It is particularly preferable that the insulator 276 be provided in contact with the insulator 282 having a barrier property. When the insulator 276 is provided in contact with the insulator 282, the insulator 276 can be extended to the insulator 284 and diffusion of oxygen and impurities can be further inhibited.

That is, with the insulator 276, a decrease in reliability of the semiconductor device due to diffusion of impurities contained in the insulator 280 into the transistor 200 through the conductor 240 can be inhibited. Furthermore, with the insulator 276, the range of choices for the materials of the conductor used for a plug or a wiring can be expanded.

A metal oxide can be used for the insulator 276, for example. In particular, an insulating film having a barrier property against oxygen or hydrogen, such as aluminum oxide, hafnium oxide, or gallium oxide, is preferably used. Alternatively, silicon nitride formed by a chemical vapor deposition (CVD) method may be used.

The insulator 280 covering the transistor 200 is not necessarily planarized. Since the coverage with the insulator 282 is reduced in that case, the insulator 283 may be provided. Note that like the insulator 282, the insulator 283 preferably has a function of inhibiting diffusion of oxygen. Moreover, the insulator 283 is preferably deposited by an ALD method. This is because an ALD method is less likely to be influenced by the shape of an object and thus has favorable step coverage, owing to its excellent step coverage and excellent thickness uniformity.

In that case, the insulator 284 may function as a planarization film that covers roughness. This structure makes it easy to form another structure body over the transistor 200, which enables high integration.

Note that the amount of excess oxygen contained in the insulator 280 can be easily derived when the insulator 280 is not planarized. That is, the volume of the insulator 280 affects the amount of excess oxygen that can be contained in the insulator 280. When the insulator 280 is not planarized, the volume of the insulator 280 can be roughly estimated by the deposition thickness, so that the transistor and the circuit are easily designed.

The insulator 275 is not necessarily formed. For example, in the case where the opening portion 273h included in the insulator 273 is provided only over the insulator 224, the excess oxygen contained in the insulator 280 is supplied from the insulator 224. In other words, in the case where the excess oxygen is supplied from below the oxide 230 without passing through the insulator 250, the insulator 275 is not necessarily provided.

Note that in the case where the insulator 275 is not provided, the amount of excess oxygen contained in the insulator 280, the distance between the opening portion 273h and the region 234 of the oxide 230, and the like are preferably determined so that oxygen vacancies generated in the oxide 230 are compensated for without excess or deficiency by the excess oxygen diffused from the insulator 224.

The structure, composition, method, and the like described above in this embodiment can be used in appropriate combination with the structures, compositions, methods, and the like described in the other embodiments.

### Embodiment 2

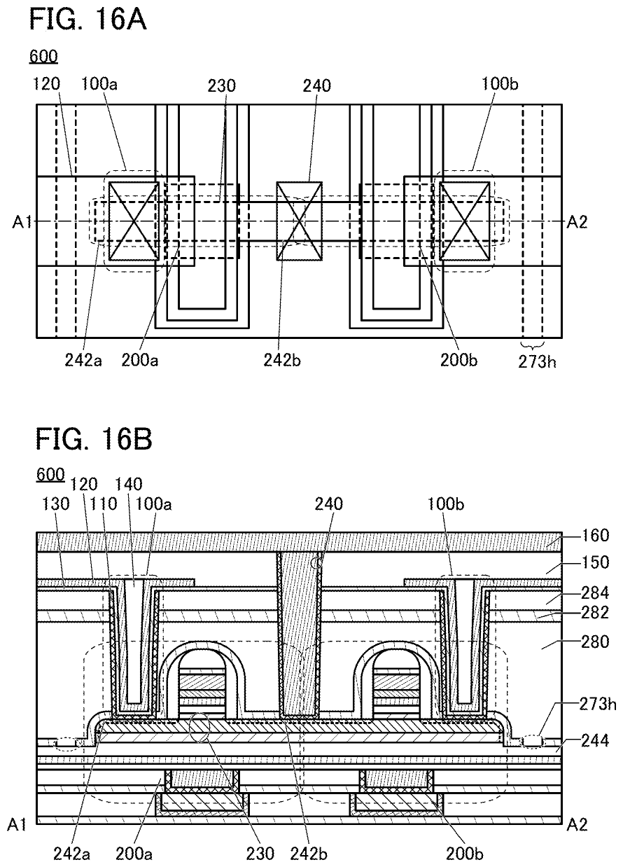

In this embodiment, a mode of a semiconductor device that functions as a memory device and is different from one in the above embodiment will be described with reference to FIG. 16 to FIG. 18.

### <Memory Device>

FIG. 16(A) and FIG. 16(B) illustrate a cell 600 included in a memory device. The cell 600 includes a transistor 200a, a transistor 200b, a capacitor 100a, and a capacitor 100b. FIG. 16(A) is a top view of the cell 600. FIG. 16(B) is a cross-sectional view of a portion indicated by dashed-dotted line A1-A2 in FIG. 16(A). Note that for simplification of the drawing, some components are omitted in the top view of FIG. 16(A).

The cell 600 includes the transistor 200a, the transistor 200b, the capacitor 100a that overlaps with the transistor 200a, and the capacitor 100b that overlaps with the transistor 200b. In the cell 600, in some cases, the transistor 200a and the transistor 200b are arranged to be axisymmetric to each other and the capacitor 100a and the capacitor 100b are arranged to be axisymmetric to each other. It is thus preferable that the transistor 200a and the transistor 200b have similar structures and the capacitor 100a and the capacitor 100b have similar structures.

An insulator 130 is provided over the insulator 284 over the transistor 200a and the transistor 200b, and an insulator 150 is provided over the insulator 130. Here, an insulator that can be used for the insulator 284 may be used for the insulator 150.

Furthermore, a conductor 160 is provided over the insulator 150. The conductor 240 is provided to be embedded in an opening formed in the insulator 280, the insulator 284, the insulator 130, and the insulator 150. A bottom surface of the conductor 240 is in contact with the region 242 and the top surface of the conductor 240 is in contact with the conductor 160.

The transistor 200 described in the above embodiment can be used as the transistor 200a and the transistor 200b. Therefore, the above description of the transistor 200 can be referred to for the structures of the transistor 200a and the transistor 200b. In FIG. 16(A) and FIG. 16(B), reference numerals for the components of the transistor 200a and the transistor 200b are omitted. Note that the transistor 200a and the transistor 200b in FIG. 16(A) and FIG. 16(B) are only examples and are not limited to the structures, and an appropriate transistor may be used in accordance with a circuit configuration or a driving method.

Both the transistor 200a and the transistor 200b are formed in the oxide 230, and one of a source and a drain of the transistor 200a is also used as one of a source and a drain of the transistor 200b. Accordingly, the one of the source and the drain of the transistor 200a and the one of the source and the drain of the transistor 200b are electrically connected to the conductor 240. In this manner, the transistor 200a and the transistor 200b share a contact portion, which reduces the number of plugs and contact holes. Sharing a wiring which is electrically connected to one of a source and a drain as described above can further reduce the area occupied by a memory cell array.

[Capacitor 100a and Capacitor 100b]

As illustrated in FIG. 16(A) and FIG. 16(B), the capacitor 100a is provided in a region overlapping with the transistor 200a. In a similar manner, the capacitor 100b is provided in a region overlapping with the transistor 200b. Note that components of the capacitor 100b correspond to those of the capacitor 100a. The structure of the capacitor 100a is described in detail below, and unless otherwise specified, the description for the capacitor 100a can be referred to for the capacitor 100b.

The capacitor 100a includes a conductor 110, the insulator 130, and a conductor 120 over the insulator 130. Here, for the conductor 110 and the conductor 120, a conductor that can be used for the conductor 203, the conductor 205, the conductor 260, or the like can be used.

The capacitor 100a is formed in an opening provided in the insulator 273, the insulator 280, the insulator 282, and the insulator 284. At a bottom surface and a side surface of the opening, the conductor 110 functioning as a lower electrode and the conductor 120 functioning as an upper electrode face each other with the insulator 130 functioning as a dielectric therebetween. Here, the conductor 110 of the capacitor 100a is formed in contact with the other of the source and the drain of the transistor 200a.

In particular, with the deeper opening in the insulator 280 and the insulator 284, the capacitor 100a can have increased capacitance without an increase in its projected area. Therefore, the capacitor 100a preferably has a cylinder shape (the side surface area is larger than the bottom surface area).

The above structure allows the capacitance per unit area of the capacitor 100a to be high, which promotes miniaturization and higher integration of the semiconductor device. The capacitance value of the capacitor 100a can be appropriately set by the thicknesses of the insulator 280 and the insulator 284. Thus, a semiconductor device with high design flexibility can be provided.

An insulator having a high permittivity is preferably used for the insulator 130. For example, an insulator containing an oxide of one or both of aluminum and hafnium can be used. Aluminum oxide, hafnium oxide, an oxide containing aluminum and hafnium (hafnium aluminate), or the like is preferably used as the insulator containing an oxide of one or both of aluminum and hafnium.

The insulator 130 may have a stacked-layer structure; for example, two or more layers selected from silicon oxide, silicon oxynitride, silicon nitride oxide, silicon nitride, aluminum oxide, hafnium oxide, an oxide containing aluminum and hafnium (hafnium aluminate), and the like may be used for the stacked-layer structure. For example, it is preferable that hafnium oxide, aluminum oxide, and hafnium oxide be deposited in this order by an ALD method to form a stacked-layer structure. Hafnium oxide and aluminum oxide each have a thickness of greater than or equal to 0.5 nm and less than or equal to 5 nm. With such a stacked-layer structure, the capacitor 100a can have a large capacitance value and a low leakage current.

Note that the conductor 110 or the conductor 120 may have a stacked-layer structure. For example, the conductor 110 or the conductor 120 may have a stacked-layer structure of a conductive material containing titanium, titanium nitride, tantalum, or tantalum nitride as its main component and a conductive material containing tungsten, copper, or aluminum as its main component. The conductor 110 or the conductor 120 may have a single-layer structure or a stacked-layer structure of three or more layers.

### [Configuration of Cell Array]

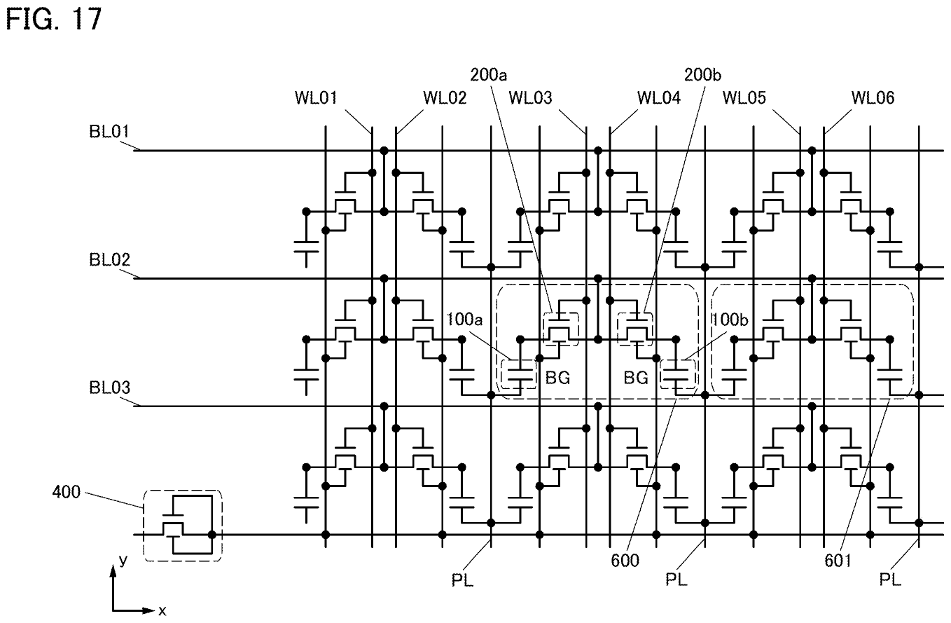

Next, an example of a cell array in which the above-described cells are arranged in a matrix will be described with reference to FIG. 17.

FIG. 17 is a circuit diagram showing an embodiment in which the cells 600 illustrated in FIG. 16 are arranged in a matrix. In FIG. 17, the extending direction of a wiring BL is the x-direction, the extending direction of a wiring WL is the y-direction, and the direction perpendicular to the x-y plane is the z-direction. Note that although FIG. 17 illustrates an example in which the cells are arranged in a 3×3 matrix, this embodiment is not limited thereto and the number and arrangement of the memory cells, the wirings, or the like included in the cell array are set as appropriate.

As illustrated in FIG. 17, one of the source and the drain of each of the transistor 200a and the transistor 200b which are included in the cell is electrically connected to the common wiring BL (BL01, BL02, and BL03). Furthermore, the wiring BL is also electrically connected to one of the source and the drain of each of the transistor 200a and the transistor 200b included in each of the cells 600 arranged in the x-direction. A first gate of the transistor 200a and a first gate of the transistor 200b, which are included in the cell 600, are electrically connected to different wirings WL (WL01 to WL06). Furthermore, these wirings WL are electrically connected to the first gates of the transistors 200a and the first gates of the transistors 200b which are included in the cells 600 arranged in the y-direction.

Furthermore, one electrode of the capacitor 100a and one electrode of the capacitor 100b in the cell 600 are electrically connected to wirings PL. For example, the wirings PL are formed to extend in the y-direction.

In addition, the transistor 200a and the transistor 200b in each cell 600 may each be provided with a second gate BG. The threshold voltage of the transistor can be controlled by a potential applied to the BG. The BG is connected to a transistor 400 and the potential applied to the BG can be controlled by the transistor 400.

For example, as illustrated in FIG. 17, the conductor 160 extends in the x-direction to function as the wiring BL, the conductor 260 extends in the y-direction to function as the wiring WL, and the conductor 120 extends in the y-direction to function as the wiring PL. In addition, the conductor 203 may extend in the y-direction to function as a wiring connected to the BG.

As shown in FIG. 17, it is preferable that the conductor 120 functioning as the one electrode of the capacitor 100b in the cell 600 also function as one electrode of the capacitor 100a in a cell 601. Furthermore, the conductor 120 functioning as the one electrode of the capacitor 100a in the cell 600 also functions as one electrode of a capacitor in the adjacent cell on the left side of the cell 600, although not shown. The same applies to a cell on the right side of the cell 601. Thus, a cell array can be formed. With this structure of the cell array, the space between the adjacent cells can be reduced; thus, the projected area of the cell array can be reduced and high integration can be achieved.

The oxides 230 and the wirings WL are arranged in a matrix, whereby the semiconductor device in the circuit diagram in FIG. 17 can be formed. Here, the wirings BL are preferably provided in a layer different from the wirings WL and the oxides 230. In particular, the capacitor 100a and the capacitor 100b are provided below the wirings BL, in which case the long side direction of the oxide 230 and the wiring BL can be substantially parallel to each other in the layout. Accordingly, the layout of the cell can be simplified, the design flexibility is increased, and the process cost can be reduced.

For example, the oxide 230 and the wiring WL may be provided such that the long side of the oxide 230 is substantially orthogonal to the extending direction of the wiring WL. Alternatively, for example, a layout may be employed in which the long side of the oxide 230 is not orthogonal to the extending direction of the wiring WL and the long side of the oxide 230 and the extending direction of the wiring WL intersect at an angle other than a right angle. With an angle of greater than 0° and less than 90°, for example, the capacitor 100a and the capacitor 100b can be arranged without intersecting with the wiring BL; thus, the capacitor 100a and the capacitor 100b can extend in the z-direction, increasing the capacitance of the capacitor 100a and the capacitor 100b. The oxide 230 and the wiring WL are preferably provided such that an angle between the long side of the oxide 230 and the wiring WL is greater than or equal to 20° and less than or equal to 70°, preferably greater than or equal to 30° and less than or equal to 60°.

Furthermore, stacked cell arrays may be used instead of the single-layer cell array. By stacking a plurality of cell arrays, the cells can be integrated without an increase in the area occupied by the cell arrays. In other words, a 3D cell array can be formed.

As described above, according to one embodiment of the present invention, a semiconductor device that can be miniaturized or highly integrated can be provided. Alternatively, according to one embodiment of the present invention, a semiconductor device having favorable electrical characteristics can be provided. Alternatively, according to one embodiment of the present invention, a semiconductor device having a low off-state current can be provided. Alternatively, according to one embodiment of the present invention, a transistor having a high on-state current can be provided. Alternatively, according to one embodiment of the present invention, a highly reliable semiconductor device can be provided. Alternatively, according to one embodiment of the present invention, a semiconductor device in which power consumption is reduced can be provided. Alternatively, according to one embodiment of the present invention, a semiconductor device with high productivity can be provided.

The structure, method, and the like described above in this embodiment can be used in combination as appropriate with the structures, methods, and the like described in the other embodiments.

### Embodiment 3

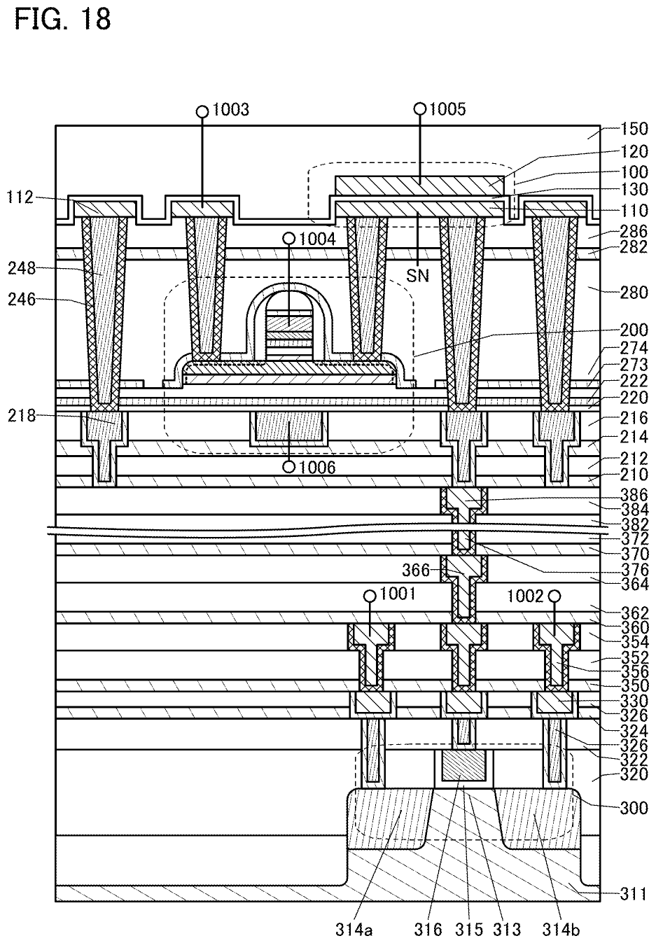

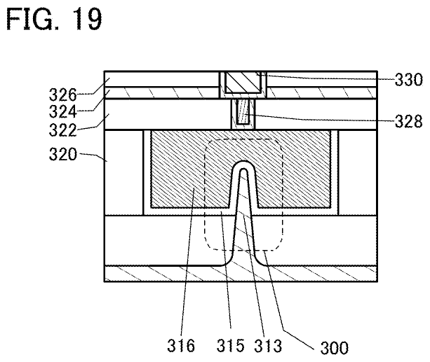

In this embodiment, one embodiment of a semiconductor device will be described with reference to FIG. 18 and FIG. 19.

### <Memory Device>

A memory device illustrated in FIG. 18 and FIG. 19 includes a transistor 300, the transistor 200, and the capacitor 100. FIG. 18 is a cross-sectional view of the transistor 200 and the transistor 300 in the channel length direction. FIG. 19 is a cross-sectional view of the vicinity of the transistor 300 in the channel width direction of the transistor 300.

The transistor 200 is a transistor in which a channel is formed in a semiconductor layer including an oxide semiconductor. Since the off-state current of the transistor 200 is low, a memory device including the transistor 200 can retain stored data for a long time. In other words, such a memory device does not require refresh operation or has an extremely low frequency of the refresh operation, which leads to a sufficient reduction in power consumption of the memory device.

In the memory device illustrated in FIG. 18, a wiring 1001 is electrically connected to a source of the transistor 300, and a wiring 1002 is electrically connected to a drain of the transistor 300. A wiring 1003 is electrically connected to one of the source and the drain of the transistor 200, a wiring 1004 is electrically connected to a top gate of the transistor 200, and a wiring 1006 is electrically connected to a bottom gate of the transistor 200. A gate of the transistor 300 and the other of the source and the drain of the transistor 200 are electrically connected to one electrode of the capacitor 100, and a wiring 1005 is electrically connected to the other electrode of the capacitor 100.

The memory device illustrated in FIG. 18 and FIG. 19 has a feature that a potential of the gate of the transistor 300 can be retained and thus enables writing, retaining, and reading of data as follows.

Writing and retaining of data are described. First, the potential of the wiring 1004 is set to a potential at which the transistor 200 is brought into a conduction state, so that the transistor 200 is brought into a conduction state. Accordingly, the potential of the wiring 1003 is supplied to a node SN where the gate of the transistor 300 and one electrode of the capacitor 100 are electrically connected to each other. That is, a predetermined charge is supplied to the gate of the transistor 300 (writing). Here, one of two kinds of charges providing different potential levels (hereinafter referred to as a Low-level charge and a High-level charge) is supplied. After that, the potential of the wiring 1004 is set to a potential at which the transistor 200 is brought into a non-conduction state, so that the transistor 200 is brought into a non-conduction state. Thus, the charge is retained in the node SN (retaining).

In the case where the off-state current of the transistor 200 is low, the charge in the node SN is retained for a long time.

Next, reading of data is described. An appropriate potential (reading potential) is supplied to the wiring 1005 while a predetermined potential (constant potential) is supplied to the wiring 1001, whereby the wiring 1002 has a potential corresponding to the amount of charge retained in the node SN. This is because when the transistor 300 is of an n-channel type, an apparent threshold voltage V_{th_H} at the time when the High-level charge is supplied to the gate of the transistor 300 is lower than an apparent threshold voltage V_{th_L} at the time when the Low-level charge is supplied to the gate of the transistor 300. Here, an apparent threshold voltage refers to the potential of the wiring 1005 which is needed to bring the transistor 300 into a “conduction state”. Thus, the potential of the wiring 1005 is set to a potential V₀ which is between V_{th_H} and V_{th_L}, whereby the charge supplied to the node SN can be determined. For example, in the case where the High-level charge is supplied to the node SN in writing and the potential of the wiring 1005 is V₀ (>V_{th_H}), the transistor 300 is brought into a “conduction state”. Meanwhile, in the case where the Low-level charge is supplied to the node SN, the transistor 300 remains in a “non-conduction state” even when the potential of the wiring 1005 is V₀ (<V_{th_L}). Thus, the data retained in the node SN can be read by determining the potential of the wiring 1002.

### <Structure of Memory Device>

The memory device of one embodiment of the present invention includes the transistor 300, the transistor 200, and the capacitor 100 as illustrated in FIG. 18. The transistor 200 is provided above the transistor 300, and the capacitor 100 is provided above the transistor 300 and the transistor 200.

The transistor 300 is provided on a substrate 311 and includes a conductor 316, an insulator 315, a semiconductor region 313 that is a part of the substrate 311, and a low-resistance region 314a and a low-resistance region 314b functioning as a source region and a drain region.

As illustrated in FIG. 18, in the transistor 300, a top surface and a side surface in the channel width direction of the semiconductor region 313 are covered with the conductor 316 with the insulator 315 therebetween. When the transistor 300 is such a Fin-type transistor, the effective channel width is increased, whereby the on-state characteristics of the transistor 300 can be improved. In addition, since contribution of an electric field of a gate electrode can be increased, the off-state characteristics of the transistor 300 can be improved.

The transistor 300 is either a p-channel transistor or an n-channel transistor.

It is preferable that a region of the semiconductor region 313 where a channel is formed, a region in the vicinity thereof, the low-resistance region 314a and the low-resistance region 314b functioning as the source region or the drain region, and the like contain a semiconductor such as a silicon-based semiconductor, further preferably single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is adjusted by applying stress to the crystal lattice and thereby changing the lattice spacing is used. Alternatively, the transistor 300 may be an HEMT (High Electron Mobility Transistor) with GaAs and GaAlAs, or the like.

The low-resistance region 314a and the low-resistance region 314b contain an element which imparts n-type conductivity, such as arsenic or phosphorus, or an element which imparts p-type conductivity, such as boron, in addition to the semiconductor material used for the semiconductor region 313.

The conductor 316 functioning as a gate electrode can be formed using a semiconductor material such as silicon containing the element which imparts n-type conductivity, such as arsenic or phosphorus, or the element which imparts p-type conductivity, such as boron, or using a conductive material such as a metal material, an alloy material, or a metal oxide material.

Note that the work function depends on a material of the conductor; thus, the threshold voltage can be adjusted by changing the material of the conductor. Specifically, it is preferable to use a material such as titanium nitride or tantalum nitride for the conductor. Moreover, in order to ensure both conductivity and embeddability, it is preferable to use a stacked layer of metal materials such as tungsten and aluminum for the conductor, and it is particularly preferable to use tungsten in terms of heat resistance.

Note that the transistor 300 illustrated in FIG. 18 is only an example and the structure is not limited thereto; a transistor appropriate for a circuit configuration or a driving method can be used.

An insulator 320, an insulator 322, an insulator 324, and an insulator 326 are stacked sequentially to cover the transistor 300.

The insulator 320, the insulator 322, the insulator 324, and the insulator 326 can be formed using, for example, silicon oxide, silicon oxynitride, silicon nitride oxide, silicon nitride, aluminum oxide, aluminum oxynitride, aluminum nitride oxide, or aluminum nitride.

The insulator 322 may have a function of a planarization film for eliminating a level difference caused by the transistor 300 or the like underlying the insulator 322. For example, a top surface of the insulator 322 may be planarized by planarization treatment using a chemical mechanical polishing (CMP) method or the like to improve planarity.

The insulator 324 is preferably formed using a film having a barrier property that prevents hydrogen or impurities from the substrate 311, the transistor 300, or the like from diffusing to a region where the transistor 200 is provided.

For the film having a barrier property against hydrogen, silicon nitride formed by a CVD method can be used, for example. The diffusion of hydrogen into a semiconductor element including an oxide semiconductor, such as the transistor 200, degrades the characteristics of the semiconductor element in some cases. Therefore, a film that inhibits hydrogen diffusion is preferably provided between the transistor 200 and the transistor 300. The film that inhibits hydrogen diffusion is specifically a film from which a small amount of hydrogen is released.

The amount of released hydrogen can be measured by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm², in the TDS analysis in a range of 50° C. to 500° C., for example.

Note that the permittivity of the insulator 326 is preferably lower than that of the insulator 324. For example, the relative permittivity of the insulator 324 is preferably lower than 4, further preferably lower than 3. The relative permittivity of the insulator 326 is, for example, preferably 0.7 or less times the relative permittivity of the insulator 324, further preferably 0.6 or less times the relative permittivity of the insulator 324. When a material with a low permittivity is used for an interlayer film, the parasitic capacitance generated between wirings can be reduced.

A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 each have a function of a plug or a wiring. In addition, a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases, and part of the conductor functions as a plug in other cases.

As a material of each of the plugs and wirings (e.g., the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 18, an insulator 350, an insulator 352, and an insulator 354 are stacked sequentially. Furthermore, a conductor 356 is formed in the insulator 350, the insulator 352, and the insulator 354. The conductor 356 functions as a plug or a wiring. Note that the conductor 356 can be provided using a material similar to those of the conductor 328 and the conductor 330.

Note that the insulator 350 is preferably formed using an insulator having a barrier property against hydrogen, as with the insulator 324, for example. Furthermore, the conductor 356 preferably contains a conductor having a barrier property against hydrogen. In particular, the conductor having a barrier property against hydrogen is formed in an opening portion of the insulator 350 having a barrier property against hydrogen. In such a structure, the transistor 300 and the transistor 200 can be separated by a barrier layer, so that the diffusion of hydrogen from the transistor 300 to the transistor 200 can be inhibited.

Note that as the conductor having a barrier property against hydrogen, tantalum nitride is preferably used, for example. The use of a stack including tantalum nitride and tungsten having high conductivity can inhibit the diffusion of hydrogen from the transistor 300 while the conductivity of a wiring is ensured. In that case, a structure is preferable in which the tantalum nitride layer having a barrier property against hydrogen is in contact with the insulator 350 having a barrier property against hydrogen.

A wiring layer may be provided over the insulator 350 and the conductor 356. For example, in FIG. 18, an insulator 360, an insulator 362, and an insulator 364 are stacked sequentially. Furthermore, a conductor 366 is formed in the insulator 360, the insulator 362, and the insulator 364. The conductor 366 functions as a plug or a wiring. Note that the conductor 366 can be provided using a material similar to those of the conductor 328 and the conductor 330.

Note that the insulator 360 is preferably formed using an insulator having a barrier property against hydrogen, as with the insulator 324, for example. Furthermore, the conductor 366 preferably contains a conductor having a barrier property against hydrogen. In particular, the conductor having a barrier property against hydrogen is formed in an opening portion of the insulator 360 having a barrier property against hydrogen. In such a structure, the transistor 300 and the transistor 200 can be separated by a barrier layer, so that the diffusion of hydrogen from the transistor 300 to the transistor 200 can be inhibited.

A plurality of wiring layers may be provided over the insulator 364 and the conductor 366. For example, an insulator 370 and an insulator 372 are stacked sequentially in FIG. 18. Furthermore, a conductor 376 is formed in the insulator 370 and the insulator 372. An insulator 382 and an insulator 384 are stacked sequentially. Furthermore, a conductor 386 is formed in the insulator 382 and the insulator 384. The conductor 376 and the conductor 386 have a function of a plug or a wiring. A plurality of wiring layers may be provided between the insulator 372 and the insulator 382 in accordance with design as appropriate.

Although the wiring layer including the conductor 356, the wiring layer including the conductor 366, the wiring layer including the conductor 376, and the wiring layer including the conductor 386 are described above, the memory device of this embodiment is not limited thereto. Three or less wiring layers which are similar to the wiring layer including the conductor 356 may be provided, or five or more wiring layers which are similar to the wiring layer including the conductor 356 may be provided.

The insulator 210, the insulator 212, the insulator 214, and the insulator 216 are stacked sequentially over the insulator 384. A substance having a barrier property against oxygen or hydrogen is preferably used for one of the insulator 210, the insulator 212, the insulator 214, and the insulator 216.

For example, the insulator 210 and the insulator 214 are preferably formed using a film having a barrier property that prevents hydrogen or impurities from diffusing from the substrate 311, a region where the transistor 300 is provided, or the like to a region where the transistor 200 is provided. Therefore, a material similar to that of the insulator 324 can be used.

For the film having a barrier property against hydrogen, silicon nitride formed by a CVD method can be used, for example. The diffusion of hydrogen into a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which a small amount of hydrogen is released.

For the film having a barrier property against hydrogen used as the insulator 210 and the insulator 214, for example, a metal oxide such as aluminum oxide, hafnium oxide, or tantalum oxide is preferably used.

In particular, aluminum oxide has an excellent blocking effect that inhibits the passage of both oxygen and impurities such as hydrogen and moisture which are factors of a change in electrical characteristics of the transistor. Accordingly, the use of aluminum oxide can prevent the entry of impurities such as hydrogen and moisture into the transistor 200 in and after a manufacturing process of the transistor. In addition, release of oxygen from the oxide included in the transistor 200 can be prevented. Therefore, aluminum oxide is suitably used for a protective film of the transistor 200.

The insulator 212 and the insulator 216 can be formed using a material similar to that of the insulator 320, for example. In the case where a material with a relatively low permittivity is used for an interlayer film, the parasitic capacitance generated between wirings can be reduced. A silicon oxide film, a silicon oxynitride film, or the like can be used as the insulator 212 and the insulator 216, for example.

A conductor 218, a conductor included in the transistor 200, and the like are embedded in the insulator 210, the insulator 212, the insulator 214, and the insulator 216. Note that the conductor 218 functions as a plug or a wiring that is electrically connected to the capacitor 100 or the transistor 300. The conductor 218 can be provided using a material similar to those of the conductor 328 and the conductor 330.

In particular, the conductor 218 in a region in contact with the insulator 210 and the insulator 214 is preferably a conductor having a barrier property against oxygen, hydrogen, and water. In such a structure, the transistor 300 and the transistor 200 can be separated by a layer having a barrier property against oxygen, hydrogen, and water; thus, the diffusion of hydrogen from the transistor 300 to the transistor 200 can be prevented.

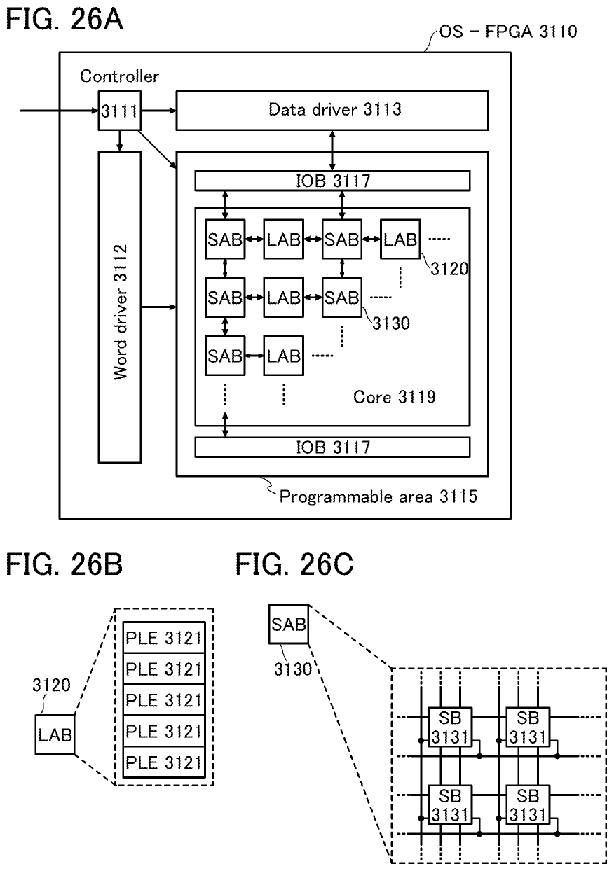

The transistor 200 is provided over the insulator 216. Note that the structure of the transistor included in the semiconductor device described in the above embodiment can be used as the structure of the transistor 200. Note that the transistor 200 illustrated in FIG. 26 is only an example and the structure is not limited thereto; a transistor appropriate for a circuit configuration or a driving method is used.

The insulator 280 is provided over the transistor 200.

The insulator 282 is provided over the insulator 280. A substance having a barrier property against oxygen or hydrogen is preferably used for the insulator 282. Thus, the insulator 282 can be formed using a material similar to that of the insulator 214. For the insulator 282, a metal oxide such as aluminum oxide, hafnium oxide, or tantalum oxide is preferably used, for example.

In particular, aluminum oxide has an excellent blocking effect that inhibits the passage of both oxygen and impurities such as hydrogen and moisture which are factors of a change in electrical characteristics of the transistor. Accordingly, the use of aluminum oxide can prevent the entry of impurities such as hydrogen and moisture into the transistor 200 in and after a manufacturing process of the transistor. In addition, release of oxygen from the oxide included in the transistor 200 can be prevented. Therefore, aluminum oxide is suitably used for a protective film of the transistor 200.

The insulator 283 is provided over the insulator 282. The insulator 283 can be formed using a material similar to that of the insulator 320. In the case where a material with a relatively low permittivity is used for an interlayer film, the parasitic capacitance generated between wirings can be reduced. For example, a silicon oxide film, a silicon oxynitride film, or the like can be used as the insulator 286.

A conductor 246, a conductor 248, and the like are embedded in the insulator 220, the insulator 222, the insulator 280, the insulator 282, and the insulator 283.

The conductor 246 and the conductor 248 function as plugs or wirings that are electrically connected to the capacitor 100, the transistor 200, or the transistor 300. The conductor 246 and the conductor 248 can be provided using a material similar to those of the conductor 328 and the conductor 330.

In addition, the capacitor 100 is provided above the transistor 200. The capacitor 100 includes a conductor 110, the conductor 120, and an insulator 130.

A conductor 112 may be provided over the conductor 246 and the conductor 248. The conductor 112 functions as a plug or a wiring that is electrically connected to the capacitor 100, the transistor 200, or the transistor 300. The conductor 110 functions as the electrode of the capacitor 100. The conductor 112 and the conductor 110 can be formed at the same time.

The conductor 112 and the conductor 110 can be formed using a metal film containing an element selected from molybdenum, titanium, tantalum, tungsten, aluminum, copper, chromium, neodymium, and scandium; a metal nitride film containing any of the above elements as its component (a tantalum nitride film, a titanium nitride film, a molybdenum nitride film, or a tungsten nitride film); or the like. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

The conductor 112 and the conductor 110 each have a single-layer structure in FIG. 18; however, the structure is not limited thereto, and a stacked-layer structure of two or more layers may be used. For example, between a conductor having a barrier property and a conductor having high conductivity, a conductor which is highly adhesive to the conductor having a barrier property and the conductor having high conductivity may be formed.

As a dielectric of the capacitor 100, the insulator 130 is provided over the conductor 112 and the conductor 110. The insulator 130 can be provided to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

A material with high dielectric strength, such as silicon oxynitride, is preferably used for the insulator 130, for example. In the capacitor 100 having such a structure, the dielectric strength can be increased and the electrostatic breakdown of the capacitor 100 can be prevented because of the insulator 130.

Over the insulator 130, the conductor 120 is provided so as to overlap with the conductor 110. Note that the conductor 120 can be formed using a conductive material such as a metal material, an alloy material, or a metal oxide material. It is preferable to use a high-melting-point material which has both heat resistance and conductivity, such as tungsten or molybdenum, and it is particularly preferable to use tungsten. In the case where the conductor 120 is formed concurrently with another component such as a conductor, Cu (copper), Al (aluminum), or the like which is a low-resistance metal material can be used.

An insulator 150 is provided over the conductor 120 and the insulator 130. The insulator 150 can be provided using a material similar to that of the insulator 320. The insulator 150 may function as a planarization film that covers an uneven shape thereunder.

With the use of the structure, a change in electrical characteristics can be prevented and reliability can be improved in a semiconductor device using a transistor including an oxide semiconductor. Alternatively, a transistor including an oxide semiconductor having a high on-state current can be provided. Alternatively, a transistor including an oxide semiconductor having a low off-state current can be provided. Alternatively, a semiconductor device with reduced power consumption can be provided.

### Embodiment 4

In this embodiment, an inverter circuit including the semiconductor device described in the above embodiment is described. Note that in this specification, a high power supply voltage and a low power supply voltage are sometimes referred to as an H level (or VDD) and an L level (or GND), respectively.

### <Structure Example of Inverter Circuit>

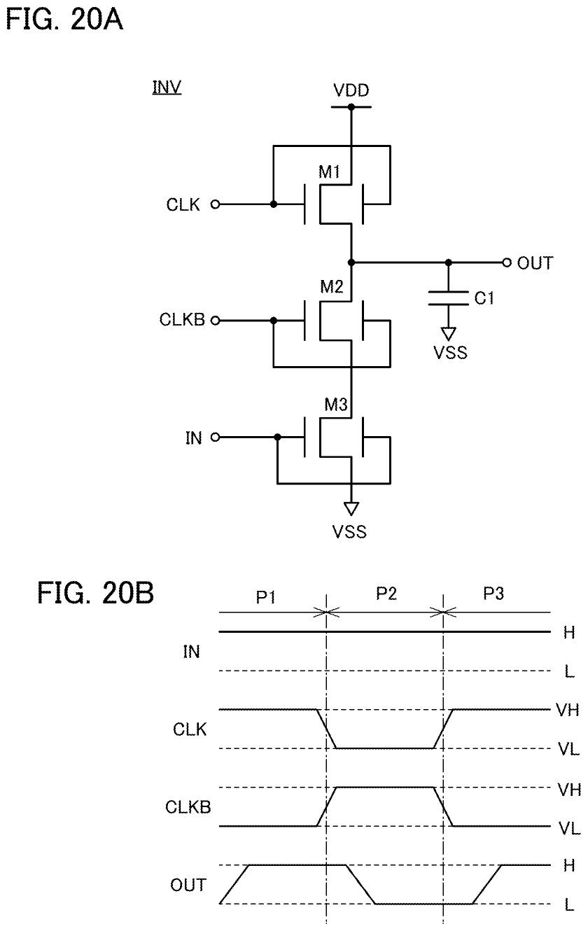

A circuit INV illustrated in FIG. 20(A) includes a capacitor C1, and a transistor M1, a transistor M2, and a transistor M3 that are connected in series. The circuit INV functions as an inverter circuit.

The transistors M1 to M3 are n-channel transistors. Since the circuit INV includes only n-channel transistors, the manufacturing cost can be reduced as compared to that of an inverter circuit including CMOS transistors.

It is preferable to use, as the transistors M1 to M3, the transistor 200 described in the above embodiment.

The transistor M1 includes a first gate and a second gate that are electrically connected to each other. The first gate and the second gate overlap with each other with a semiconductor layer positioned therebetween. The same applies to the transistors M2 and M3. Note that the first gate and the second gate may be referred to as a front gate and a back gate, respectively.

The circuit INV includes a terminal IN, a terminal OUT, a terminal CLK, and a terminal CLKB. The terminal IN functions as an input terminal, and the terminal OUT functions as an output terminal. A clock signal is input to the terminal CLK, and an inverted signal of the clock signal input to the terminal CLK is input to the terminal CLKB.

The circuit INV is supplied with VDD and VSS as power supply voltages. VDD, which is a high power supply voltage, is input to a drain of the transistor M1. VSS, which is a low power supply voltage, is input to a source of the transistor M3.

In the transistor M1, the front gate and the back gate are electrically connected to the terminal CLK, and a source is electrically connected to a drain of the transistor M2.

In the transistor M2, the front gate and the back gate are electrically connected to the terminal CLKB, and a source is electrically connected to a drain of the transistor M3.

In the transistor M3, the front gate and the back gate are electrically connected to the terminal IN.

A first terminal of the capacitor C1 is electrically connected to the source of the transistor M1. VSS is input to a second terminal of the capacitor C1.

The terminal OUT is electrically connected to the source of the transistor M1, the drain of the transistor M2, and the first terminal of the capacitor C1.

Note that the capacitor C1 may be replaced with parasitic capacitance of a wiring or gate capacitance of a transistor. In that case, the area occupied by the semiconductor device can be reduced.

Next, the operation of the circuit INV is described.

FIG. 20(B) is a timing chart for explaining the operation of the circuit INV. Changes in potentials of the terminals IN, CLK, CLKB, and OUT are shown. In FIG. 20(B), a period is classified into three periods P1, P2, and P3.

The H level is supplied to the terminal IN during the periods P1 to P3. That is, the transistor M3 is on during the periods P1 to P3.

In the period P1, a potential VH is input to the terminal CLK and a potential VL is input to the terminal CLKB. The transistor M1 is turned on and the transistor M2 is turned off. At this time, VDD is supplied to the capacitor C1 and the capacitor C1 starts to be charged (precharged).

Note that VH is preferably higher than or equal to the total voltage of VDD and the threshold voltage (Vₜₕ) of the transistor M1 (VDD+Vₜₕ). Thus, VDD can be accurately transmitted to the terminal OUT. VL may be a low power supply voltage (or GND). Note that VH and VL are sometimes referred to as a high potential and a low potential, respectively.

In the period P2, VL is input to the terminal CLK and VH is input to the terminal CLKB. The transistor M1 is turned off and the transistor M2 is turned on. At this time, the transistor M3 is on; thus, electrical continuity is established between the first terminal of the capacitor C1 and the source of the transistor M3, so that the capacitor C1 starts to be discharged. Finally, the terminal OUT outputs an L level. That is, the terminal OUT outputs an inverted signal of the signal input to the terminal IN.

In the period P3, VH is input to the terminal CLK and VL is input to the terminal CLKB. The transistor M1 is turned on and the transistor M2 is turned off. As in the period P1, the capacitor C1 starts to be precharged.

In the case where an input of the terminal IN is set to an L level during the periods P1 to P3, the terminal OUT outputs an H level in the period P2. That is, the terminal OUT outputs an inverted signal of the signal input to the terminal IN.

From the above, it is found that the circuit INV performs precharge of the capacitor C1 when the terminal CLK is at VH and functions as an inverter circuit when the terminal CLK is at VL.

In addition, it is found that the circuit INV functions as a dynamic logic circuit that operates by repeating charge and discharge of the capacitor C1. The transistor M1 functions as a precharge transistor for charging the capacitor C1, and the transistor M2 functions as a discharge transistor for discharging charges accumulated in the capacitor C1.

A transistor with a low off-state current is preferably used as each of the transistors M1 to M3. Examples of the transistor with a low off-state current include a transistor using a metal oxide or an oxide semiconductor for a channel formation region (hereinafter also referred to as an OS transistor). Note that a low off-state current means that the off-state current of a transistor is preferably lower than or equal to 10⁻¹⁸ A/μm, further preferably lower than or equal to 10⁻²¹ A/μm, still further preferably lower than or equal to 10⁻²⁴ A/μm.

With the use of an OS transistor as each of the transistors M1 to M3, a shoot-through current of the circuit INV can be reduced. As a result, the power consumption of the circuit INV can be reduced.

With the use of an OS transistor as each of the transistors M1 to M3, charges precharged in the capacitor C1 can avoid being lost due to a leakage current. As a result, the circuit INV can transmit data more accurately.

The front gate and the back gate of the transistor M1 are electrically connected to each other, whereby the gate voltage can be applied to the semiconductor layer from the front gate and the back gate at the same time and thus the on-state current can be increased. The same applies to the transistor M2 and the transistor M3. Consequently, the circuit INV can achieve an inverter circuit with a high operation frequency.

In the circuit INV, the terminal IN may be electrically connected to the front gate and the back gate of the transistor M2 and the terminal CLKB may be electrically connected to the front gate and the back gate of the transistor M3.

The back gates of the transistors M1 to M3 may each be supplied with a potential different from that supplied to their top gates. For example, a common fixed potential may be supplied to the back gates of the transistors M1 to M3. Thus, the threshold voltages of the transistors M1 to M3 in the circuit INV can be controlled.

In addition, all of the back gates of the transistors M1 to M3 in the circuit INV may be omitted depending on the case. In that case, the manufacturing process of the circuit INV can be simplified.

As described above, the circuit INV can provide an inverter circuit that has low power consumption and is configured with transistors having the same polarity type. In addition, an inverter circuit that has a high operation frequency and is configured with transistors having the same polarity type can be provided.

The structure described in this embodiment can be used in appropriate combination with the structures described in the other embodiments.

### Embodiment 5

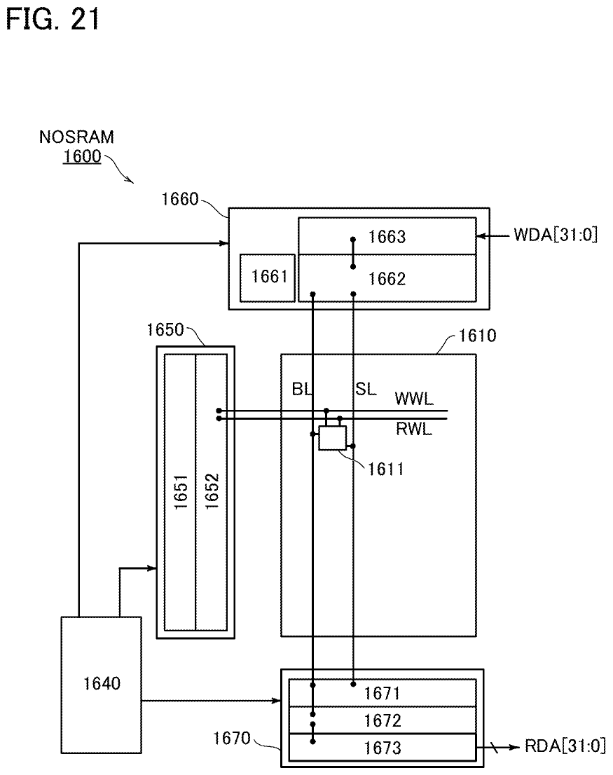

In this embodiment, with reference to FIG. 21 to FIG. 23, a NOSRAM will be described as an example of a memory device, which is one embodiment of the present invention, including a transistor in which an oxide is used for a semiconductor (hereinafter referred to as an OS transistor) and a capacitor. A NOSRAM (registered trademark) is an abbreviation of “Nonvolatile Oxide Semiconductor RAM”, which indicates a RAM including a gain cell (2T or 3T) memory cell. Note that hereinafter, a memory device including an OS transistor, such as a NOSRAM, is referred to as an OS memory in some cases.

A memory device in which OS transistors are used in memory cells (hereinafter referred to as an “OS memory”) is used in a NOSRAM. The OS memory is a memory including at least a capacitor and an OS transistor that controls charge and discharge of the capacitor. Since the OS transistor is a transistor with an extremely low off-state current, the OS memory has excellent retention characteristics and thus can function as a nonvolatile memory.

### <<NOSRAM>>

FIG. 21 illustrates a configuration example of a NOSRAM. A NOSRAM 1600 illustrated in FIG. 21 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL and RWL, bit lines BL, and source lines SL. The word lines WWL are write word lines and the word lines RWL are read word lines. In the NOSRAM 1600, one memory cell 1611 stores 3-bit (8-level) data.

The controller 1640 controls the NOSRAM 1600 as a whole, and writes data WDA[31:0] and reads out data RDA[31:0]. The controller 1640 processes command signals from the outside (for example, a chip enable signal and a write enable signal) to generate control signals of the row driver 1650, the column driver 1660, and the output driver 1670.

The row driver 1650 has a function of selecting a row to be accessed. The row driver 1650 includes a row decoder 1651 and a word line driver 1652.

The column driver 1660 drives the source lines SL and the bit lines BL. The column driver 1660 includes a column decoder 1661, a write driver 1662, and a DAC (digital-analog converter circuit) 1663.

The DAC 1663 converts 3-bit digital data into an analog voltage. The DAC 1663 converts 32-bit data WDA[31:0] into an analog voltage per 3 bits.

The write driver 1662 has a function of precharging the source lines SL, a function of bringing the source lines SL into an electrically floating state, a function of selecting a source line SL, a function of inputting a writing voltage generated in the DAC 1663 to the selected source line SL, a function of precharging the bit lines BL, a function of bringing the bit lines BL into an electrically floating state, and the like.

The output driver 1670 includes a selector 1671, an ADC (analog-digital converter circuit) 1672, and an output buffer 1673. The selector 1671 selects a source line SL to be accessed and transmits the voltage of the selected source line SL to the ADC 1672. The ADC 1672 has a function of converting an analog voltage into 3-bit digital data. The voltage of the source line SL is converted into 3-bit data in the ADC 1672, and the output buffer 1673 retains the data output from the ADC 1672.

Note that the configuration of the row driver 1650, the column driver 1660, and the output driver 1670 described in this embodiment is not limited to the above. The arrangement of the drivers and wirings connected to the drivers may be changed or the functions of the drivers and the wirings connected to the drivers may be changed or added, depending on the configuration, the driving method, or the like of the memory cell array 1610. For example, the bit lines BL may have part of a function of the source lines SL.

Note that although the amount of data retained in each of the memory cells 1611 is 3 bits in the above description, the structure of the memory device described in this embodiment is not limited thereto. The amount of data retained in each of the memory cells 1611 may be 2 bits or less or 4 bits or more. In the case where the amount of data retained in each of the memory cells 1611 is one bit, for example, a structure may be employed in which the DAC 1663 and the ADC 1672 are not provided.

### <Memory Cell>

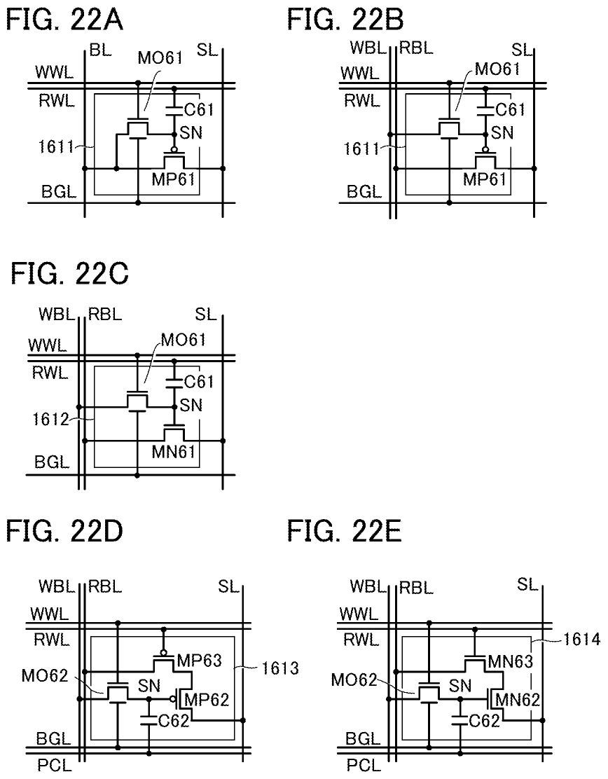

FIG. 22(A) is a circuit diagram showing a configuration example of the memory cell 1611. The memory cell 1611 is a 2T gain cell and the memory cell 1611 is electrically connected to the word lines WWL and RWL, the bit line BL, the source line SL, and a wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for retaining the voltage of the node SN. The node SN is a data storage node and corresponds to a gate of the transistor MP61 here.

The write transistor of the memory cell 1611 is formed using the OS transistor MO61; thus, the NOSRAM 1600 can retain data for a long time.

In the example of FIG. 22(A), write and read bit lines are a common bit line; however, as illustrated in FIG. 22(B), a bit line WBL functioning as a write bit line and a bit line RBL functioning as a read bit line may be provided.

FIG. 22(C) to FIG. 22(E) show other configuration examples of the memory cell. FIG. 22(C) to FIG. 22(E) show examples where the write bit line WBL and the read bit line RBL are provided; however, as in FIG. 22(A), a bit line shared in writing and reading may be provided.

A memory cell 1612 illustrated in FIG. 22(C) is a modification example of the memory cell 1611 where the read transistor is changed into an n-channel transistor (MN61). The transistor MN61 may be an OS transistor or a Si transistor.

In the memory cells 1611 and 1612, the OS transistor MO61 may be an OS transistor with no back gate.

A memory cell 1613 illustrated in FIG. 22(D) is a 3T gain cell and is electrically connected to the word lines WWL and RWL, the bit lines WBL and RBL, the source line SL, the wiring BGL, and a wiring PCL. The memory cell 1613 includes the node SN, an OS transistor MO62, a transistor MP62, a transistor MP63, and a capacitor C62. The OS transistor MO62 is a write transistor. The transistor MP62 is a read transistor and the transistor MP63 is a selection transistor.

A memory cell 1614 illustrated in FIG. 22(E) is a modification example of the memory cell 1613 where the read transistor and the selection transistor are changed into n-channel transistors (MN62 and MN63). The transistors MN62 and MN63 may be OS transistors or Si transistors.

The OS transistors provided in the memory cells 1611 to 1614 may each be a transistor with no back gate or a transistor with a back gate.

What is called a NOR memory device in which the memory cells 1611 or the like are connected in parallel is described above, but the memory device of this embodiment is not limited thereto. For example, what is called a NAND memory device in which memory cells 1615 described below are connected in series may be provided.

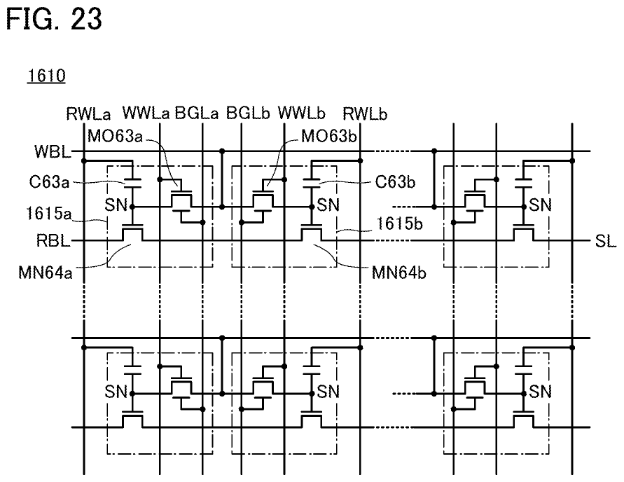

FIG. 23 is a circuit diagram showing a configuration example of the NAND memory cell array 1610. The memory cell array 1610 illustrated in FIG. 23 includes the source line SL, the bit line RBL, the bit line WBL, the word line WWL, the word line RWL, the wiring BGL, and the memory cell 1615. The memory cell 1615 includes the node SN, an OS transistor MO63, a transistor MN64, and a capacitor C63. Here, the transistor MN64 is an n-channel Si transistor, for example. The transistor MN64 is not limited thereto and may be a p-channel Si transistor or an OS transistor.

A memory cell 1615a and a memory cell 1615b, which are illustrated in FIG. 23, are described below as examples. Here, the character “a” or “b” is added to the reference numerals of the wirings and circuit elements connected to the memory cell 1615a or the memory cell 1615b.

In the memory cell 1615a, a gate of a transistor MN64a, one of a source and a drain of an OS transistor MO63a, and one electrode of a capacitor C63a are electrically connected to each other. The bit line WBL and the other of the source and the drain of the OS transistor MO63a are electrically connected to each other. A word line WWLa and a gate of the OS transistor MO63a are electrically connected to each other. A wiring BGLa and a back gate of the OS transistor MO63a are electrically connected to each other. A word line RWLa and the other electrode of the capacitor C63a are electrically connected to each other.

The memory cell 1615b can be provided to be symmetric to the memory cell 1615a with the use of a contact portion with the bit line WBL as a symmetry axis. Therefore, circuit elements included in the memory cell 1615b are connected to wirings as in the memory cell 1615a.

A source of the transistor MN64a of the memory cell 1615a is electrically connected to a drain of a transistor MN64b of the memory cell 1615b. A drain of the transistor MN64a of the memory cell 1615a is electrically connected to the bit line RBL. A source of the transistor MN64b of the memory cell 1615b is electrically connected to the source line SL through the transistors MN64 of the plurality of memory cells 1615. As described here, the plurality of transistors MN64 are connected in series between the bit line RBL and the source line SL in the NAND memory cell array 1610.

In a memory device including the memory cell array 1610 illustrated in FIG. 23, writing operation and reading operation are performed for a plurality of memory cells (hereinafter referred to as a memory cell column) connected to the same word line WWL (or word line RWL). For example, the writing operation can be performed as follows. A potential at which the OS transistor MO63 is brought into an on state is supplied to the word line WWL connected to a memory cell column on which writing is performed so that the OS transistors MO63 in the memory cell column on which writing is performed are brought into an on state. Accordingly, the potential of the bit line WBL is applied to the gates of the transistors MN64 and ones of electrodes of the capacitors C63 in the specified memory cell column, whereby a predetermined charge is supplied to the gates. After that, turning off the OS transistors MO63 in the memory cell column allows the predetermined charge to be retained in the gates. Thus, data can be written to the memory cells 1615 in the specified memory cell column.

For example, the reading operation can be performed as follows. First, a potential at which the transistor MN64 is brought into an on state is supplied to the word lines RWL not connected to a memory cell column on which reading is to be performed regardless of a charge supplied to the gates of the transistors MN64, so that the transistors MN64 in memory cell columns other than the memory cell column on which reading is to be performed are brought into an on state. Then, a potential (reading potential) at which an on state or an off state of the transistor MN64 is selected is supplied to the word line RWL connected to the memory cell column on which reading is to be performed in accordance with a charge of the gates of the transistors MN64. After that, a constant potential is supplied to the source line SL and a reading circuit connected to the bit line RBL is brought into an operation state. Here, the plurality of transistors MN64 between the source line SL and the bit line RBL are in an on state except the transistor MN64 in the memory cell column on which reading is to be performed; therefore, the conductance between the source line SL and the bit line RBL depends on the state (an on state or an off state) of the transistor MN64 in the memory cell column on which reading is to be performed. Since the conductance of the transistor varies depending on the charge of the gate of the transistor MN64 in the memory cell column on which reading is to be performed, the potential of the bit line RBL varies accordingly. By reading the potential of the bit line RBL with the reading circuit, data can be read from the memory cell 1615 in the selected memory cell column.

There is theoretically no limitation on the number of rewriting operations of the NOSRAM 1600 because data is rewritten by charging and discharging the capacitor C61, the capacitor C62, or the capacitor C63; and writing and reading of data can be performed with low energy. Furthermore, since data can be retained for a long time, the refresh rate can be reduced.

In the case where the semiconductor device described in the above embodiment is used for the memory cells 1611, 1612, 1613, 1614, and 1615, the transistors 200 can be used as the OS transistors MO61, MO62, and MO63, the capacitors 100 can be used as the capacitors C61, C62, and C63, and the transistors 300 can be used as the transistors MP61, MP62, MP63, MN61, MN62, MN63, and MN64. Thus, the area occupied by one set consisting of a transistor and a capacitor in the top view can be reduced, so that the memory device of this embodiment can be further highly integrated. As a result, storage capacity per unit area of the memory device of this embodiment can be increased.

The structure described in this embodiment can be used in appropriate combination with the structures described in the other embodiments.

### Embodiment 6

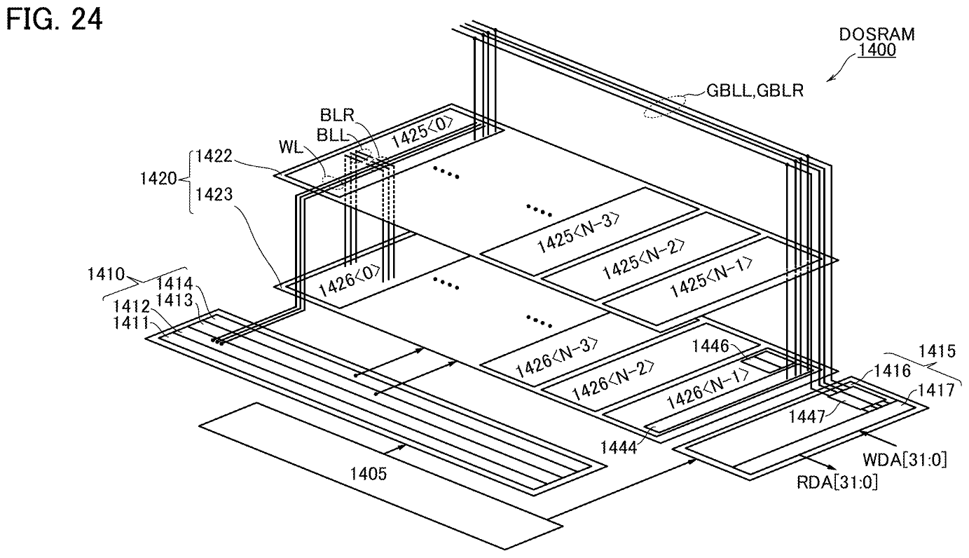

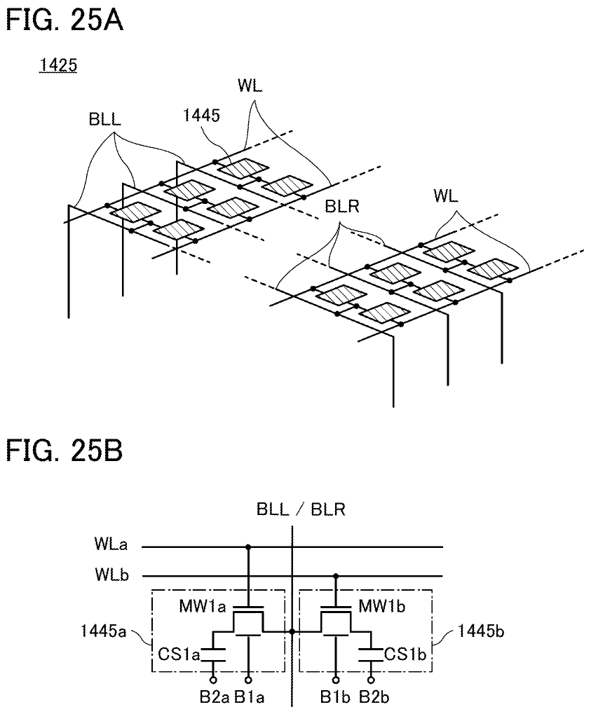

In this embodiment, a DOSRAM will be described as an example of the memory device of one embodiment of the present invention that includes an OS transistor and a capacitor, with reference to FIG. 24 and FIG. 25. A DOSRAM (registered trademark) is an abbreviation of “Dynamic Oxide Semiconductor RAM”, which refers to a RAM including a 1T (transistor) 1C (capacitor) memory cell. As in the NOSRAM, an OS memory is used in the DOSRAM.

### <<DOSRAM 1400>>

FIG. 24 illustrates a configuration example of the DOSRAM. As illustrated in FIG. 24, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1> (N is an integer greater than or equal to 2). FIG. 25(A) illustrates a configuration example of the local memory cell array 1425. The local memory cell array 1425 includes a plurality of memory cells 1445, a plurality of word lines WL, and a plurality of bit lines BLL and BLR. In the example in FIG. 25(A), the local memory cell array 1425 has an open bit-line architecture but may have a folded bit-line architecture.

FIG. 25(B) illustrates a circuit configuration example of a pair of a memory cell 1445a and a memory cell 1445b connected to the same bit line BLL (BLR). The memory cell 1445a includes a transistor MW1a, a capacitor CS1a, and terminals B1a and B2a, and is connected to a word line WLa and the bit line BLL (BLR). The memory cell 1445b includes a transistor MW1b, a capacitor CS1b, and terminals B1b and B2b, and is connected to a word line WLb and the bit line BLL (BLR). Hereinafter, in the case where the description is not limited to the memory cell 1445a or the memory cell 1445b, the memory cell 1445 and its components are described without using the letter “a” or “b”, in some cases.

The transistor MW1a has a function of controlling the charging and discharging of the capacitor CS1a, and the transistor MW1b has a function of controlling the charging and discharging of the capacitor CS1b. A gate of the transistor MW1a is electrically connected to the word line WLa, a first terminal of the transistor MW1a is electrically connected to the bit line BLL (BLR), and a second terminal of the transistor MW is electrically connected to a first terminal of the capacitor CS1a. A gate of the transistor MW1b is electrically connected to the word line WLb, a first terminal of the transistor MW1b is electrically connected to the bit line BLL (BLR), and a second terminal of the transistor MW1b is electrically connected to a first terminal of the capacitor CS1b. In this way, the bit line BLL (BLR) is shared by the first terminal of the transistor MW1a and the first terminal of the transistor MW1b.

The transistor MW1 has a function of controlling the charging and discharging of the capacitor CS1. A second terminal of the capacitor CS1 is electrically connected to the terminal B2. A constant voltage (e.g., low power supply voltage) is input to the terminal B2.

In the case where the semiconductor device described in the above embodiment is used for the memory cells 1445a and 1445b, the transistor 200 can be used as the transistor MW1a or the transistor MW1b, and the capacitor 100 can be used as the capacitor CS1a or the capacitor CS1b. In that case, the area occupied by one set consisting of one transistor and one capacitor in the top view can be reduced; accordingly, the memory device of this embodiment can be highly integrated. As a result, storage capacity per unit area of the memory device of this embodiment can be increased.

The transistor MW1 includes a back gate, and the back gate is electrically connected to the terminal B1. This makes it possible to change the threshold voltage of the transistor MW1 with a voltage of the terminal B1. For example, the voltage of the terminal B1 may be a fixed voltage (e.g., a negative constant voltage); alternatively, the voltage of the terminal B1 may be changed in response to the operation of the DOSRAM 1400.

The back gate of the transistor MW1 may be electrically connected to the gate, the source, or the drain of the transistor MW1. Alternatively, the transistor MW1 does not necessarily include the back gate.

The sense amplifier array 1423 includes N local sense amplifier arrays 1426<0> to 1426<N−1>. The local sense amplifier array 1426 includes one switch array 1444 and a plurality of sense amplifiers 1446. The sense amplifier 1446 is electrically connected to a bit line pair. The sense amplifier 1446 has a function of precharging the bit line pair, a function of amplifying a voltage difference of the bit line pair, and a function of retaining the voltage difference. The switch array 1444 has a function of selecting a bit line pair and electrically connecting the selected bit line pair and a global bit line pair to each other.

Here, two bit lines that are compared simultaneously by the sense amplifier are collectively referred to as the bit line pair. Two global bit lines that are compared simultaneously by the global sense amplifier are collectively referred to as the global bit line pair. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signal from the sense amplifier driver circuit 1414, each of the plurality of local sense amplifier arrays 1426 is driven independently.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference of the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a target column. The local sense amplifier array 1426 amplifies the written data, and then retains the amplified data. In the specified local memory cell array 1425, the word line WL of the target row is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified with an address signal. In the specified local memory cell array 1425, the word line WL of a target row is selected, and data of the memory cell 1445 is written to the bit line. The local sense amplifier array 1426 detects a voltage difference of the bit line pair of each column as data, and retains the data. The switch array 1444 writes the data of a column specified by the address signal to the global bit line pair; the data is chosen from the data retained at the local sense amplifier array 1426. The global sense amplifier array 1416 determines and retains the data of the global bit line pair. The data retained at the global sense amplifier array 1416 is output to the input/output circuit 1417. Thus, the read operation is completed.

The DOSRAM 1400 has no limitation on the number of rewrites in principle and data can be read and written with low energy consumption, because data is rewritten by charging and discharging the capacitor CS1. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is considerably longer than that of a DRAM. This allows less frequent refresh, which can reduce power needed for refresh operations. Thus, the DOSRAM 1400 is suitably used for a memory device that can rewrite a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which allows the storage capacitance of the memory cell 1445 to be reduced. In addition, providing the switch array 1444 in the local sense amplifier array 1426 allows the number of long bit lines to be reduced. For the reasons described above, a load to be driven during access to the DOSRAM 1400 is reduced, enabling a reduction in power consumption.

The structure described in this embodiment can be used in appropriate combination with the structures described in the other embodiments.

### Embodiment 7

In this embodiment, an FPGA (field programmable gate array) is described as an example of a semiconductor device of one embodiment of the present invention in which an OS transistor and a capacitor are used, with reference to FIG. 26 to FIG. 29. In the FPGA of this embodiment, an OS memory is used for a configuration memory and a register. Here, such an FPGA is referred to as an “OS-FPGA”.

### <<OS-FPGA>>

FIG. 26(A) illustrates a configuration example of an OS-FPGA. An OS-FPGA 3110 illustrated in FIG. 26(A) is capable of context switching by a multi-context configuration, fine-grained power gating, and NOFF (normally-off) computing. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 26(B) illustrates an example in which the LAB 3120 includes five PLEs 3121. As illustrated in FIG. 26(C), the SAB 3130 includes a plurality of switch blocks (SBs) 3131 arranged in an array. The LAB 3120 is connected to the LABs 3120 in four directions (on the left, right, top, and bottom sides) through its input terminals and the SABs 3130.

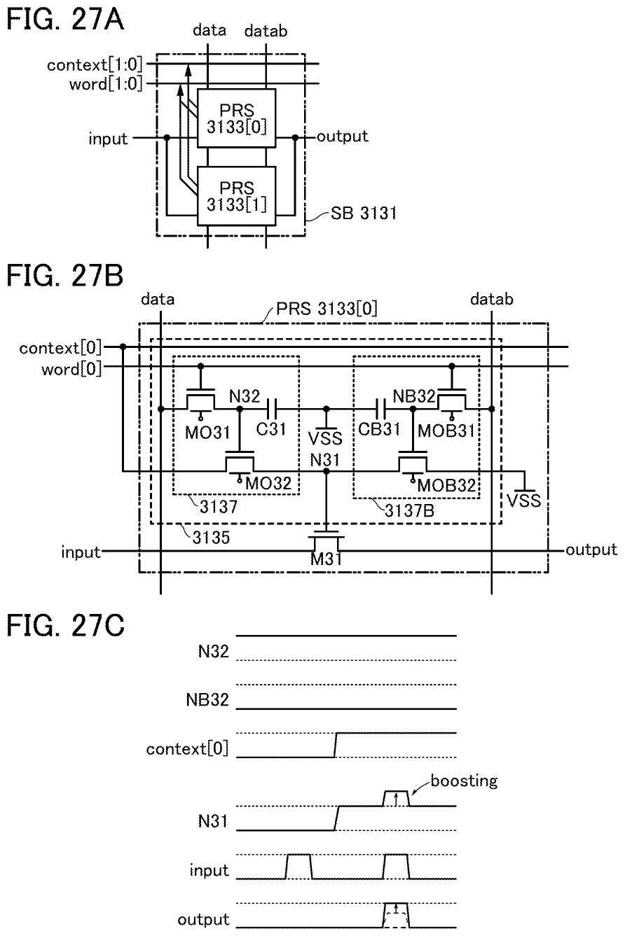

The SB 3131 is described with reference to FIG. 27(A) to FIG. 27(C). To the SB 3131 illustrated in FIG. 27(A), data, datab, and signals context[1:0] and word[1:0] are input. The data and the datab are configuration data, and the logics of the data and the datab have a complementary relationship. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes PRSs (programmable routing switches) 3133[0] and 3133[1]. The PRSs 3133[0] and 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 27(B) illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal that are input. The signals context[0] and word[0] are input to the PRS 3133[0], and the signals context[1] and word[1] are input to the PRS 3133[1]. For example, in the SB 3131, when the signal context[0] is set to “H”, the PRS 3133[0] is activated.

The PRS 3133[0] includes a CM 3135 and a Si transistor M31. The Si transistor M31 is a pass transistor that is controlled by the CM 3135. The CM 3135 includes memory circuits 3137 and 3137B. The memory circuits 3137 and 3137B have the same circuit configuration. The memory circuit 3137 includes a capacitor C31 and OS transistors MO31 and MO32. The memory circuit 3137B includes a capacitor CB31 and OS transistors MOB31 and MOB32.

In the case where the semiconductor device described in the above embodiment is used in the SAB 3130, the transistors 200 can be used as the OS transistors MO31 and MOB31, and the capacitors 100 can be used as the capacitors C31 and CB31. Thus, the area occupied by one set consisting of one transistor and one capacitor in the top view can be reduced, so that the semiconductor device of this embodiment can be highly integrated.

The OS transistors MO31, MO32, MOB31, and MOB32 include back gates, and each of these back gates is electrically connected to a power supply line that supplies a fixed voltage.

A gate of the Si transistor M31 corresponds to a node N31, a gate of the OS transistor MO32 corresponds to a node N32, and a gate of the OS transistor MOB32 corresponds to a node NB32. The nodes N32 and NB32 are each a charge retention node of the CM 3135. The OS transistor MO32 controls the conduction state between the node N31 and a signal line for the signal context[0]. The OS transistor MOB32 controls the conduction state between the node N31 and a low-potential power supply line VSS.

Data retained in the memory circuits 3137 and 3137B have a complementary relationship. Thus, either of the OS transistors MO32 or MOB32 is turned on.

The operation example of the PRS 3133[0] is described with reference to FIG. 27(C). Configuration data has already been written to the PRS 3133[0], and the node N32 is at “H” and the node NB32 is at “L” in the PRS 3133[0].

The PRS 3133[0] is inactive while the signal context[0] is at “L”. During this period, even when an input terminal of the PRS 3133[0] is transferred to “H”, the gate of the Si transistor M31 is kept at “L” and an output terminal of the PRS 3133[0] is also kept at “L”.

The PRS 3133[0] is active while the signal context[0] is at “H”. When the signal context[0] is transferred to “H”, the gate of the Si transistor M31 is transferred to “H” by the configuration data stored in the CM 3135.

When the input terminal is transferred to “H” during a period in which the PRS 3133[0] is active, the gate voltage of the Si transistor M31 is increased by boosting because the OS transistor MO32 of the memory circuit 3137 is a source follower. As a result, the OS transistor MO32 of the memory circuit 3137 loses the driving capability, and the gate of the Si transistor M31 is brought into a floating state.

In the PRS 3133 with a multi-context function, the CM 3135 also has a function of a multiplexer.

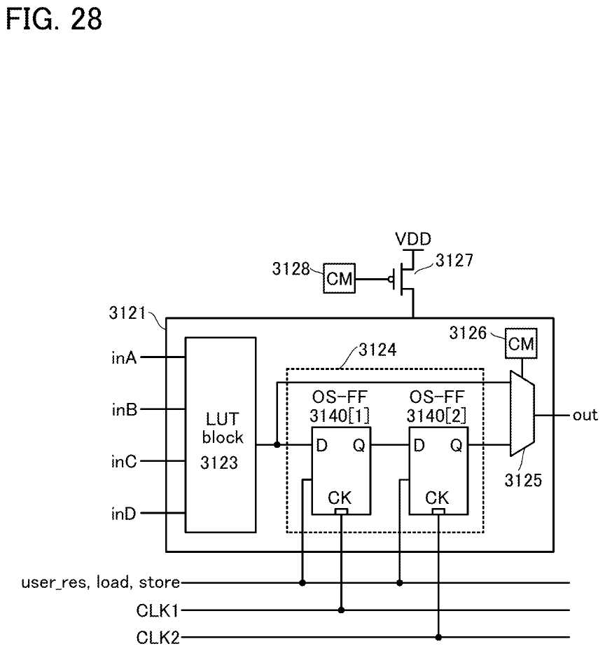

FIG. 28 illustrates a configuration example of the PLE 3121. The PLE 3121 includes an LUT (lookup table) block 3123, a register block 3124, a selector 3125, and a CM 3126. The LUT block 3123 is configured to multiplex an output of a pair of 16-bit CMs therein in accordance with inputs inA to inD. The selector 3125 selects an output of the LUT block 3123 or an output of the register block 3124 in accordance with the configuration stored in the CM 3126.

The PLE 3121 is electrically connected to a power supply line for a voltage VDD through a power switch 3127. Whether the power switch 3127 is turned on or off is determined in accordance with configuration data stored in a CM 3128. Providing the power switch 3127 for each PLE 3121 enables fine-grained power gating. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as [OS-FF]).

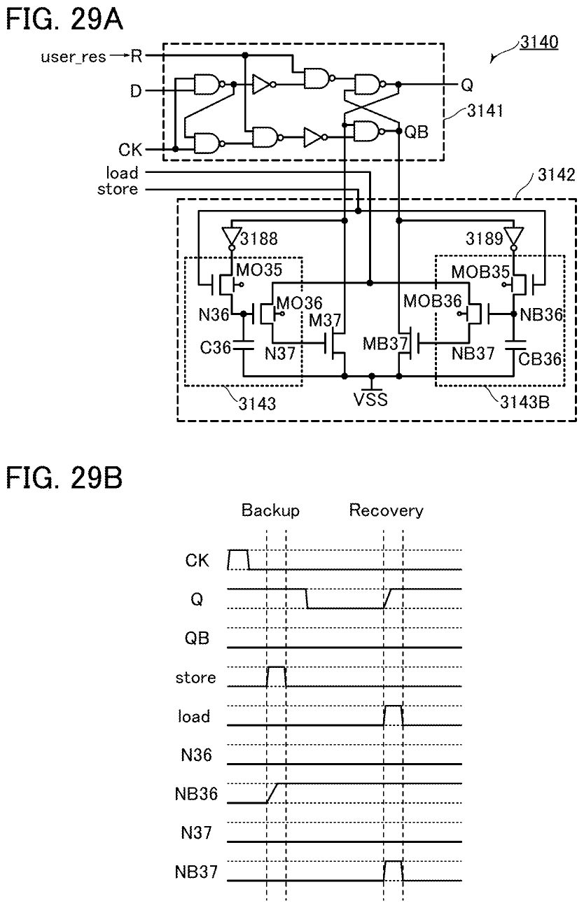

The register block 3124 includes OS-FFs 3140[1] and 3140[2]. Signals user_res, load, and store are input to the OS-FFs 3140[1] and 3140[2]. A clock signal CLK1 is input to the OS-FF 3140[1] and a clock signal CLK2 is input to the OS-FF 3140[2]. FIG. 29(A) illustrates a configuration example of the OS-FF 3140.

The OS-FF 3140 includes an FF 3141 and a shadow register 3142. The FF 3141 includes nodes CK, R, D, Q, and QB. A clock signal is input to the node CK. The signal user_res is input to the node R. The signal user_res is a reset signal. The node D is a data input node, and the node Q is a data output node. The logics of the node Q and the node QB have a complementary relationship.

The shadow register 3142 functions as a backup circuit of the FF 3141. The shadow register 3142 backs up data of the nodes Q and QB in response to the signal store and writes back the backed up data to the nodes Q and QB in response to the signal load.

The shadow register 3142 includes inverter circuits 3188 and 3189, Si transistors M37 and MB37, and memory circuits 3143 and 3143B. The memory circuits 3143 and 3143B each have the same circuit configuration as the memory circuit 3137 of the PRS 3133. The memory circuit 3143 includes a capacitor C36 and OS transistors MO35 and MO36. The memory circuit 3143B includes a capacitor CB36, an OS transistor MOB35, and an OS transistor MOB36. A node N36 and a node NB36 correspond to a gate of the OS transistor MO36 and a gate of the OS transistor MOB36, respectively, and are each a charge retention node. A node N37 and a node NB37 correspond to a gate of the Si transistor M37 and a gate of the Si transistor MB37, respectively.

In the case where the semiconductor device described in the above embodiment is used in the LAB 3120, the transistors 200 can be used as the OS transistors MO35 and MOB35, and the capacitors 100 can be used as the capacitors C36 and CB36. Thus, the area occupied by one set consisting of one transistor and one capacitor in the top view can be reduced, so that the semiconductor device of this embodiment can be highly integrated.

The OS transistors MO35, MO36, MOB35, and MOB36 include back gates, and each of these back gates is electrically connected to a power supply line that supplies a fixed voltage.

An example of an operation method of the OS-FF 3140 is described with reference to FIG. 29(B).

### (Backup)

When the signal store at “H” is input to the OS-FF 3140, the shadow register 3142 backs up data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the nodes Q and QB of the FF 3141 are lost, the shadow register 3142 retains the backed up data even when power supply is stopped.

### (Recovery)

The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 is recovered to a state at the backup operation.

A combination of the fine-grained power gating and backup/recovery operation of the OS-FF 3140 allows power consumption of the OS-FPGA 3110 to be effectively reduced.

As an error that might occur in a memory circuit, a soft error due to the entry of radiation is given. The soft error is a phenomenon in which a malfunction such as inversion of data stored in a memory is caused by electron-hole pair generation when a transistor is irradiated with a rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory using an OS transistor has a high soft-error tolerance. Therefore, the OS-FPGA 3110 with high reliability can be provided when an OS memory is included therein.

The structure described in this embodiment can be used in appropriate combination with the structures described in the other embodiments.

### Embodiment 8

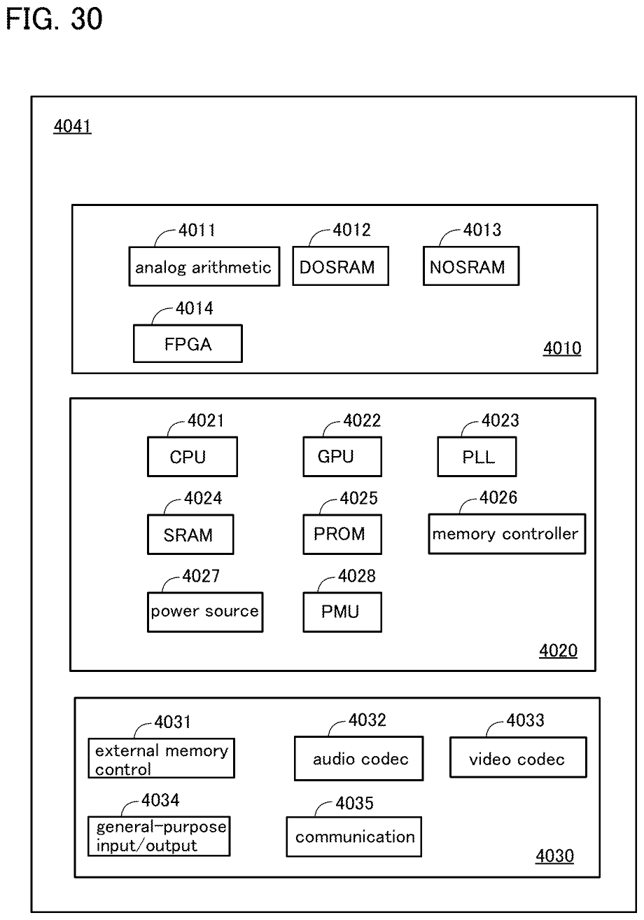

In this embodiment, an AI system in which the semiconductor device of any of the above embodiments is used will be described with reference to FIG. 30.

FIG. 30 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiments can be used as the DOSRAM 4012, the NOSRAM 4013, and the FPGA 4014, respectively.

The control portion 4020 includes a CPU (Central Processing Unit) 4021, a GPU (Graphics Processing Unit) 4022, a PLL (Phase Locked Loop) 4023, an SRAM (Static Random Access Memory) 4024, a PROM (Programmable Read Only Memory) 4025, a memory controller 4026, a power supply circuit 4027, and a PMU (Power Management Unit) 4028.

The input/output portion 4030 includes an external memory control circuit 4031, an audio codec 4032, a video codec 4033, a general-purpose input/output module 4034, and a communication module 4035.

The arithmetic portion 4010 can execute learning or inference by a neural network.

The analog arithmetic circuit 4011 includes an A/D (analog/digital) converter circuit, a D/A (digital/analog) converter circuit, and a product-sum operation circuit.

The analog arithmetic circuit 4011 is preferably formed using an OS transistor. The analog arithmetic circuit 4011 using an OS transistor includes an analog memory and can execute a product-sum operation necessary for the learning or inference with low power consumption.

The DOSRAM 4012 is a DRAM formed using an OS transistor, and the DOSRAM 4012 is a memory that temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data have to be stored piece by piece because of the circuit area limitation and small storage capacity of the SRAM. The DOSRAM 4012 has a larger storage capacity than an SRAM because the memory cells can be highly integrated even in a limited circuit area. Therefore, the DOSRAM 4012 can efficiently store the input data.

The NOSRAM 4013 is a nonvolatile memory using an OS transistor. The NOSRAM 4013 consumes less power in writing data than the other nonvolatile memories such as a flash memory, a ReRAM (Resistive Random Access Memory), and an MRAM (Magnetoresistive Random Access Memory). Furthermore, unlike a flash memory and a ReRAM in which elements deteriorate by data writing, the NOSRAM has no limitation on the number of times of data writing.

Furthermore, the NOSRAM 4013 can store multilevel data of two or more bits as well as one-bit binary data. The multilevel data storage in the NOSRAM 4013 leads to a reduction in the memory cell area per bit.

Furthermore, the NOSRAM 4013 can store analog data as well as digital data. Thus, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, the area of a peripheral circuit for the NOSRAM 4013 can be reduced. In this specification, analog data refers to data having a resolution of three bits (eight levels) or more. The above-described multilevel data is included in the analog data in some cases.

Data and parameters used in the neural network calculation can be once stored in the NOSRAM 4013. The data and parameters may be stored in a memory provided outside the AI system 4041 via the CPU 4021; however, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA using an OS transistor. With the use of the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), or a deep belief network (DBN) described later, with hardware. Establishing the connection of the neural network with hardware enables higher-speed performance.

The FPGA 4014 is an FPGA including an OS transistor. An OS-FPGA can have a smaller memory area than an FPGA including an SRAM. Thus, addition of a context switching function only causes a small increase in area. Moreover, an OS-FPGA can transmit data and parameters at high speed by boosting.

In the AI system 4041, the analog arithmetic circuit 4011, the DOSRAM 4012, the NOSRAM 4013, and the FPGA 4014 can be provided on one die (chip). Thus, the AI system 4041 can execute calculation of the neural network quickly with low power consumption. In addition, the analog arithmetic circuit 4011, the DOSRAM 4012, the NOSRAM 4013, and the FPGA 4014 can be manufactured through the same manufacturing process. Therefore, the AI system 4041 can be manufactured at low cost.

Note that the arithmetic portion 4010 does not necessarily include all of the following: the DOSRAM 4012, the NOSRAM 4013, and the FPGA 4014. One or more of the DOSRAM 4012, the NOSRAM 4013, and the FPGA 4014 are selected and provided in accordance with a problem that is desired to be solved by the AI system 4041.

The AI system 4041 can execute a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for executing at least one of these methods. Furthermore, part or the whole of the program may be stored in the NOSRAM 4013.

Most of the existing programs used as libraries are premised on processing with a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be executed at high speed.

The power supply circuit 4027 generates not only a low power supply potential for a logic circuit but also a potential for an analog operation. The power supply circuit 4027 may use an OS memory. When a reference potential is stored in the OS memory, the power consumption of the power supply circuit 4027 can be reduced.

The PMU 4028 has a function of temporarily stopping the power supply to the AI system 4041.

The CPU 4021 and the GPU 4022 preferably include OS memories as registers. By including the OS memories, the CPU 4021 and the GPU 4022 can retain data (logic values) in the OS memories even when power supply is stopped. As a result, the AI system 4041 can save the power.

The PLL 4023 has a function of generating a clock. The AI system 4041 performs an operation on the basis of the clock generated by the PLL 4023. The PLL 4023 preferably includes an OS memory. By including the OS memory, the PLL 4023 can retain an analog potential with which the clock oscillation cycle is controlled.

The AI system 4041 may store data in an external memory such as a DRAM. For this reason, the AI system 4041 preferably includes the memory controller 4026 functioning as an interface with the external DRAM. Furthermore, the memory controller 4026 is preferably positioned near the CPU 4021 or the GPU 4022. Thus, data transmission can be performed at high speed.

Some or all of the circuits illustrated in the control portion 4020 can be formed on the same die as the arithmetic portion 4010. Thus, the AI system 4041 can execute the neural network calculation at high speed with low power consumption.

Data used for the neural network calculation is stored in an external memory device (such as an HDD (Hard Disk Drive) or an SSD (Solid State Drive)) in many cases. Therefore, the AI system 4041 preferably includes the external memory control circuit 4031 functioning as an interface with the external memory device.

Because the neural network often deals with audio and video for learning and inference, the AI system 4041 includes the audio codec 4032 and the video codec 4033. The audio codec 4032 encodes and decodes audio data, and the video codec 4033 encodes and decodes video data.

The AI system 4041 can perform learning or inference using data obtained from an external sensor. For this reason, the AI system 4041 includes the general-purpose input/output module 4034. The general-purpose input/output module 4034 includes a USB (Universal Serial Bus) or an I2C (Inter-Integrated Circuit), for example.

The AI system 4041 can perform learning or inference using data obtained via the Internet. For this reason, the AI system 4041 preferably includes the communication module 4035.

The analog arithmetic circuit 4011 may use a multi-level flash memory as an analog memory. However, the flash memory has a limitation on the number of rewriting times. In addition, it is extremely difficult to embed the multi-level flash memory (to form the arithmetic circuit and the memory on the same die).

Alternatively, the analog arithmetic circuit 4011 may use a ReRAM as an analog memory. However, the ReRAM has a limitation on the number of rewriting times and also has a problem in storage accuracy. Moreover, the ReRAM is a two-terminal element, and thus has a complicated circuit design for separating data writing and data reading.

Further alternatively, the analog arithmetic circuit 4011 may use an MRAM as an analog memory. However, the MRAM has a problem in storage accuracy because of its low magnetoresistive ratio.

In consideration of the above, the analog arithmetic circuit 4011 preferably uses an OS memory as an analog memory.

The structure described in this embodiment can be used in appropriate combination with the structures described in the other embodiments.

### Embodiment 9

### <Application Example of AI System>

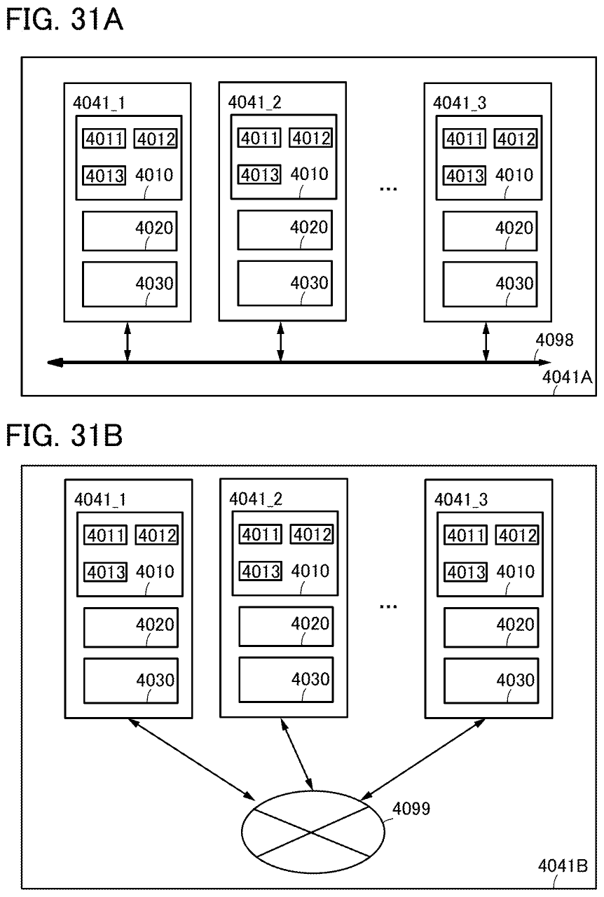

In this embodiment, application examples of the AI system described in the above embodiment will be described with reference to FIG. 31.

FIG. 31(A) illustrates an AI system 4041A in which the AI systems 4041 described with FIG. 30 are arranged in parallel and a signal can be transmitted between the systems via a bus line.

The AI system 4041A illustrated in FIG. 31(A) includes a plurality of AI systems 4041_1 to 4041_n (n is a natural number). The AI system 4041_1 to the AI system 4041_n are connected to each other via a bus line 4098.

FIG. 31(B) illustrates an AI system 4041B in which the AI systems 4041 described with FIG. 30 are arranged in parallel as in FIG. 31(A) and a signal can be transmitted between the systems via a network.

The AI system 4041B illustrated in FIG. 31(B) includes the plurality of AI systems 4041_1 to 4041_n. The AI system 4041_1 to the AI system 4041_n are connected to each other via a network 4099.

A communication module is provided in each of the AI systems 4041_1 to 4041_n; such a configuration enables wireless or wired communication via the network 4099. A communication module can communicate via an antenna. For example, the communication can be performed in such a manner that an electronic device is connected to a computer network such as the Internet that is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA 2000 (Code Division Multiple Access 2000), or W-CDMA (registered trademark), or a communications standard developed by IEEE such as Wi-Fi (registered trademark), Bluetooth (registered trademark), or ZigBee (registered trademark).

With the configuration illustrated in FIG. 31(A) or 31(B), analog signals obtained with external sensors or the like can be processed by different AI systems. For example, analog signals containing biological information such as brain waves, a pulse, blood pressure, and body temperature obtained with a variety of sensors such as a brain wave sensor, a pulse wave sensor, a blood pressure sensor, and a temperature sensor can be processed by different AI systems. Since each of the AI systems performs signal processing or learning, the amount of information processed by each AI system can be reduced. Accordingly, the signal processing or learning can be performed with a smaller amount of arithmetic processing. As a result, recognition accuracy can be increased. With the use of data obtained with each AI system, biological information that irregularly changes should be able to be collectively grasped instantly.

The structure described in this embodiment can be used in appropriate combination with the structures described in the other embodiments.

### Embodiment 10

In this embodiment, an example of an IC in which the AI system described in the above embodiment is incorporated will be described.

In the AI system described in the above embodiment, a digital processing circuit such as a CPU that includes a Si transistor, an analog arithmetic circuit that uses an OS transistor, an OS-FPGA, and an OS memory such as a DOSRAM or a NOSRAM can be integrated into one die.

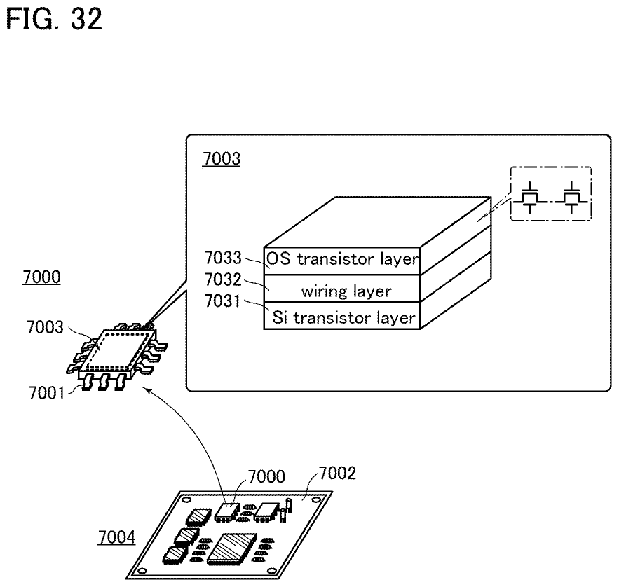

FIG. 32 illustrates the example of the IC in which the AI system is incorporated. An AI system IC 7000 illustrated in FIG. 32 includes a lead 7001 and a circuit portion 7003. The AI system IC 7000 is mounted on a printed circuit board 7002, for example. A plurality of such IC chips are combined and electrically connected to each other on the printed circuit board 7002; thus, a board on which electronic components are mounted (a circuit board 7004) is completed. In the circuit portion 7003, the various circuits described in the above embodiments are provided on one die. The circuit portion 7003 has a stacked-layer structure as described in the above embodiment, and is broadly divided into a Si transistor layer 7031, a wiring layer 7032, and an OS transistor layer 7033. Since the OS transistor layer 7033 can be provided to be stacked over the Si transistor layer 7031, the size of the AI system IC 7000 can be easily reduced.

Although a QFP (Quad Flat Package) is used as a package of the AI system IC 7000 in FIG. 32, the embodiment of the package is not limited thereto.

The digital processing circuit such as a CPU, the analog arithmetic circuit that uses an OS transistor, the OS-FPGA, and the OS memory such as a DOSRAM or a NOSRAM can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly, the AI system can be incorporated in the IC at low cost.

The structure described in this embodiment can be used in appropriate combination with the structures described in the other embodiments.

### Embodiment 11

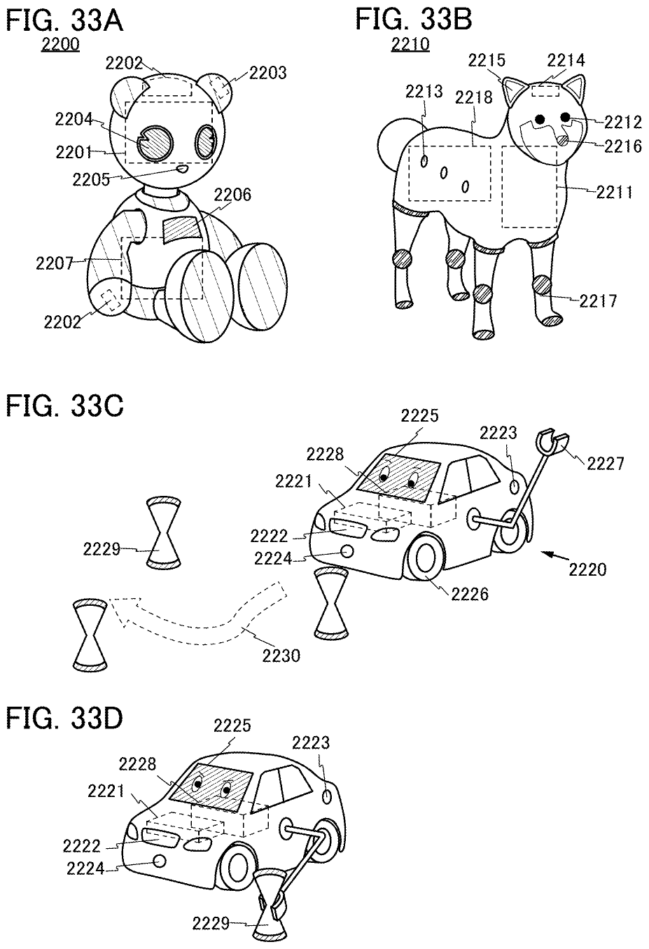

FIG. 33(A) illustrates a communication robot 2200 as an example of an electronic device for which one embodiment of the present invention is used. The communication robot 2200 includes an arithmetic device 2201, contact sensors 2202, a microphone 2203, a camera 2204, a speaker 2205, a display 2206, and a battery 2207.

In the communication robot 2200, one embodiment of the present invention can be used for the arithmetic device 2201. The communication robot 2200 can make conversation with the user by processing a factory-installed language library, sensing results of various sensors, and the like in the arithmetic device 2201. In addition, the communication robot 2200 can recognize the user's face or facial expression.

The display 2206 has a function of displaying various types of information. Information that the user desires can be displayed on the display 2206 in the communication robot 2200. Note that the display 2206 may include a touch panel. The communication robot 2200 may have a telephone function.

FIG. 33(B) illustrates a robotic dog 2210 as an example of the electronic device for which one embodiment of the present invention is used. The robotic dog 2210 includes an arithmetic device 2211, a front camera 2212, a side camera 2213, a contact sensor 2214, a microphone 2215, a speaker 2216, legs 2217, and a battery 2218.

In the robotic dog 2210, one embodiment of the present invention can be used for the arithmetic device 2211. By processing online map information, sensing results of various sensors, and the like in the arithmetic device 2211, the robotic dog 2211 can move the legs 2217 to automatically run and can raise an alert to ensure the user's safety. For example, an alert can be raised through the speaker 2216 or the like when the user walking on a road with the robotic dog 2210 is about to cross the road at the red light.

Furthermore, the robotic dog 2211 can recognize the surroundings using the front camera 2212 and the side camera 2213. For example, the robot 2210 may have a function of raising a loud alert through the speaker 2216 or reporting an emergency in the case where a suspicious person is intruding into a house where the robot 2210 is set. Note that the robot is not limited to the robotic dog 2211 illustrated in FIG. 33(B), and may be a humanoid robot, a robotic cat, a robotic bird, and other types of robots.

FIGS. 33(C) and 33(D) illustrate a robotic car 2220 as an example of the electronic device for which one embodiment of the present invention is used. The robotic car 2220 includes an arithmetic device 2221, a front camera 2222, a side camera 2223, a speaker 2224, a display 2225, tires 2226, an arm 2227, and a battery 2228.

The robotic car 2220 can move with the tires 2226. In the robotic car 2220, one embodiment of the present invention can be used for the arithmetic device 2221. The robotic car 2220 can also move while perceiving the surroundings by recognizing, in the arithmetic device 2221, an image captured by the front camera 2222 and the side camera 2223. For example, as illustrated in FIG. 33(C), the robotic car 2220 can travel around obstacles 2229 (see an arrow 2230) or recognize the user's face to turn toward the user.

In addition, the robotic car 2220 can lift up and transfer the obstacle 2229 with the arm 2227 as illustrated in FIG. 33(C). With the use of this function, the speaker 2224, and the display 2225, the robotic car 2220 can play a game with the user.

The robotic car 2220 may also be connected to a portable information terminal such as a smartphone. For example, the user may operate the portable information terminal to control the robotic car 2220.

### Example 1

In this example, results of TDS measurement performed on an insulator 903 deposited over a substrate after oxygen introduction treatment will be described. Note that in this example, Sample 1A, Sample 1B, Sample 1C, Sample 1D, and Sample 1E were fabricated.

### <Structure and Fabrication Method of Samples>

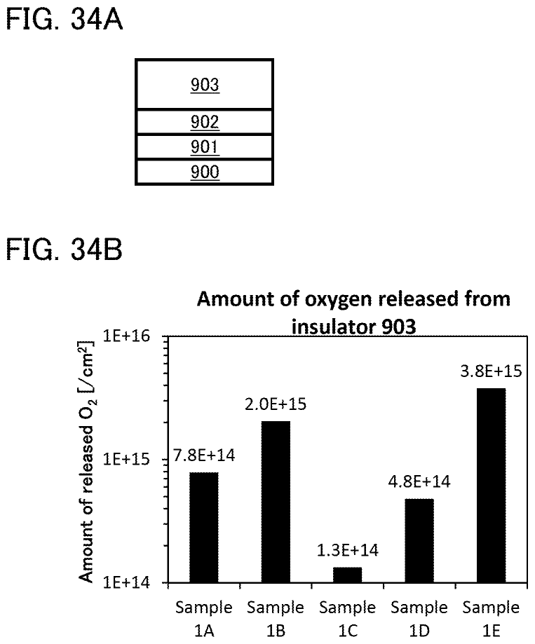

FIG. 34(A) illustrates a stacked-layer structure of each sample. Each of Sample 1A, Sample 1B, Sample 1C, Sample 1D, and Sample 1E includes a substrate 900, an insulator 901 over the substrate 900, an insulator 902 over the insulator 901, and the insulator 903 over the insulator 902. Note that to inhibit diffusion of excess oxygen from the insulator 903 to the insulator 901 and the substrate 900, an insulator having a function of inhibiting diffusion of oxygen was used for the insulator 902. In addition, an oxide in which an excess-oxygen region can be formed was used for the insulator 903.

In each of Sample 1A and Sample 1B, an excess-oxygen region was formed in the insulator 903 by depositing aluminum oxide (AlOₓ) over the insulator 903 by a sputtering method in an atmosphere containing oxygen. In contrast, in each of Sample 1C, Sample 1D, and Sample 1E, an excess-oxygen region was formed in the insulator 903 by implanting oxygen ions by an ion implantation method. After that, aluminum oxide (AlOₓ) was deposited by a sputtering method in an atmosphere without oxygen.

Next, methods for fabricating the samples are described.

First, in each of Sample 1A to Sample 1E, a silicon wafer was prepared as the substrate 900. Then, as the insulator 901, a 100-nm-thick silicon oxide film was deposited over the substrate 900 by a thermal oxidation method.

Next, in each of Sample 1A to Sample 1E, heat treatment was performed at 600° C. in a nitrogen atmosphere for one hour.

Then, as the insulator 902 having a function of inhibiting diffusion of oxygen, 10-nm-thick aluminum oxide was deposited over the insulator 901 by an ALD method. As the deposition conditions, the deposition temperature was 250° C., and TMA (trimethylaluminum: (CH₃)₃Al) and ozone were used for deposition.

Then, a 100-nm-thick silicon oxynitride film was formed as the insulator 903 over the insulator 902 by a plasma CVD method. As deposition gases, silane (SiH₄) at a flow rate of 5 sccm and dinitrogen monoxide (N₂O) at a flow rate of 1000 sccm were used. Furthermore, the deposition was performed under the conditions where the pressure in a reaction chamber was 133.3 Pa, the substrate surface temperature was 325° C., and a high-frequency (RF) power of 45 W (13.56 MHz) was applied.

Here, oxygen ions were implanted directly into the insulator 903 of each of Sample 1C to Sample 1E by an ion implantation method. Conditions of implanting oxygen (¹⁶O) ions were set as follows: the tilt angle was 0°, the twist angle was 0°, and the acceleration voltage was 10 kV.

Note that the dose for Sample 1C was 5.0×10¹⁴ cm⁻². Note that the dose for Sample 1D was 2.0×10¹⁵ cm⁻². Note that the dose for Sample 1E was 2.0×10¹⁶ cm⁻².

Then, in each of Sample 1A to Sample 1C, a 40-nm-thick aluminum oxide film was deposited over the insulator 903 with a sputtering apparatus. Note that the aluminum oxide film was deposited as follows: an aluminum oxide target was used; a mixed atmosphere of an oxygen (02) gas and an argon gas (Ar) was used; the deposition temperature was 250° C.; the pressure was 0.4 Pa; the distance between the target and the substrate was 60 mm; and an electric power (RF) of 2.5 kW was applied. Then, the aluminum oxide film was removed using a mixed solution of a phosphoric acid, a nitric acid, and an acetic acid (also referred to as A1 etchant) at 85° C.

Note that for Sample 1A, the oxygen (O₂) gas flow rate was 2 sccm and the argon (Ar) gas flow rate was 48 sccm. For Sample 1A, the oxygen (O₂) gas flow rate was 25 sccm and the argon (Ar) gas flow rate was 25 sccm. On the other hand, for Sample 1C to Sample 1E, the argon (Ar) gas flow rate was 50 sccm.

Through the above steps, Sample 1A to Sample 1E of this example were fabricated. Note that the conditions of the oxygen introduction treatment on Sample 1A to Sample 1E are shown in the table below.

TABLE 1

| | Condition of ion addition | Condition of deposition |
|---|---|---|
| | treatment on insulator 903 | of AlOₓ over insulator |
| | oxygen dose [/cm²] | 903 O₂ flow rate [%] |
| Sample 1A | — | 4% |
| Sample 1B | — | 50% |
| Sample 1C | 5E+14 [/cm²] | 0% |
| Sample 1D | 2E+15 [/cm2] | 0% |
| Sample 1E | 2E+16 [/cm2] | 0% |

### <TDS Measurement Results of Samples>

The amount of oxygen contained in the insulator 903 of each sample was measured. As for the measurement method, the insulator 903 was subjected to TDS analysis. In the TDS analysis, the amount of a released gas with a mass-to-charge ratio m/z=32, which corresponds to an oxygen molecule, was measured. WA1000S produced by ESCO Ltd. was used as a TDS analysis apparatus, and a temperature rising rate was 30° C./min.

FIG. 34(B) shows the amount of released oxygen molecules (O₂) [/cm²] of each sample. As shown in FIG. 34(B), oxygen release from the insulator 903 was observed in each of Sample 1A to Sample 1E subjected to the oxygen introduction treatment. That is, it was found that by performing the oxygen introduction treatment on the insulator 903, an excess-oxygen region was formed in the insulator 903.

From the results of Sample 1A and Sample 1B, it was found that the amount of excess oxygen contained in the insulator 903 can be adjusted by adjusting the oxygen flow rate at the time of deposition of an oxide by a sputtering method.

From the results of Sample 1C to Sample 1E, it was found that the amount of excess oxygen contained in the insulator 903 can be adjusted by adjusting the dose in the case of providing an excess-oxygen region by an ion implantation method.

The structure described above in this example can be used in appropriate combination with the other example or the other embodiments.

### Example 2

In this example, semiconductor devices each including the transistor 200 which is one embodiment of the present invention illustrated in FIG. 1 were fabricated as Sample 2A to Sample 2E, and tests for the electrical characteristics and reliability of the transistor 200 were carried out.

### <Structure and Fabrication Method of Samples>

The channel length of the transistor 200 was 0.31 μm and the channel width thereof was 0.25 μm. In Sample 2A to Sample 2E, a plurality of transistors 200 were formed through the same process. The transistor density was set to 0.147/μm².

A silicon oxynitride film, a hafnium oxide film, and a silicon oxynitride film were deposited as the insulator 220, the insulator 222, and the insulator 224, respectively. The silicon oxynitride film was deposited by a CVD method to have a thickness of 10 nm. The hafnium oxide film was deposited by an ALD method to have a thickness of 20 nm. The silicon oxynitride film was deposited by a CVD method to have a thickness of 30 nm.

An In—Ga—Zn oxide was deposited as each of the oxide 230a, the oxide 230b, and the oxide 230c by a sputtering method. The oxide 230a was deposited using a target with In:Ga:Zn=1:3:4 [atomic ratio] to have a thickness of 5 nm. The oxide 230b was deposited using a target with In:Ga:Zn=4:2:4.1 [atomic ratio] to have a thickness of 15 nm. The oxide 230c was deposited using a target with In:Ga:Zn=4:2:4.1 [atomic ratio] to have a thickness of 5 nm.

As the insulator 250, a 10-nm-thick silicon oxide film was deposited by a CVD method.

As the insulator 273, a 20-nm-thick aluminum oxide film was deposited.

A 470-nm-thick silicon oxynitride film was deposited as the insulator 280 by a CVD method. Then, CMP treatment was performed to polish the silicon oxynitride film, so that the surface of the silicon oxynitride film was planarized; accordingly, the insulator 280 over the transistor 200 was formed to have a thickness of 100 nm.

As the insulator 282, a 40-nm-thick aluminum oxide film was deposited over the insulator 280 by a sputtering method.

Note that as the insulator 282 over the insulator 280 in each of Sample 2A and Sample 2B, aluminum oxide (AlOₓ) was deposited by a sputtering method in an atmosphere containing oxygen. In contrast, in each of Sample 2C, Sample 2D, and Sample 2E, an excess-oxygen region was formed in the insulator 280 by implanting oxygen ions using an ion implantation method and aluminum oxide (AlOₓ) was deposited as the insulator 282 over the insulator 280 by a sputtering method in an argon atmosphere.

Through the above steps, Sample 2A to Sample 2E were fabricated. Note that the conditions of the oxygen introduction treatment on Sample 2A to Sample 2E are shown in the table below.

TABLE 1

| | Condition of ion addition | Condition for insulator |
|---|---|---|
| | treatment on insulator 280 | 282 over insulator 280 |
| | oxygen dose [/cm²] | O₂ flow rate [%] |
| Sample 2A | — | 4% |
| Sample 2B | — | 50% |
| Sample 2C | 5E+14 [/cm²] | 0% |
| Sample 2D | 2E+15 [/cm2] | 0% |
| Sample 2E | 2E+16 [/cm2] | 0% |

### <Electrical Characteristics of Transistors>

Next, the Id−Vg characteristics were measured as the electrical characteristics of Sample 2A to Sample 2E.

In the measurement of the Id−Vg characteristics, a change in a current between the conductor 240s functioning as a source electrode and the conductor 240d functioning as a drain electrode (hereinafter, also referred to as a drain current (Id)) when a potential applied to the conductor 260 functioning as a first gate electrode of the transistor 200 (hereinafter, also referred to as a gate potential (Vg)) is changed from a first value to a second value is measured.

Here, a change in a drain current (Id) when a voltage (hereinafter, also referred to as a drain voltage) that was a difference between a potential applied to the conductor 240s (hereinafter, also referred to as a source potential Vs) and a potential applied to the conductor 240d (hereinafter, also referred to as a drain potential Vd) was set to +0.1 V or +3.3 V and a voltage (hereinafter, also referred to as a gate voltage) that was a difference between the source potential and the gate potential was changed from −3.3 V to +3.3 V was measured.

In order to examine the reliability of the transistors, a GBT (Gate Bias Temperature) stress test was performed on Sample 2A to Sample 2E. A GBT stress test is a kind of reliability test and can measure a change in transistor characteristics due to long-term use.

In a GBT stress test, the temperature of a substrate over which a transistor is formed is kept constant. A source potential and a drain potential of the transistor are set to the same potential, and as a first gate potential, a potential different from the source potential and the drain potential is supplied for a certain period. In this example, substrates over which Sample 2A to Sample 2E were formed were kept at 125° C. for one hour; this is regarded as an accelerated test. Note that the source potential and the drain potential of the transistor were set to 0.00 V, and the first gate potential was set to +3.63 V. Note that the back gate potential was set to 0.00 V.

First, initial Id−Vg characteristics of Sample 2A to Sample 2E were measured. Then, in the GBT stress test, the Id−Vg characteristics were measured under the same conditions as the measurement of the initial characteristics after a predetermined period of time.

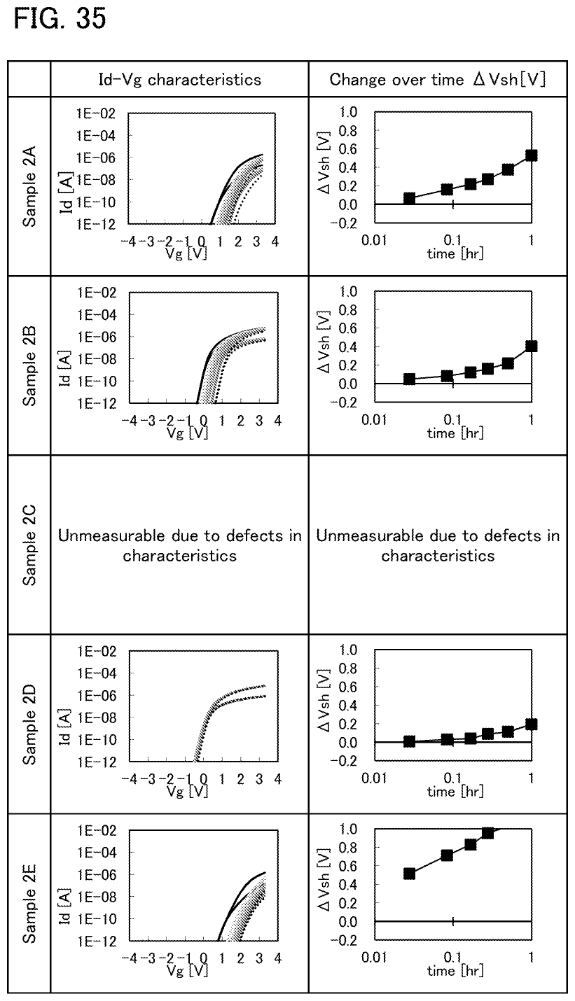

In this example, the measurement was conducted seven times: after 0 seconds, after 100 seconds, after 300 seconds, after 600 seconds, after 1000 seconds, after 1800 seconds, and after 3600 seconds. FIG. 35 shows the results. Note that black solid lines indicate the results after 0 seconds, black dotted lines indicate the results after 3600 seconds, and gray solid lines indicate the results between 0 seconds and 3600 seconds.

As an index of the amount of change in the electrical characteristics of a transistor, change over time in the threshold voltage (hereinafter, also referred to as Vsh) of the transistor (hereinafter, also referred to as ΔVsh) was used. Note that in the Id−Vg characteristics, Vsh is defined as the value of Vg when Id=1.0×10⁻¹² [A] is satisfied. If Vsh when the stress starts to be applied is +0.50 V and Vsh after the stress is applied for 100 seconds is −0.55 V, for example, ΔVsh after the stress is applied for 100 seconds is −1.05 V.

FIG. 35 shows the stress time dependence of ΔVsh after the GBT stress tests.

It was found from FIG. 35 that the amount of change in the threshold voltage (ΔVsh) of the transistors in Sample 2D is small. That is, it was found that Sample 2D has higher reliability than the other samples. The transistors in Sample 2C had defects in characteristics and thus the characteristics were unmeasurable. It was found that the change in electrical characteristics of Sample 2A, Sample 2B, and Sample 2E becomes larger as time passes.

Here, from the results in Example 1, Sample 2C probably has the largest amount of excess oxygen contained in the insulator 280, followed by Sample 2D, Sample 2A, Sample 2B, and Sample 2E in this order.

From the above, it was found that a transistor using an oxide semiconductor does not have normally-off characteristics if oxygen vacancies are included. In contrast, it was found that when the amount of excess oxygen is greater than or equal to the proper amount, the reliability is decreased. Therefore, it was found that a transistor having favorable electrical characteristics and excellent reliability can be provided when the proper amount of excess oxygen is supplied.

At least part of this example can be implemented in combination with any of the other embodiments described in this specification as appropriate.

### REFERENCE NUMERALS

200: transistor, 203: conductor, 205: conductor, 210: insulator, 212: insulator, 214: insulator, 216: insulator, 220: insulator, 222: insulator, 224: insulator, 230: oxide, 230a: oxide, 230a1: oxide, 230a2: oxide, 230A: oxide film, 230b: oxide, 230B: oxide film, 230c: oxide, 230C: oxide film, 234: region, 240: conductor, 240d: conductor, 240s: conductor, 241A: film, 242: region, 242d: region, 242s: region, 250: insulator, 250A: insulating film, 252: metal oxide, 252A: metal oxide film, 260: conductor, 260a: conductor, 260A: conductive film, 260b: conductor, 260B: conductive film, 260c: conductor, 270: insulator, 270A: insulating film, 271: insulator, 271A: insulating film, 273: insulator, 273A: insulating film, 273h: opening portion, 275: insulator, 275A: insulating film, 276: insulator, 276s: insulator, 276d: insulator, 280: insulator, 282: insulator, 283: insulator, 284: insulator.

1. A method for manufacturing a semiconductor device, comprising:
forming a first insulator;
forming a second insulator over the first insulator;
forming an island-shaped oxide over the second insulator;
forming a stacked body of a third insulator and a conductor over the oxide;
selectively reducing the resistance of the oxide by forming a film comprising a metal element over the oxide and the stacked body;
after forming a fourth insulator over the second insulator, the oxide, and the stacked body, forming, in the fourth insulator, an opening portion exposing the second insulator;
forming a fifth insulator over the second insulator and the fourth insulator; and
performing oxygen introduction treatment on the fifth insulator.

2. The method for manufacturing a semiconductor device, according to claim 1, wherein the oxygen introduction treatment is performed by an ion implantation method.

3. The method for manufacturing a semiconductor device, according to claim 1, wherein the oxygen introduction treatment is performed in such a manner that a sixth insulator is deposited over the fifth insulator by a sputtering method using an oxygen gas.

4. The method for manufacturing a semiconductor device, according to claim 3, wherein the sixth insulator has a function of inhibiting diffusion of oxygen.

5. The method for manufacturing a semiconductor device, according to claim 1, wherein the first insulator has a function of inhibiting diffusion of oxygen.

6. The method for manufacturing a semiconductor device, according to claim 1, wherein the fourth insulator is formed after the film comprising the metal element is removed.

7. The method for manufacturing a semiconductor device, according to claim 1, wherein the metal element is at least one of aluminum, ruthenium, titanium, tantalum, chromium, and tungsten.
